(19) United States
(12) Patent Application Publication
(10) Pub. No.: US 2017/0022607 A1
(43) Pub. Date: Jan. 26, 2017

(54) STRUCTURE PROVIDED WITH CARBON FILM AND METHOD FOR FORMING CARBON FILM

(71) Applicant: TAIYO YUDEN CHEMICAL TECHNOLOGY CO., LTD., Takasaki-shi (JP)

(72) Inventor: Kunihiko SHIBUSAWA, 370-1201 (JP)

(21) Appl. No.: 15/114,354

(22) PCT Filed: Jan. 27, 2015
(86) PCT No.: PCT/JP2015/052130

§ 371 Date: Jul. 26, 2016

(30) Foreign Application Priority Data
Jan. 28, 2014 (JP) 2014-013340

(51) Int. Cl. C23C 16/26; C23C 16/56; C23C 16/50

(52) U.S. Cl. CPC C23C 16/26; C23C 16/50; C23C 16/56

(57) ABSTRACT

A structure in an embodiment of the present invention includes fine unevenness structure in the surface of a carbon film independently of the shape of the surface of a substrate. This structure includes a substrate and a carbon film formed on the substrate and containing carbon or carbon and hydrogen. At least part of the surface of the carbon film has fine unevenness structure formed by applying ions and/or radicals (e.g., plasma) of oxygen and/or Ar. The fine unevenness structure has a ten point average roughness Rz of 20 nm or larger.

### CROSS-REFERENCE TO RELATED APPLICATIONS

This application is based on and claims the benefit of priority from Japanese Patent Application Serial No. 2014-013340 (filed on Jan. 28, 2014), the contents of which are hereby incorporated by reference in their entirety.

The present invention relates to a structure including a carbon film and a method of forming a carbon film, and in particular to a structure including a carbon film having unevenness structure in the surface thereof and a method of forming the carbon film.

### BACKGROUND

### Technical Field

Carriers for catalysts, ions, and organisms have conventionally been made of porous activated carbon, zeolite, ceramic, and porous beads. A surface layer of such carriers has unevenness structure produced by pores and having a large surface area. Structures including a carbon film have also been produced for various applications so as to have fine unevenness structure in the surface of the carbon film and a large surface area.

In the first example of such applications, the unevenness structure is formed in the surface of the carbon film to improve wettability of the surface. For example, Japanese Patent Application Publication No. 2010-186578 discloses a separator for a fuel cell including a gas channel structure having an amorphous carbon film on the surface thereof, wherein the amorphous carbon film has unevenness structure formed therein to hydrophilize the gas channel structure for better discharge of water produced in the gas channel. The surface of the lower layer (expanded metal) under the amorphous carbon film is previously roughened to produce unevenness structure of the amorphous carbon film to be formed on the lower layer.

In the second example of the applications, another functional substance (e.g., a lubricant) is fixedly contained in recesses of the unevenness structure in the surface of the carbon film. For example, Japanese Patent Application Publication No. 2013-087197 discloses a slider mechanism including two sliding members configured to slide with respect to each other at sliding surfaces thereof containing a lubricant therebetween, where amorphous carbon films formed in the sliding surfaces of the sliding members have granular structure in the surfaces thereof such that the lubricant is fixedly contained between the sliding surfaces. The amorphous carbon films are formed on, e.g., the lower layer having granular unevenness structure so as to form granular unevenness structure in the surface of the amorphous carbon film.

In another example of the applications, the unevenness structure is formed in the surface of the carbon film to improve adhesion to other materials. For example, Japanese Patent Application Publication No. 2004-339564 discloses a sliding member including a diamond-like carbon (DLC) film on the surface of a substrate, wherein the surface of the DLC film has fine recesses aggregated together so as to improve adhesion between a solid lubricant film and the DLC film. In forming the DLC film on the surface of the substrate by a sputtering method using carbon as a target, the negative bias voltage applied to the substrate is set at 150 to 600 V such that the surface of the DLC film has fine recesses aggregated together.

Thus, it is conventional to previously form unevenness structure conforming to the lower layer (substrate) to form unevenness structure in the surface of a carbon film such as an amorphous carbon film. Other known methods include a method in which fine particles are arranged on the substrate so as to correspond to the unevenness structure and a carbon film is formed thereon, a method in which after a carbon film is formed, the surface of the carbon film is roughened (unevenness structure is formed) by physical grinding such as shotblasting, and a method in which fine powder of carbon nanotube (CNT) is scattered on the surface of a carbon film. Further, droplets may be produced during formation of an amorphous carbon film and then removed to leave recesses.

### SUMMARY

For example, since an amorphous carbon film, a sort of carbon film, is hard and highly wear resistant, unevenness structure formed in the surface thereof is less prone to wear and damage due to external friction or stress and thus can be maintained easily. Various functions and physical properties originated from such unevenness structure of a surface (with a large surface area) can be retained stably. However, for example, the shape of an amorphous carbon film tends to conform to the shape of the surface of a substrate. If the surface of a substrate is flat and smooth, the amorphous carbon film is formed to have a flat and smooth surface in conformity to the flat and smooth surface of the substrate. It is difficult to form an amorphous carbon film having continuous and fine unevenness structure on the surface of a substrate. Additionally, for example, it is also very difficult to form an amorphous carbon film while finely controlling the shape of the fine (e.g., submicron-level) unevenness structure (e.g., so as to form a shape in which recesses of unevenness structure can contain, retain, and release another substance efficiently).

The unevenness structure may occur incidentally in an amorphous carbon film, for example, when unevenness is produced locally due to inevitable droplets, or random catching of dust, when in a high voltage plasma process a cluster of atoms of material gas is formed and consequently the film with a low density has irregular and gentle unevenness structure formed therein, or when the film has openings formed therein by abnormal electric discharge such as arcing in forming the film. However, since the unevenness structure in these cases is not formed under control, it is difficult to control the roughness, shape, position, etc. of the unevenness structure desirably. Accordingly, to form the unevenness structure in the surface of the carbon film for the above-mentioned various applications, it is necessary to previously form unevenness structure in the surface of a substrate. There is no established technique for forming unevenness structure in a surface layer of a carbon film independently of the shape of the surface of the substrate.

One object of the embodiments of the present invention is to form fine unevenness structure in a surface of a carbon film independently of the shape of the surface of a substrate. Other objects of the embodiments of the present disclosure will be apparent with reference to the entire description in this specification.

A structure according to an embodiment includes a substrate and a carbon film formed on the substrate and containing carbon or carbon and hydrogen, wherein at least part of the surface of the carbon film has unevenness structure formed by applying ions and/or radicals of oxygen and/or Ar and having a ten point average roughness Rz of 20 nm or larger. The ten point average roughness Rz refers to the ten point average roughness Rz defined under JIS B 0601 (1994).

A method of forming a carbon film according to an embodiment includes: forming a carbon film containing carbon, or carbon and hydrogen on a substrate; and irradiating at least part of a surface of the carbon film with ions and/or radicals of oxygen and/or Ar until unevenness structure having a ten point average roughness Rz of 20 nm or larger is formed.

Various embodiments of the present invention permits forming fine unevenness structure in the surface of a carbon film independently of the shape of the surface of a substrate.

### BRIEF DESCRIPTION OF THE DRAWINGS

FIG. 1 is an electron microscope photograph of the surface of Comparative Example 1-1.

FIG. 2 is an electron microscope photograph of a section of Comparative Example 1-1.

FIG. 3 is an electron microscope photograph of the surface of Comparative Example 2.

FIG. 4 is an electron microscope photograph of the surface of Comparative Example 3-1.

FIG. 5 is an electron microscope photograph of the surface of Example 1-1.

FIG. 6 is an electron microscope photograph of the surface of Example 1-2.

FIG. 7 is an electron microscope photograph of a section of Example 1-2.

FIG. 8 is an electron microscope photograph of the surface of Example 1-3.

FIG. 9 is an electron microscope photograph of the surface of Comparative Example 1-2.

FIG. 10 is an electron microscope photograph of the surface of Example 3.

FIG. 11 is an electron microscope photograph of the surface of Comparative Example 3-2.

FIG. 12 is an electron microscope photograph of the surface of Example 6.

FIG. 13 is an electron microscope photograph of a section of Example 1-2.

FIG. 14 is an electron microscope photograph of the surface of Example 4.

FIG. 15 is an electron microscope photograph of a section of Example 4.

FIG. 16 is an electron microscope photograph of the surface of Example 5.

FIG. 17 is an electron microscope photograph of a fracture section of Example 5.

FIG. 18 shows a surface condition of stainless steel of Reference Example.

FIG. 19 shows a surface condition of Example 1-1.

FIG. 20 shows a surface condition of Example 5.

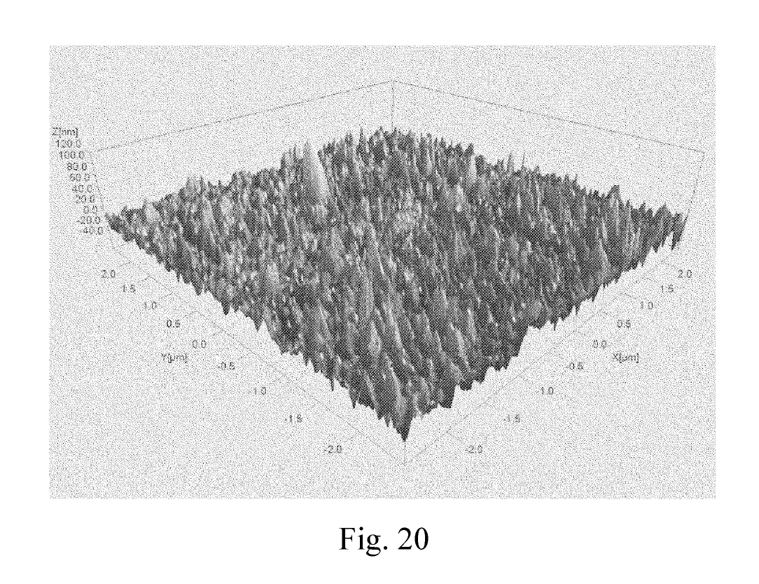

FIG. 21 is an electron microscope photograph of the surface of Example 7.

FIG. 22 is an electron microscope photograph of the surface of Example 8.

FIG. 23 shows a surface condition of Reference Example 3.

FIG. 24 shows a surface condition of Reference Example 4.

FIG. 25 shows a surface condition of Reference Example 5.

FIG. 26 shows a surface condition of Reference Example 5 having fine unevenness structure formed therein.

FIG. 27 is an electron microscope photograph of the surface of Comparative Example 101.

FIG. 28 is an electron microscope photograph of the surface of Example 101 (prior to dry etching).

FIG. 29 is a photograph showing measured distribution of Si in the surface of Example 101 (prior to dry etching).

FIG. 30 is an electron microscope photograph of the surface of Comparative Example 101 (after dry etching).

FIG. 31 is an electron microscope photograph of a section of Comparative Example 101 (after dry etching).

FIG. 32 is an electron microscope photograph of a section of Comparative Example 101 (prior to dry etching).

FIG. 33 is an electron microscope photograph of the surface of Example 101 (after dry etching).

FIG. 34 is an electron microscope photograph of a fracture section of Example 101 (after dry etching).

FIG. 35 is an electron microscope photograph of the surface of Example 101 (after two times of dry etching).

FIG. 36 is an electron microscope photograph of a section of Example 101 (after two times of dry etching).

FIG. 37 is an electron microscope photograph of the surface of Example 105.

FIG. 38 is an electron microscope photograph of a section of Example 105.

FIG. 39 is an electron microscope photograph of the surface of Example 106.

### DESCRIPTION OF EXAMPLE EMBODIMENTS

Various embodiments of the present disclosure will now be described with reference to the attached drawings. The structure in an embodiment includes a substrate and a carbon film formed on the substrate and containing carbon or carbon and hydrogen. At least part of the surface of the carbon film may have fine unevenness structure formed by applying ions and/or radicals (e.g., plasma) of oxygen and/or Ar. It is conventional to irradiate a carbon film with oxygen plasma for various applications, but this is not intended to form fine unevenness structure in the surface of the carbon film. For example, it is conventional to perform etching (ashing) with oxygen plasma to remove a carbon film. However, in this etching process, a carbon film masked with a desired pattern may be irradiated with oxygen plasma to remove the carbon film totally from the portions not masked. Accordingly, the surface layer of the carbon film left after the masking (the portion under the mask (the outermost portion of the surface of the carbon film in the thickness direction thereof)) may be protected from oxygen plasma by masking and remain unmodified. Further, for example, a carbon film such as an amorphous carbon film may be irradiated with plasma including oxygen so as to produce open carbon chains in the surface of the carbon film for activation and improve wettability using functional groups in the surface. However, this process is intended for chemical modification. Since application of oxygen plasma is intended to cleave the bond between carbon atoms in the surface layer of the carbon film and form active sites, it is possible to put in sufficient energy only to cleave the bond between carbon atoms, and this process may be finished in a relatively short time to prevent unnecessary reduction in the thickness and roughening of the surface of the film. The duration of application of oxygen plasma may be rather minimized to prevent removal of the carbon film and reduction in film thickness.

Further, after a carbon film such as an amorphous carbon film is irradiated with plasma of oxygen, Ar, etc. to activate the surface thereof (provide polarity or functional groups or produce open carbon chains to form active sites in the surface) so as to improve wettability of the surface, the activity of the surface may be lost over time, and the wettability of the surface may fall back in a relatively short time. Accordingly, it is not practicable as a method of producing a long-lasting and stable hydrophilic surface to irradiate a carbon film such as an amorphous carbon film containing hydrogen and carbon with plasma of oxygen, Ar, etc. to hydrophilize the surface thereof.

When a substrate or a film is subjected to an etching process using an electric field such as plasma etching, the electric field is typically concentrated on the tip portions of the projections in the uneven shape of the substrate or the film, and thus the tip portions of the projections are etched faster than the recesses in the substrate or the film. Accordingly, the surface layer of the substrate or the film can be smoothened. In a known electropolishing technique for example, the electrolytic action is concentrated on the projections in the stainless steel surface to remove the projections and smoothen the surface. Further, in a plasma process for forming an amorphous carbon film using an electric field of plasma and a wet electrolytic plating technique, a film is formed to a larger thickness on the projections in the surface layer of the substrate where the electric field (electrolytic action) is concentrated. Therefore, when the surface layer of a carbon film is irradiated with oxygen plasma having an electric field, the projections in a substrate or a film are removed faster, such that the surface of the carbon film is smoothened.

The inventors of the present invention have found that fine unevenness structure can be formed in the surface of a carbon film independently of unevenness structure of a substrate by, e.g., irradiating the surface of the carbon film (e.g., an amorphous carbon film) formed on the substrate and containing carbon or carbon and hydrogen with plasma (ions and/or radicals) of oxygen and/or Ar under conditions of the duration, energy level, and concentration of an etching gas exceeding the conditions necessary for the above-mentioned surface modification applications including the duration, energy level, and concentration of an etching gas including oxygen and/or Ar made into plasma in a vacuum apparatus. As will be described later, the fine unevenness structure in an embodiment can be reproduced similarly in the surface of the carbon film by roughening under the same etching conditions the works formed under the same conditions. Such fine unevenness structure can be used industrially.

The initial film thickness of the carbon film prior to application of plasma of oxygen and/or Ar should be equal to or larger than a desired ten point average roughness Rz of the unevenness structure formed of the carbon film itself. In an embodiment, in forming the unevenness structure in the carbon film itself by applying plasma of oxygen and/or Ar, the thickness of the carbon film prior to the application of the plasma will be reduced (at both recesses and projections of the unevenness structure to be formed). Thus, the starting material should theoretically be a carbon film having an initial thickness equal to or larger than a desired ten point average roughness (Rz) of the unevenness structure to be formed. For example, if the desired ten point average roughness (Rz) of the unevenness structure to be formed is 20 nm, the initial thickness of the carbon film prior to the application of the plasma of oxygen and/or Ar should be 20 nm or larger; and if the desired ten point average roughness (Rz) of the unevenness structure to be formed is 150 nm, the initial thickness of the carbon film prior to the application of the plasma of oxygen and/or Ar should be 150 nm or larger. By contrast, for mere surface modification of the surface layer of a carbon film for chemical activation, the plasma irradiation may be performed without any constraint in initial thickness of the carbon film.

Further, at least part of the projections in the fine unevenness structure formed of the carbon film itself in an embodiment may extend (project) outwardly from the surface of the carbon film so as to be substantially orthogonal or at an angle with respect to the surface of the substrate. That is, the part of the surface of the carbon film contacting the outside is modified toward the outside. Such unevenness structure can serve as “a surface” efficiently containing, retaining, releasing, and reflecting possible foreign substances coming from the outside (foreign substances coming substantially orthogonally or at an angle with respect to the surface of the substrate). Such structure makes the substantial area (surface area) larger than the projected area. If the structure in an embodiment is used as a light receiver for example, adequate light receiving area can be readily obtained. Further, in applications where the substrate is in a direct surface contact with other solid or liquid substances, the unevenness structure formed in the carbon film can directly contact with a mating member, making it possible to efficiently exhibit properties of the unevenness structure in the embodiment such as wettability, capacity demoldability, and adhesion. Since the unevenness structure is formed to face the outside, the substances adhering to the unevenness structure can be readily cleaned off, and a second film can be efficiently formed on top of the unevenness structure.

The above-mentioned “conditions of the duration, energy level, and concentration of an etching gas exceeding the conditions necessary for the surface modification applications including the duration, energy level, and concentration of an etching gas” may refer to the conditions such as the duration of applying a plasma of oxygen and/or Ar, energy level, and concentration of an etching gas sufficient to form unevenness structure having a ten point average roughness Rz of 20 nm or larger in the surface of the carbon film.

The conditions such as the duration of applying a plasma of oxygen and/or Ar, energy level, and concentration of an etching gas sufficient to form unevenness structure having a ten point average roughness Rz of 20 nm or larger in the surface of the carbon film may include various plasma process conditions (the flow rate of a plasma gas, gas pressure, applied voltage, application time, etc.) in accordance with the thickness and the density of the carbon film and the added elements.

The structure in an embodiment may include fine unevenness structure in at least part of the surface of a carbon film. In this unevenness structure, the carbon film itself may be made uneven in the thickness direction (substantially orthogonal to the surface of the substrate) (instead of conforming to the shape of the substrate). The unevenness structure may include the components constituting the carbon film itself and the components of the material gas applied by plasma irradiation, and may be on a nano order scale and continuous (however, the components of the material gas applied by plasma irradiation, such as Ar or oxygen, may naturally leave the structure in an embodiment over time or may be forcibly removed by application of hydrogen gas, etc.). The unevenness structure may have a ten point average roughness (Rz) of 20 nm or larger, more preferably 40 nm or larger, or still more preferably 150 nm or larger. The fine unevenness structure in the surface of the carbon film in an embodiment, which is composed of the carbon film itself made uneven in the thickness direction, may have a different shape than the portion of the substrate (the underlying layer) underlying the unevenness structure.

Attention has conventionally been not paid to the shape and continuity of unevenness structure composed of the carbon film itself and formed by applying a plasma of oxygen and/or Ar to the surface layer thereof, and the shape, roughness, and other characteristics of the unevenness structure have not been understood. Accordingly, no study has been made on the unevenness structure for use in accordance with the characteristics thereof (as a structure retaining, carrying, and laminated with other substances) or use as a structure having a large surface area obtained by roughening the surface thereof. For example, the surface layer of an amorphous carbon film conventionally used as a protection film having a high slidability and wear resistance should be more smooth or should preferably be smoothened over time with use thereof. For example, it is intended that a sliding surface (a surface to be rubbed) of an amorphous carbon film having an intentionally low hardness and initially rough unevenness structure and thus relatively prone to wear should be smoothened as a result of repetition of sliding on a mating member rubbed on or contacted with.

The unevenness structure in the surface of a carbon film according to an embodiment may be formed of the carbon film itself and may include, for example, a plurality of projections having a diameter of about 20 to 30 nm and a height of 10 to 20 nm and aggregated at intervals (the distance at the root of the projections) of less than about 20 nm. The recesses (grooves, low points) formed between adjacent projections may have an aspect ratio (the depth/the width of the openings) of about 0.3 or greater. Alternatively, this unevenness structure may include, for example, a plurality of projections having a diameter of about 40 to 50 nm and a height of 20 to 50 nm and aggregated at intervals (the distance at the root of the projections) of less than about 50 nm. The recesses (grooves, low points) formed between adjacent projections may have an aspect ratio (the depth/the width of the openings) of about 0.3 or greater.

Such unevenness structure having a high aspect ratio may retain air by the capillary action (inverse capillary action) in, e.g., improving the wettability with water in the surface, and thus can provide the characteristic of water having a contact angle with water of 180° Further, in the unevenness structure in an embodiment, the projections formed in the surface layer may be wider toward the surface layer (toward the substrate), and may receive, retain, and release the substance to be filled into the recesses. Since the tip end portion of the projections (having a shape wider toward the substrate) may have a small area, “point contact” with solid substances contacting with the structure according to an embodiment may be possible and the coefficient of friction thereof may be significantly reduced. Additionally, such unevenness structure may make it possible to, for example, form relatively large unevenness structure by oxygen plasma, and then form relatively small unevenness structure by Ar plasma in the surface layer of the relatively large unevenness structure, so as to produce “fractal structure,” as will be described later.

In the structure according to an embodiment, the unevenness structure in the carbon film may have a surface area of 25,200,000 nm² or larger and a root-mean-square roughness of 2.03 nm or higher in a rectangular measurement region of 5 nm by 5 μm for example (both when the rectangular region of 5 μm by 5 μm is directly measured and when a region other than the rectangular region (e.g., a rectangular region of 1 μm by 1 μm) is measured and then the measurement value is converted for a rectangular region of 5 μm by 5 μm).

Additionally, in the structure according to an embodiment, a local projection (a significantly high projection that can increase the maximum height Ry and the ten point average roughness Rz) may be unintentionally formed in the surface layer when an amorphous carbon film is formed. For example, if the local projection is formed of a droplet, post-process grinding such as lapping is conventionally performed on the surface layer of the film. In an embodiment, in the initial stage where a plasma of Ar or oxygen is applied to the surface layer after the amorphous carbon film is formed, the unevenness structure (particularly “sticking-out” projections) unintentionally formed of the amorphous carbon component may be removed to achieve an extremely smooth condition (as a stage preceding the formation of fine unevenness structure according to an embodiment in the amorphous carbon film. In view of the above, the surface modification conventionally performed for surface activation can initially smoothen the surface roughness of the amorphous carbon film, and thus may be an extremely useful “surface smoothening” method in an amorphous carbon film required to have wear resistance and slidability.

If the same unevenness structure as the fine unevenness structure in the carbon film according to an embodiment is formed by, e.g., previously forming corresponding unevenness structure on the substrate, it may be necessary to design and fabricate the unevenness structure on the substrate on a nano order scale taking into account the thickness of the carbon film to be formed thereon. Likewise, if the unevenness structure is formed by previously arranging fine particles on the substrate, it may be necessary to prepare fine particles having a uniform diameter on a nano order scale, uniformly arrange the fine particles at constant intervals while preventing aggregation thereof, fix the fine particles so as to prevent the fine particles from being moved or scattered by handling of the substrate, and uniformly form a carbon film as an upper layer. Further, in the unevenness structure previously formed on the substrate on a nano order scale and the fine unevenness structure formed of the fine solid matters previously arranged on the substrate, it is difficult to finely adjust the unevenness structure. For example, it is extremely difficult to finely design and fabricate the unevenness structure such that for example the tip ends of the projections have a tapered shape (that is, the projections are wider toward the substrate) and the openings in the recesses are narrower toward the substrate, thereby making it possible to fill, retain, and release a desired substance through wide openings (around the entrances of the recesses) in the fine unevenness structure in the carbon film. These are very complex processes and require very sophisticated and expensive facilities. By contrast, with the structure according to an embodiment, a carbon film having fine unevenness structure in the surface thereof can be achieved without need of a complex process or sophisticated and expensive facilities.

Examples of a substrate practically available and having a smooth surface may include a Si (100) wafer polished to an arithmetic average roughness Ra of less than about 0.1 nm (e.g., Ra of 0.054 nm) and a stainless steel plate ordinarily available and having a scar from rolling (having an arithmetic average roughness Ra of about 15 nm). The difference in surface roughness between these substrates may be a factor of about 300, while the difference in surface area may be smaller than the difference in surface roughness. This may indicate that large unevenness such as large indentations may enlarge the surface roughness of the substrate but may not enlarge the substantial surface area.

In an embodiment, the carbon film may have a large surface area if the carbon film is previously formed to have a smooth surface on the above-mentioned Si wafer substrate having a smooth surface and fine unevenness structure is formed in the smooth surface of the carbon film. For similar surface roughnesses, a higher density of the fine unevenness structure can increase the surface area. Additionally, as the surface roughness of the substrate is greater, the surface roughness of the carbon film formed on the substrate and having the unevenness structure may be greater.

It is publicly known that an amorphous carbon film can be formed by a plasma process typically in high conformity to the unevenness structure of the substrate. If, for example, the substrate itself has fine unevenness structure on a nano order scale, it is difficult to form an amorphous carbon film on the substrate so as to conform to (reproduce) the fine unevenness structure. That is, if an amorphous carbon film is formed on a substrate having fine unevenness structure on a nano order scale, the amorphous carbon film may be first formed on the tip end portion of the projections of the unevenness structure of the substrate. This portion of the amorphous carbon film formed first may grow and deposit upward to a certain film thickness. In the bottom of the recesses in the unevenness structure, the action of forming the film may be reduced due to interruption by plasma, etc. The amorphous carbon film may also grow horizontally at the tip ends of the projections in the unevenness structure, and as a result, the portions of the amorphous carbon film formed on the tip ends of adjacent projections may be integrated together into the continuous amorphous carbon film having a generally smooth surface. As will be described later, the comparison between Example 4 and Example 8 and the comparison between Example 1-1 and Example 7 may experimentally confirmed that, particularly in a process of depositing a film by using a strong electric field, a film formed on a substrate having fine unevenness structure may have a smaller surface roughness (e.g., the ten point average roughness Rz and the surface area) than the substrate.

To prevent the carbon film from having a smaller surface roughness, the carbon film may be formed only on the tip ends of the projections in the fine unevenness structure on a nano order scale formed in the substrate itself, and the carbon film may be formed in dots (separated parts) without continuity as a surface. In this case, a film that can be formed may be extremely thin and defective in durability. Additionally, the discontinuity of the carbon film may be an issue for applications requiring gas barrier quality and corrosion resistance for example.

In a structure according to an embodiment, even if the substrate itself previously has fine unevenness structure and the carbon film formed thereon has unevenness structure with an irregular thickness due to the unevenness structure of the substrate (e.g., the film thickness is larger on the projections and smaller on the recesses of the unevenness structure of the substrate itself, and these portions alternate with each other), the carbon film having the irregular thickness (unevenness structure) may be irradiated with a plasma of oxygen and/or Ar to have finer unevenness structure with an increased surface area.

Whether the surface area of the structure is enlarged by the fine unevenness structure of the substrate itself (by the unevenness structure in the carbon film conforming to the fine unevenness structure of the substrate itself) or by the unevenness structure of the carbon film according to an embodiment (by the unevenness structure of the carbon film itself independent of the shape of the substrate) can be confirmed by measuring, observing, and comparing the roughness (rises and falls like quadratic curves) of the substrate surface on the side where the carbon film is formed (the boundary between the substrate and the carbon film in the section) and the roughness (rises and falls like quadratic curves) of the substrate surface on the opposite side (the boundary between the substrate and the outside in the section) in a certain region of the section of the substrate while eliminating minute roughness smaller than a certain roughness (roughness functionally unnecessary and negligible). Additionally, the shape of the substrate may be observed by removing the carbon film.

In a structure according to an embodiment, the unevenness structure in the surface of the carbon film may not necessarily be continuous but may be separated into parts (that is, the “unevenness structure” described in this specification encompasses the aspect in which the substrate (or the underlying layer) is exposed at the recesses in the unevenness structure). Further, in a structure according to an embodiment, the substrate or the underlying layer exposed at the recesses in the unevenness structure may have been etched by a plasma of oxygen and/or Ar gas applied continuously (for example, if the substrate or the underlying layer is formed of Cu, which is prone to be etched by Ar plasma, or if the overlying layer is the carbon film containing Si or a metal element and the underlying layer is formed of a carbon film containing carbon or carbon and hydrogen which is prone to be etched by oxygen).

In an embodiment, a carbon film can be formed on various substrates. For example, the surface roughness of the substrate may not be particularly specified. The substrate may previously have inherent indentations or unevenness (e.g., a rolled stainless steel plate, a resin film such as a PET film, or a rubber film may be pressed with a die (such as a nanoimprint die) having unevenness on a nano order scale to form the unevenness while varying the pressure and the temperature) or may have indentations or unevenness intentionally formed therein. However, if the unevenness structure is previously formed uniformly on the substrate, and the diameter of the projections or the diameter of the recesses in the unevenness structure is about 30 nm to 1,000 μm, the height of the projections is about 30 nm to 1,000 μm, and the intervals between adjacent projections (e.g., the intervals between roots of the adjacent projections) are about 1 nm to 1,000 nm, and more preferably, if the diameter of the projections or the diameter of the recesses in the unevenness structure is about 50 nm to 100 nm, the height of the projections is about 50 nm to 100 nm, and the intervals between adjacent projections (e.g., the intervals between roots of the adjacent projections) are about 1 nm to 100 μm, then the unevenness structure on a nano order scale in the surface of a carbon film according to an embodiment formed on the substrate may suitably approximate the fractal dimensionality of the structure to 3 and enlarge the surface area.

In an embodiment, the surface of the substrate may be very smooth like a polished Si (100) wafer or may have unevenness structure as described above; and the surface of the substrate may have finer unevenness in the tip end of the projections in the unevenness structure, and may have a multi-layer (multiplex) unevenness structure including further multiplexed unevenness structures. Such unevenness structure may have various shapes. For example, the recesses may be inversely tapered or may have indeterminate shapes. The shape of the projections in the unevenness structure may be circular, rectangular, astral, oval, needle-like, wavy, or indeterminate.

In an embodiment, the material of the substrate may not be particularly specified. The carbon film according to an embodiment can be formed on substrates made of various materials that can support the carbon film. Examples of the substrate that can be used may include a film composed of carbon or carbon and hydrogen, a film composed of blocks, flakes, beads, or powder of carbon, metals such as iron, aluminum, copper, Ni, and Cr, alloys such as stainless steel, inver, inconel, and Ni—Co, noble metals such as Au, Pt, Ro, and Ag, amorphous metals, resins such as PET, PEN, OPP, acrylic, and vinyl chloride, composite materials such as glass, ceramic, cellulose, carbon fibers, carbon rods, carbon plates, glass fibers, and FRP, semimetals such as Si, semiconductors, amorphous Si, and other various materials.

The substrates previously having unevenness structure can be formed by various methods. Examples of such substrates may include a substrate provided with unevenness structure by a known electrotyping method, a substrate having the surface patterned by laser, a substrate shaped with a die having a desired surface roughness or a die patterned previously, a substrate provided with unevenness structure by printing, a substrate provided with unevenness structure by a known photolithography method, a substrate provided with unevenness structure by a physical external stress (e.g., sandblasting, lapping, filing, or rolling), a substrate having a large number of voids formed therein by part of the components gasified upon heating, etc. and released from inside to outside, and a substrate having the surface roughened by various known chemical etching methods. Further examples may include: a substrate provided with a rough plating film formed by electrolytic plating intentionally without using the additive (such as a leveling agent) ordinarily used for forming a smooth plating film, for example, a substrate provided with a Ni plating film formed in a sulfamic acid nickel plating bath in which no leveling agent is added or a restricted amount of leveling agent is added, a Ni plating film formed in an acidic nickel chloride plating bath in which addition of the leveling agent is similarly controlled, or a rough plating film formed by a plating method referred to as Joule Ni plating or Satin Ni plating, in which a plating liquid previously contains various fine particles, and the fine particles and a plating film are subjected to eutectoid to form a rough plating film having unevenness structure constituted by the fine particles; and various electrolytic plating films or nonelectrolytic plating films that can be formed by other known methods to have a rough surface.

The substrate may not necessarily be a single integral body but may be constituted by needle-like or rod-like members (e.g., carbon nanotube or needles) bundled together or may be constituted by a printing stencil (with or without a printing screen mesh), an emulsion, an electroforming foil, a stainless steel foil, a mesh, or other composite materials.

In an embodiment, the substrate may have various shapes. The substrate may be tubular, cubic, cuboid, spherical, polygonal pyramid, circular conic, bead-like, rod-like, ring-like, coil-like, powder, film-like, mesh-like, porous, fibriform, or in other various forms. For example, the substrate may be a printing screen mesh such as the mesh #640 having openings with a width of about 20 μm and threads with a diameter of about 15 μm, and a carbon film according to an embodiment may be formed on the surface layer of the substrate (fiber threads), such that the unevenness structure in the surface of the carbon film may enlarge the surface area thereof.

Thus, fabrics and porous bodies have large unevenness structure (a large surface area) and can be suitably used as substrates of the structure according to an embodiment. Further, substrates made of aluminum (anodized aluminum), zeolite, or active carbon subjected to anodic oxidation and having a large number of unevenness structures (pores) in the surface thereof can also be suitably used as substrates of the structure according to an embodiment.

The substrate according to an embodiment may also have fine pattern openings or pattern unevenness in the surface layer thereof. Examples of such substrates include a printing stencil, a gravure printing plate, an intaglio, a relief printing plate, etc. having a fine pattern therein, a microchip having a micro channel formed in the surface layer thereof for receiving a liquid or samples contained in a liquid for analysis or stratification (a channel member in the analytical instrument called μ-TAS: micro total analysis system), a separator in various cells including fuel cells, a structure for generating or discharging water such as an expand metal member or a water treatment filter in the drain outlet for water produced by the reaction.

In an embodiment, the carbon film may not necessarily be formed on a substrate. For example, a substrate composed of carbon (a block, a flake, a chip, fiber threads, beads, or powder of carbon) may include a surface layer constituted by a carbon film according to an embodiment having fine unevenness structure in the surface.

In an embodiment, a carbon film before plasma irradiation with oxygen and/or Ar can be formed by various known plasma film-forming apparatuses and plasma processes. For example, to form an amorphous carbon film, a hydrocarbon-based material gas such as acetylene or ethylene may be introduced into a known plasma CVD apparatus at a predetermined flow rate and pressure and made into a plasma with an electric field, and deposited on the substrate. A carbon film before plasma irradiation with oxygen and/or Ar may contain, by a known method, an inert gas such as hydrogen, nitrogen, or Ar, metal elements such as fluorine, boron, Ti, Cr, Ni, Cu, or Al, metal oxide elements such as Al₂O₃ or TiO₂, sulfur, or semimetals such as Si, in addition to carbon, within the purport of the present invention.

In an embodiment, a carbon film before plasma irradiation with oxygen and/or Ar may have a surface with various roughness, as does the above-mentioned substrate. However, if relatively rough unevenness structure is previously formed uniformly on the substrate, and the diameter of the projections or the diameter of the recesses in the unevenness structure is about 30 nm to 1,000 μm, the height of the projections is about 30 nm to 1,000 μm, and the intervals between adjacent projections (e.g., the intervals between roots of the adjacent projections) are about 1 nm to 1,000 μm, and more preferably, if the diameter of the projections or the diameter of the recesses in the relatively rough unevenness structure is about 50 nm to 100 μm, the height of the projections is about 50 nm to 100 μm, and the intervals between tip ends of adjacent projections are about 1 nm to 100 μm, the fine unevenness structure on a nano order scale formed by applying a plasma of oxygen and/or Ar on the surface of the carbon film may suitably approximate the fractal dimensionality of the structure to 3 and enlarge the surface area.

The surface of the carbon film before plasma irradiation with oxygen and/or Ar may be smooth or may have unevenness structure as described above; and the surface of the carbon film before plasma irradiation with oxygen and/or Ar may have finer unevenness in the tip end of the projections in the unevenness structure, and may have a multi-layer (multiplex) unevenness structure including further multiplexed unevenness structures. Such unevenness structure may have various shapes. For example, the recesses may be inversely tapered or may have indeterminate shapes. The shape of the projections in the unevenness structure may be circular, rectangular, astral, oval, needle-like, wavy, or indeterminate.

The carbon film included in the structure according to an embodiment may have fine unevenness structure produced by plasma irradiation of oxygen and/or Ar. The fine unevenness structure may have various shapes. For example, the ten point average roughness (Rz) of the unevenness structure in the carbon film according to an embodiment, indicating the surface roughness of at least a part thereof, may be at least 20 nm or larger, more preferably 40 nm or larger, or still more preferably 150 nm or larger.

Application of a plasma of oxygen and/or Ar for forming a carbon film having fine unevenness structure according to an embodiment can be performed by various known plasma film-forming apparatuses and plasma processes. For example, a substrate having a carbon film formed on the surface layer thereof may be placed in a plasma film-forming apparatus, and then oxygen or a gas containing oxygen (e.g., CO₂ or CO) and/or Ar or a gas containing Ar may be introduced to form a plasma. The plasma may be applied at a necessary energy level (plasma irradiation condition) for a necessary time to form fine unevenness structure in the surface of the carbon film. As described above, application of a plasma of oxygen and/or Ar at the necessary energy level (plasma irradiation condition) for the necessary time in an embodiment may be enough to first smoothen the surface layer of the carbon film to a high degree and then form fine unevenness structure according to an embodiment. In an embodiment, the content of oxygen and/or Ar in the top surface of the carbon film having fine unevenness structure may be larger than the content of oxygen and/or Ar in the other surface (the bottom surface (on the substrate side)).

A carbon film containing Si or metal elements may be previously formed under a top layer composed of carbon and prone to be etched by oxygen, that is, between the top layer and the substrate. The carbon film containing Si or metal elements may restrict the underlying layer from being modified by the etching with oxygen. With such structure, the unevenness structure can be readily formed only in the top layer by etching with oxygen without modification of the underlying layer (e.g., degradation in adhesion to the substrate, ductility, gas barrier quality, and wear resistance). The layer containing Si or metal elements may not necessarily contain carbon but may be various within the purport of the present invention as long as it can restrict etching with oxygen. The layer containing Si or metal elements can be formed in a desired portion of the structure according to an embodiment in the form of a single layer or multiple layers.

Such a plasma process may not be particularly specified. Any apparatuses that can make oxygen or Ar into a plasma (activation), such as a plasma CVD apparatus or a plasma PVD apparatus, may be used for the plasma process. Such apparatuses may include an atmospheric-pressure plasma apparatus, a corona discharge apparatus, a UV irradiation apparatus, an ozone irradiation apparatus, a laser irradiation apparatus, and even a heating furnace. When a carbon film containing hydrogen, such as an amorphous carbon film containing hydrogen, is heated, the film may be roughened by separation of hydrogen to form unevenness structure. However, in forming a carbon film having fine unevenness structure according to an embodiment, a plasma CVD apparatus or a PVD apparatus such as a sputtering apparatus can be suitably used for the entire process from forming of the carbon film on the substrate to high energy application of a plasma of oxygen or Ar (forming of the fine unevenness structure). In particular, a DC-pulsed plasma CVD apparatus that can apply a high voltage to the substrate and produce a plasma in a pulsed form can be used suitably.

The carbon film having fine unevenness structure formed by applying a plasma of oxygen and/or Ar may possibly be relatively brittle. However, since the fine unevenness structure in the carbon film according to an embodiment is on a nano scale, large unevenness structure (particularly projections therein) such as indentations in the substrate itself may typically protect at least a part of the fine unevenness structure and restrict it from directly receiving an external physical stress and breaking (except in the case where the surface of the substrate is very smooth as in a Si wafer substrate).

If the structure according to an embodiment is applied to a printing plate having a pattern opening for transferring a printing ink or a substrate such as a mesh or fabric having openings (through-holes), the section of the pattern openings that requires hydrophilicity or water repellence with respect to the printing ink may receive only the stress from a relatively soft liquid ink, and the portion located in the section of the openings in the mesh or fabric is less prone to receive an external frictional stress directly. Thus, the structure may be durable.

Further, if the fine unevenness structure in the carbon film according to an embodiment is required to have wear resistance, it may be possible to form a hard film (e.g., TiN, TiAlN, TiC) on the surface layer of the unevenness structure (including the recesses) by a dry process of an amorphous carbon film within a minimum necessary area for applications. If the fine unevenness structure in the carbon film according to an embodiment is required to have slidability, it is effective that the recesses in the fine unevenness structure carry a fluorine resin film, a silicon resin film, or a lubricant such as grease composed of fluorine-containing coupling agent and having cushioning property.

The fine unevenness structure in the surface of the carbon film according to an embodiment may be formed in the following manner. First, a carbon film may be formed on a substrate by a known plasma apparatus. The surface layer of this carbon film may include relatively large unevenness structure (projections) produced by uncontrolled carbon from a large plasma cluster or flock of an uncontrollable carbon film material, a droplet from a carbon target, a fine carbon film deposited in an apparatus having fallen and adhered (carbon dust adhered), or organic substance (dust) adhered in an atmosphere before the carbon film is introduced into the film-forming apparatus. After forming the carbon film with possible unintentional large unevenness structure produced therein, a plasma of oxygen and/or Ar may be applied. In applying the plasma, the projections in the relatively large unevenness structure may be etched first to smoothen the carbon film tentatively (the unintentional large unevenness structure may be removed to achieve a controlled surface roughness). Then, the application of the plasma of oxygen and/or Ar may be continuously performed on the smoothened surface of the carbon film, so as to form the fine unevenness structure as in the carbon film according to an embodiment. Accordingly, this process can transform the relatively large uncontrolled (unintentional) unevenness structure in the carbon film into the fine controlled unevenness structure and produce a carbon film having uniform and stable fine unevenness structure in the surface thereof.

The carbon film according to an embodiment having the fine unevenness structure produced in the surface thereof by applying a plasma of oxygen and/or Ar may have a high chemical activity immediately after it is formed, and thus may be reduced with hydrogen, etc. In the reduction process using hydrogen, etc., a known plasma process may be used to apply a hydrogen plasma, or a known wet process such as acid electrolysis may be used. In this case, oxygen and/or Ar introduced into the surface layer of the carbon film according to an embodiment may be removed by reduction or sputtering with hydrogen.

For example, when the structure according to an embodiment is used as a primer layer for a fluorine-containing coupling agent (described later), the film composed of the fluorine-containing coupling agent and having a thickness of about 10 to 20 nm may contain much fluorine in the surface layer thereof and thus can provide the substrate with a strong water repellence. Also, this film may have an excellent shock absorbing quality and corrosion resistance as a resin film, but may be susceptible to external frictional stresses because it is formed of a resin. The film composed of a fluorine-containing coupling agent and having water repellence or water and oil repellence may be formed in the recesses in the unevenness structure in the carbon film according to an embodiment to protect the film against external stresses such as friction. Accordingly, the ten point average roughness (Rz) of at least part of the unevenness structure in the carbon film according to an embodiment should preferably be at least about 20 nm or larger. Further, the ten point average roughness (Rz) of at least part of the unevenness structure in the carbon film according to an embodiment should preferably be at least about 40 nm or larger, such that after the film composed of the fluorine-containing coupling agent and having a thickness of about 10 to 20 nm is formed on the surface layer of the structure according to an embodiment, the water repellent layer composed of the fluorine-containing coupling agent can retain sufficient unevenness structure, and the structure according to an embodiment can continuously retain the structural water repellence produced by the unevenness structure.

If the unevenness structure in the carbon film according to an embodiment is made larger (rougher), the unevenness structure may be more likely to be retained even after the layer composed of the fluorine-containing coupling agent is formed, and may provide the structure with structural water repellence or water and oil repellence. On the other hand, if the unevenness structure is extremely fine, no substance can be contained or formed in the recesses in the unevenness structure, and thus the unevenness structure may be practically equivalent to a mere smooth surface. An example of fine particles practically available may be Ag nanoparticles used as a catalyst having a diameter of about 20 nm. Accordingly, the ten point average roughness (Rz) of the unevenness structure in the carbon film according to an embodiment, indicating the surface roughness of at least a part thereof, may be at least 20 nm or larger, more preferably 40 nm or larger, or still more preferably 150 nm or larger.

For example, if the carbon film according to an embodiment before application of a plasma of oxygen and/or Ar already has the unevenness structure, and the diameter of the projections in the unevenness structure in the carbon film is about 1 nm to 100 nm, the height of the projections is about 40 nm to 100 nm, the intervals between tip ends of adjacent projections are about 1 nm to 100 nm, and such unevenness structure is formed uniformly (possible unevenness structure may be, for example, the unevenness structure formed of the carbon film itself, or the unevenness structure of the substrate itself or the unevenness structure produced by fine substances adhered to the substrate), then the composite unevenness structure including the fine unevenness structure having nano order roughness to be formed later in the surface layer of the carbon film by application of a plasma of oxygen and/or Ar according to an embodiment may suitably approximate the fractal dimensionality of the structure to 3 and enlarge the surface area.

The fine unevenness structure in the carbon film according to an embodiment may include fine needle-like or columnar projections formed in the carbon film and appearing in the surface layer as fine unevenness. The fine unevenness structure in the carbon film according to an embodiment may include so-called “segment structure” in which the projections (or the carbon film itself containing the projections and the recesses) may be formed discontinuously and the substrate or the underlying layer may be exposed in the recesses of the unevenness structure. The recesses in the unevenness structure may be formed continuously to a thickness as small as several nanometers which is less impactive on transmittance of light, so as to improve the corrosion resistance and the gas barrier quality with respect to the substrate, for example. Minimizing the thickness of the film at the recesses in the unevenness structure may ensure the transmittance of light at the thin portions of the film (the recesses in the unevenness structure), while the thick and robust portion of the carbon film at the projections can provide the inherent qualities of the carbon film such as wear resistance, wettability, and the primer action.

Thus, the structure according to an embodiment in which the recessed portions of the film in the unevenness structure are removed or thinned can be applied to the case where a carbon film is formed on a transparent or translucent (light transmissive) substrate made of a transparent resin film or glass, for example, or the case where a carbon film is formed not on a transparent substrate but on the surface layer of an art work, decoration, fancy item having a colorful design, so as to reduce the coverage of the carbon film having a low transparency and ensure the transparency (light transmittance) with ease. The fine unevenness structure (a large surface area) can make a hydrophilic wear-resistant and low-friction structure or a primer substrate for a water repellent or water and oil repellent film (described later).

If the corrosion resistance and the gas barrier quality with respect to the substrate is required, the thickness of the film at the recesses in the unevenness structure may be 100 nm or larger. The thickness of the film at the recesses in the unevenness structure can be adjusted by the initial thickness of the carbon film (before application of a plasma of oxygen and/or Ar) or the contained elements, or a duration of applying a plasma of oxygen and/or Ar, or other conditions.

As will be described in more detail, a carbon film formed on a polished Si (100) substrate to a thickness of about 350 nm as in Comparative Example 3-1 (described later) can be visually observed as a green film on the Si (100) substrate serving as a base, and the color tone of the Si (100) substrate serving as an underlayer cannot be observed By contrast, in Example 3 (described later) (the sample prepared by applying a mixed plasma of Ar and oxygen gas to “Comparative Example 3-1” for 11 minutes) corresponding to the structure according to an embodiment, in which separated unevenness structure is formed in the Si (100) substrate, no green film is visually observed, and dark silvery metal gloss of the Si (100) substrate serving as an underlayer can be observed. The carbon film of Example 3, which constitutes the thick portion in the unevenness structure, may have a thickness of about 30 to 60 nm. Although this thickness is smaller than the initial thickness of the carbon film (before application of a plasma of a mixture gas of Ar and oxygen), a carbon film having such a thickness may typically be observed visually as a pale brown film on the Si (100) substrate. However, when the unevenness structure according to an embodiment is formed, the thickness of the portion of the carbon film at the recesses in the unevenness structure may be reduced enough to allow a high transmittance of light and the coverage by the thick portion (projections) of the carbon film may be reduced. Thus, the metal gloss of the Si (100) substrate can be visually observed.

When, for example, an amorphous carbon film is formed to a thickness of about 15 nm on a transparent slide glass having a light transmittance (total light transmittance) of about 90% (and having an average surface roughness Sa of about 0.336 nm and a ten point average roughness Rz of about 23.8 nm), the light transmittance may be reduced to about 70% around the wavelength of 450 nm and to about 72% around the wavelength of 500 nm. The transmitted light may be visually observed to be brown (measurement instrument U-4100 spectrophotometer from Hitachi High-Technologies Corporation). The amorphous carbon film was measured by “L*a*b* color system.” The untreated slide glass (before formation of the amorphous carbon film) exhibited b* (yellow, brown) of about 5.9, while the slide glass after formation of the amorphous carbon film exhibited b* of as large as 13.11 (measurement instrument the spectral colorimeter CM-508d from Minolta Camera Co., Ltd., measurement light source: a pulsed xenon lamp, measurement diameter: 8 mm, measured view: 2°, measurement light source: D65, measurement type: L*a*b* color system). This measurement result indicates that when the coverage by the thick portion of the carbon film having fine unevenness structure (the projections in the unevenness structure) is reduced and the thickness of the film at the recesses is reduced, the light transmittance and the transparency of the structure according to an embodiment can be ensured.

For example, a structure (a light transmissive film) having the carbon film according to an embodiment formed on a transparent film or glass should preferably have a total light transmittance of 80% or more. The structure according to an embodiment (a light transmissive film) having a total light transmittance of 80% or more may be applied to a container of food and drink, medicine, or cosmetics such that the discoloration of contents can be found easily and accurately.

The structure according to an embodiment may have a further increased total light transmittance and may be applied to cover glasses or resin films for touch panels of fancy electronic devices such as mobile electronic terminals or personal computers. The carbon film having fine unevenness structure can serve as, for example, a protective film having hydrophilicity and oleophilicity and a high wear resistance. For example, a slide glass having an average surface roughness Sa of about 0.336 nm and a ten point average roughness Rz of about 23.8 nm may have a contact angle with water of about 30°, indicating a high hydrophilicity, but may have a contact angle with oil (e.g., a mineral spirit) of about 25°, indicating a low oleophilicity. Accordingly, a finger print composed of fats and oils from a finger tip contacting the glass for operation may not sufficiently spread on the glass and may be repelled on the surface in a conspicuous manner (fogging). By contrast, for example, a slide glass including an amorphous carbon film having a thickness of about 15 nm formed thereon may have a contact angle with oil of about 4°, indicating a high oleophilicity, and cause oils to spread sufficiently. Thus, a finger on this slide glass may be less conspicuous. The total light transmittance may depend on a synthetic resin material included in the substrate film and the thickness of the film, and may be measured with a spectrophotometer in accordance with JISK7105.

In an embodiment, the composition of the carbon film may not be particularly limited as long as it contains at least carbon or carbon and hydrogen, and may additionally contain various elements. For example, the carbon film may additionally contain elements such as fluorine or sulfur, semimetals such as Si, or various metal elements such as Ti, in addition to carbon and hydrogen.

For example, as in Examples described later, an amorphous carbon film composed of carbon or carbon and hydrogen and additionally containing semimetals such as Si or other metal elements may have less tendency to include rough unevenness structure with relatively large unevenness formed therein by application of a plasma of oxygen and/or Ar, and may lose smaller amount of thickness thereof. Thus, when the carbon film previously contains Si or other metal elements that, upon application of a plasma of oxygen and/or Ar (particularly oxygen), merely produce oxides or metal oxides and do not disappear in a chemical reaction but remain in the substrate, this carbon film may have less tendency to include large unevenness structure formed therein. Accordingly, the roughness of unevenness structure to be formed and the thickness of the carbon film can be controlled by appropriately varying the contents and proportion of Si or other metal elements in the carbon film

For example, an amorphous carbon film containing metal elements such as Si or Ti may also be suitably used as a substrate adhesion layer for ensuring adhesion to a metal substrate. An amorphous carbon film containing Si and oxygen may have a high transparency. Such amorphous carbon films may be previously formed on a substrate as an underlying layer or a substrate adhesion layer; and on this amorphous carbon film, a carbon film having rough unevenness structure and a high light transmittance in which the portions at the recesses are removed or thinned may be formed for applications requiring light transmittance or good design.

The amorphous carbon film containing metal elements such as Si or Ti may tend to include various functional groups such as hydroxyl groups formed in the surface layer thereof by application of oxygen plasma, and thus can be used as a film for fixing a film or substance composed of a coupling agent for forming hydrogen bonds and covalent bonds by a condensation reaction with the hydroxyl groups.

In an embodiment, an amorphous carbon film containing Si for example may be irradiated with oxygen plasma or nitrogen plasma so as to form functional groups such as carboxyl groups (—COOH) or hydroxyl groups (—OH) in the surface layer of the amorphous carbon film. When H+ ions in these functional groups are taken away by the hydroxide ions (OH—) present in an alkaline liquid, negatively ionized —COO— groups and —O— groups may be generated in the surface layer of the amorphous carbon film, and therefore, the surface layer of the amorphous carbon film may be negatively charged That is, the zeta potential of the surface layer of the carbon film may be biased toward the negative side, and the isoelectric point of the carbon film may be shifted toward the acidic region side. Thus, carboxyl groups (—COOH) or hydroxyl groups (—OH) generated in the surface layer of the amorphous carbon film may cause the surface layer of the amorphous carbon film to be negatively charged, thereby restricting adhesion of negatively charged stain such as biomolecules usually negatively charged to prevent autoagglutination thereof in a neutral region, for example, bacteria or proteins.

An amorphous carbon film containing Si and irradiated with oxygen plasma or nitrogen plasma may have higher hydrophilicity and retain the hydrophilicity longer as compared to the surface layer of an ordinary amorphous carbon film composed mainly of carbon or carbon and hydrogen and irradiated with oxygen plasma or nitrogen plasma. Therefore, such an amorphous carbon film can constitute a structure in which water (water film) spreading on the surface layer of the hydrophilic amorphous carbon film can readily ward off or remove stain, particularly in applications where the amorphous carbon film contacts with water. For example, an amorphous carbon film containing Si and oxygen formed on the surface of a stainless steel body (SUS304) having a surface roughness Ra of about 0.04 μm to a thickness of about 100 nm may have a contact angle with water of about 25° to 40°, indicating a high hydrophilicity, and exhibit less deterioration of the contact angle (shift toward water repellence direction) over time. For example, even if the film is left to stand in an environment having a normal temperature, humidity, and pressure with the surface thereof in contact with the atmosphere only, the contact angle with water indicating the hydrophilicity merely increases by about 20° to 30° toward the water repellence direction, still indicating excellent hydrophilicity. This may be because Si in the surface layer of the film tends to form Si—OH (silanol) that provides excellent wettability with water in an oxidative atmosphere such as the atmosphere, and thus the chemical wettability between the film and water can also be retained. Accordingly, the contact angle with water on the surface can be further improved (a high wettability can be obtained initially and retained over time) by applying oxygen plasma to an amorphous carbon film containing Si to form fine unevenness structure, or simultaneously to form a structural hydrophilic surface having unevenness.

Further, when a structure having fine unevenness structure according to an embodiment of the present invention (particularly a carbon film containing Si, Ti, Al, Zr, etc. and having unevenness structure) is constantly or intermittently irradiated with ultraviolet rays, ozone, or oxygen or nitrogen radicals by using an ultraviolet irradiation apparatus, an ozone generation apparatus, or an atmospheric pressure plasma generation apparatus for generating radicals including oxygen or nitrogen, the structure may be provided with structural hydrophilicity produced by the unevenness structure, as well as hydrophilicity produced by functional groups formed on the structure by ultraviolet rays, ozone, or the oxygen or nitrogen radicals and facilitating hydrogen bonding with water, and other hydrophilic functional groups. Therefore, the surface layer of the structure can retain hydrophilicity or super-hydrophilicity for a long period.

For example, when the surface layer of a structure according to an embodiment is irradiated with the emission (ultraviolet rays, deep ultraviolet rays) from a light-emitting diode for emitting ultraviolet rays, an organic material adhering to the surface layer of the structure having fine unevenness structure according to an embodiment and filling the unevenness structure can be dissolved and removed. As a result, it may be possible to continuously provide hydrophilic functional groups and a high chemical wettability with water to the surface layer of the structure according to an embodiment.

More specifically, the structure according to an embodiment may have such a thickness and composition that can transmit light and may be applied to a surface layer of a camera lens of a surveillance camera that needs to be restricted from fogging for obtaining surveillance images constantly, a surface layer of a cover for protecting such a lens, and a surface layer of a mirror, a see-through glass or film, a screen or screen cover of an electronic display, and then the structure may be irradiated with ultraviolet rays from a LED. In this case, the structure having fine unevenness structure according to an embodiment of the present invention, or particularly an amorphous carbon film containing Si may be irradiated with ultraviolet rays so as to improve the deterioration resistance of the structure itself against ultraviolet rays, as compared to the case where an amorphous carbon film composed of carbon or carbon and hydrogen and not containing Si is irradiated with ultraviolet rays.

The carbon film in an embodiment may have laminated structure including different layers (e.g., layers difficult to have large unevenness structure formed therein) such as an amorphous carbon film containing Si or metal elements in addition to the above amorphous carbon film composed of carbon or carbon and hydrogen, multilayer structure including multiple various carbon films described above, or single-layer and multilayer structure in which the contents of the elements such as Si or metal elements contained in the carbon film are varied gradationally (e.g., in the thickness direction).

In the surface of the carbon film according to an embodiment, a portion containing Si or metal elements (which is difficult to include large unevenness structure formed therein) other than the portion composed of carbon or carbon and hydrogen may be formed previously by a known patterning technique and then irradiated with a plasma of oxygen and/or Ar to form unevenness structure that corresponds to the composition of the surface of the carbon film (the portion composed of carbon or carbon and hydrogen and the portion containing Si or metal elements). Further, in the carbon film having the multilayer structure containing different substances or the gradation structure, the shape of the unevenness sectioned in the thickness direction of the unevenness structure formed by applying a plasma of oxygen and/or Ar can be readily varied in accordance with the multilayer structure or the gradation structure. The carbon film containing Si or metal elements may have less tendency to lose thickness upon irradiation with a plasma of oxygen and/or Ar, and thus can be used as the first adhesion layer on a substrate, an intermediate layer at any position in the carbon film having the multilayer structure, or the uppermost layer in the carbon film. As a result, the reduction in the thickness due to irradiation with a plasma of oxygen and/or Ar can be restricted.

The fine unevenness structure in the surface of the carbon film according to an embodiment may be relatively large when formed by irradiation mainly with a plasma of oxygen, and may be relatively small when formed by irradiation with a plasma of Ar. Accordingly, in an embodiment, relatively large unevenness structure may be first formed by irradiation mainly with a plasma of oxygen, and then relatively small fine unevenness structure may be formed on the surface layer of the large unevenness structure by irradiation with a plasma of Ar. For the irradiation of a plasma including an inert gas such as oxygen or Ar, it may be possible to use, for example, a plasma of the atmosphere, a gas including oxygen gas and other elements such as nitrogen mixed therewith, and a gas including Ar gas and other gases such as hydrogen gas and nitrogen gas mixed therewith. For example, a plasma of a gas including Ar gas and nitrogen gas mixed therewith may be applied so as to form fine unevenness structure in the carbon film and nitride the substrate to produce various functional groups in the surface layer of the carbon film.

The relatively large unevenness structure produced by oxygen plasma may be achieved by irradiating the carbon film with, e.g., ultraviolet rays having energy that can activate oxygen in the atmosphere (applying radicals of oxygen) so as to form active oxygen on the surface layer of the carbon film and cleave the chain of carbon. In addition, the relatively large unevenness structure may also be achieved by applying active oxygen of ozone, etc., or by oxidizing the carbon film with a laser beam (in particular, a laser beam with oxygen gas as an assist gas). Also, other possible methods may include using atmospheric-pressure plasma, supplying active oxygen by corona discharge, and heating. Further, the unevenness structure can also be formed by applying a plasma of a known gas including fluorine (e.g., applying a plasma of CF4); but, it may be preferable to use a plasma of oxygen or Ar in consideration of environmental impacts, safety and loads on the apparatuses.

The carbon film having the fine unevenness structure according to an embodiment thus formed may simultaneously have the surface thereof chemically modified; and therefore, for example, the wettability with water in the surface may be further improved, and the activity of the surface layer may be further improved by formation of functional groups or open bonds of carbon, thereby further improving the hydrophilicity of the surface in combination with the structural hydrophilicity caused by the fine unevenness structure. Additionally, the structural hydrophilicity may make it possible to continuously exhibit the hydrophilicity in a stable manner as long as the physical shape is retained, as opposed to the chemical surface modification that tends to lose effects thereof over time.

If the surface layer of the unevenness structure is hydrophobized by applying a plasma of a gas containing fluorine (e.g., CF4) while maintaining the fine unevenness structure, inverse capillary action caused by the fine unevenness structure may restrict penetration of water into the recesses in the unevenness structure in combination with the chemical water repellence of the surface, and thus the recesses may include the air (having a contact angle with water of 180°) to produce structural water repellence, thereby further improving the water repellence of the surface.

For example, as the diameter of the recesses in the fine unevenness structure having a hydrophilic surface is smaller, the recesses may have a larger pressure difference from the outside air pressure, causing water to condense at a vapor pressure lower than the saturated vapor pressure. Accordingly, the recesses may tend to retain or be filled with water formed from vapor by capillary condensation. As a result, the recesses in the unevenness structure filled with water may have wettability with water close to 0°, and thus the structure according to an embodiment may tend to exhibit a high wettability with water. In other words, the carbon film (not having fine unevenness structure) hydrophilized by a surface modification process using a plasma may be provided with further structural hydrophilicity produced by the fine unevenness structure. Therefore, the recesses in the unevenness structure may normally retain some water (water film), depending on the humidity and the temperature.

The structure according to an embodiment having, on the surface thereof, the carbon film retaining water in the recesses of the unevenness structure may provide a surface of a fuel cell separator (expand metal) with a high drain efficiency produced by high hydrophilicity to improve the efficiency of the fuel cell. The structure can be used to prevent fogging on the surface of a glass, mirror, or film that can degrade visibility with fogging, and can prevent adhesion of organisms or stains because of the water layer on the surface thereof. For example, the structure can be used in a microchip as a layer for preventing adhesion of biological samples or stains to the surface of a microchannel for supplying liquid samples. In this case, the structure can facilitate spreading of the liquid samples for better loading.

The fine unevenness structure in the surface of the carbon film may be suitable for applications, e.g., as a carrier for various catalysts or ions (e.g., a carrier for an active material in electrodes of a cell) that requires a large surface area or as a point contact with an external solid such as a surface of an actuator. When used in water, a lubricant for a power transmission mechanism (e.g., a friction plate of a clutch or a torque converter), or a solution containing an additive such as a surfactant, it may be possible to retain water, oil, or the solution effectively in the recesses of the unevenness structure and prevent galling in a slide member due to lack of an oil film.

Further, the unevenness structure can be used for various applications such as for retaining substances entering the recesses in the unevenness structure (e.g., for collecting and keeping a finger print), and protecting the substances entering the recesses against external stresses, preventing reflection of light entering the recesses, and augmenting hydrophilicity by modifying the wettability to be hydrophilic in the surfaces of a fixing surface with a wedge effect produced by a physical anchor-binding adhesive entering the recesses in the unevenness structure and fixed, a structure for improving a frictional force such as an actuator, an anti-fogging film, an ink-supplying channel in an ink-jet nozzle, a capillary, or a microchannel.

Further, the fine unevenness structure in the surface of a carbon film according to an embodiment, which may have a large surface area, can enlarge the surface area of other films or additives formed on the surface of the fine unevenness structure. Therefore, the fine unevenness structure can also be used effectively as a base material, carrier, or container for the other films or additives. Also, it can be used effectively for obtaining a contact area of the carbon film (or various reaction films that can be formed on the carbon film) with external objects. For example, a photocatalyst film made of titanium dioxide, zinc oxide, etc. may be formed on the surface layer of the carbon film to an appropriate thickness, while maintaining (retaining) the unevenness structure (a large surface area) of the carbon film in a predetermined region, so as to further reinforce the hydrophilicity with the structural hydrophilicity produced by the fine unevenness structure and the excellent hydrophilicity of the photocatalyst, providing the surface of the structure with abilities to prevent adhesion of stain, bacteria, and organisms and to dissolve organic substances by the photocatalyst.

Since a photocatalyst may exhibit less hydrophilicity in an environment having a less amount of light (ultraviolet rays), addition of the structural hydrophilicity may make it possible to exhibit hydrophilicity produced by the unevenness structure in a predetermined range under the darkness or visible light. Further, transparency may be obtained by forming another thin film containing SiOₓ for exhibiting hydrophilicity on the carbon film according to an embodiment. Additionally, the carbon film can be used as a light receiver having a large surface area on a photovoltaic semiconductor film such as amorphous Si.

The structure according to an embodiment can also be used as a primer layer for a fluorine-containing coupling agent. The carbon film composed of carbon or carbon and hydrogen formed on a substrate may be irradiated with a plasma of oxygen and/or Ar such that the surface of the carbon film may have various functional groups such as hydroxyl groups formed therein and may be activated by open bonds of carbon. Therefore, the surface of the carbon film may exhibit hydrophilicity and may have increased ability of binding to a coupling agent capable of forming, with the substrate, hydrogen bonds or —O-M bonds (M is any one element selected from the group consisting of Si, Ti, Al, and Zr) by condensation reaction. Accordingly, other functional films can be fixed well via the coupling agent. It may also be possible to fix a film made of a coupling agent and previously provided with a function effectively, stably, and firmly by a chemical bond. Examples of such a film may include a very thin film (having less ability to flatten the surface layer of the structure by filling the recesses of the unevenness structure formed) composed of a fluorine-containing coupling agent and having water and oil repellence.

When the structure according to an embodiment is used as a primer layer for a fluorine-containing coupling agent, the film composed of the fluorine-containing coupling agent and having a thickness of about 10 to 20 nm, as described above, may contain much fluorine in the surface layer thereof and thus can provide the substrate with a strong water repellence. Also, this film may have an excellent shock absorbing quality and corrosion resistance as a resin film, but may be susceptible to external frictional stresses because it is formed of a resin. The film composed of a fluorine-containing coupling agent and having water repellence or water and oil repellence may be formed in the recesses in the unevenness structure in the carbon film according to an embodiment to protect the film against external stresses such as friction. Accordingly, the ten point average roughness (Rz) of at least part of the unevenness structure in the carbon film according to an embodiment should preferably be at least about 20 nm or larger.

If the unevenness structure in the carbon film according to an embodiment is made larger, the unevenness structure may be more likely to be retained even after the layer composed of the fluorine-containing coupling agent is formed, and may provide the structure with structural water repellence or water and oil repellence. On the other hand, if the unevenness structure is extremely fine, no substance can be contained or formed in the recesses in the unevenness structure, and thus the unevenness structure may be practically equivalent to a mere smooth surface. Accordingly, the ten point average roughness (Rz) of the unevenness structure in the carbon film according to an embodiment, indicating the surface roughness of at least a part thereof, may be at least 20 nm or larger, more preferably 40 nm or larger, or still more preferably 150 nm or larger.

As described above, with the unevenness structure having a certain depth or more, a hydrophilic substrate can have a low saturated vapor pressure at the recesses in the deep unevenness structure and retain water formed from vapor by capillary condensation, along with other synergy effects. Accordingly, when a portion of the unevenness structure of a carbon film according to an embodiment is provided with a fluorine-containing coupling agent to have water repellence or water and oil repellence and the other portion is left as it stands, the surface may simultaneously have the hydrophilicity and the water repellence (or water and oil repellence) produced by the unevenness structure and having augmentation effect and durability. With an amorphous carbon film for example, which also has oil repellence, the surface can simultaneously have oil repellence and oleophilicity.

Further, it may be further effective to form another layer on the carbon film having the above unevenness structure or fill the recesses in the unevenness structure with other substances (it has already been described that water formed from vapor by capillary condensation can be retained in the recesses). For example, it may be effective to form an amorphous carbon film composed of carbon and hydrogen and having less reactiveness to outside, on a carbon film including the unevenness structure having activity and functional groups. Such a film may be necessary for applications where wettability of a substrate should not be varied largely, for example, surface treatment of a printing stencil. For example, a gravure printing plate may usually include a hard chrome plating film having hairlines (unevenness) formed in the surface thereof and, if provided with the unevenness structure according to an embodiment, may implement point contact with a doctor blade for scraping off an ink. However, in view of the quality of transferring an ink, the surface of the gravure printing plate may preferably have a wettability close to that of the conventional hard chrome plating film so as not to change the conventional printing conditions (the wettability between an ink and a plate). In this case, an ordinary amorphous carbon film composed of carbon and hydrogen, which exhibits a wettability with water close to that of the above hard chrome plating film, may be suitable in view of loading of an ink into a patterning portion of a gravure and transferring of the ink onto a printing sheet. A printing stencil for screen printing may be required to have appropriate water repellence and hydrophilicity on the squeegeed surface side to be supplied with an ink in view of loading of the ink into a pattern opening and cleaning after printing (that is, a highly water-repellent surface repelling water with excessive strength may degrade the quality of loading an ink into a pattern opening and cause catching of air bubbles during squeegeeing of the ink which may produce blurring of printing). Further, if an amorphous carbon film containing Si or an amorphous carbon film containing Si and further containing oxygen and/or nitrogen (in particular, an amorphous carbon film containing Si and further irradiated with a plasma of oxygen and/or nitrogen) is formed on a carbon film having unevenness structure, such an amorphous carbon film can form an upper layer having functionality via a coupling agent having a high fixing performance. The coupling agent may be capable of forming hydrogen bonds or —O-M bonds (M is any one element selected from the group consisting of Si, Ti, Al, and Zr) by condensation reaction. If the coupling agent contains a water- and oil-repellent element such as fluorine, the film thereof may have a thickness of about 10 to 20 nm so as to constitute a structural water- and oil-repellent layer formed in conformity to the unevenness structure of the carbon film such that the unevenness structure is left unfilled, thereby forming a structure that can exhibit excellent water and oil repellence.

Examples of the films that can be fixed well via the coupling agent capable of forming hydrogen bonds or —O-M bonds (M is any one element selected from the group consisting of Si, Ti, Al, and Zr) by condensation reaction may include a sputtering film containing Si, Ti, Al, or Zr, or an oxide or nitride of the foregoing elements, and a film containing any one of the foregoing elements and further irradiated with a plasma of a polar element such as oxygen or nitrogen, in addition to the amorphous carbon film containing Si. Further, it may be likewise possible to fix a coupling agent such as the above fluorine-containing coupling agent on these films.

A famous example of natural superhydrophobic surfaces may be “lotus leaves.” The surface of a lotus leaf may include micro unevenness structure having projections with thicknesses of 5 to 9 μm constituting large unevenness, and nanometer scale unevenness having a width of about 124 nm and formed in the surface layer of the tip ends of the projections in the unevenness. The contact angle with water of the surface of a lotus leaf is known to be 161° (the superhydrophobic effect produced by artificial unevenness is called “lotus effect”). A known example of superhydrophobic surface substance having artificial superhydrophobicity may be AKD (alkyl ketene dimer), a wax which spontaneously forms superhydrophobic structure constituted by “fractal structure” including large unevenness structure on a micro scale and small unevenness structure on a nano scale in the surface layer of the micro scale unevenness structure. The contact angle with water of AKD is known to be about 174°.

A known example of an artificial surface similar to the surface of “a lotus leaf” may include microscale projections constituted by bundles of CNTs (carbon nanotubes) having an average diameter of about 3 μm, and fine nanoscale projections in the end surfaces of the bundles of CNTs formed of the ends of the individual CNTs having diameters of about 30 to 60 nm in the end surfaces of the bundles of the CNTs (microscale unevenness). This surface may have a contact angle with water of about 164°. In forming the microscale unevenness structure and the nanoscale unevenness structure artificially, the microscale unevenness structure can be readily formed by various known methods.

A method of forming the microscale unevenness structure in an amorphous carbon film may include, for example, placing on a substrate a metal mesh having openings with a diameter of about 20 to 30 μm and fiber threads with a diameter of about 15 to 25 μm, forming an amorphous carbon film with the mesh serving as a mask, and then removing the mesh. This method may produce unevenness structure (segmented structure) including projections having a thickness (size) of about 20 to 30 μm equal to the diameter of the openings of the mesh, arranged regularly on the substrate at intervals of 15 to 25 μm equal to the diameter of the fiber threads. Another method may include patterning a substrate with a photosensitive resin in a mesh-like form by a known photolithography method, forming an amorphous carbon film, and removing the photosensitive resin. This method may produce unevenness structure (segmented structure) on the same principle as the above method using a mesh.

Further, the unevenness structure can also be formed by previously forming unevenness structure in a substrate using a known electrotyping technique (electroforming substrate) and then forming an amorphous carbon film on the surface layer of this substrate. However, these methods may be defective in productivity and costs for forming the above-described “nanoscale unevenness structure” in a reproducible manner.

By contrast, the embodiment may permit forming of nanoscale unevenness structure in a reproducible manner only by irradiating a carbon film having microscale unevenness structure with a plasma of oxygen and/or Ar. Further, after a carbon film is uniformly formed on the surface layer of a substrate, an etching mask layer may be formed of a photosensitive resin on the carbon film by a known photolithography method in a reverse pattern of the unevenness structure to be formed, and the portion not covered by the etching mask layer may be subjected to, e.g., an oxygen plasma process, such that microscale unevenness structure may be formed of carbon protected by the etching mask layer and remaining after the process and, when the carbon film is removed by oxygen plasma, nanoscale unevenness structure may be formed in sections or bottoms of the recesses in the microscale unevenness structure. Still further, a plasma of a hydrophobic substance such as fluorine may be applied, or a film composed of a fluorine-containing coupling agent may be provided, such that the surface layer of the unevenness structure may be chemically hydrophobic.

In an embodiment, an amorphous carbon film containing Si exhibiting a strong chemical hydrophilicity and having an ability to spontaneously form hydroxyl groups upon contacting outside moisture or oxidative atmosphere may be formed on an amorphous carbon film having unevenness structure and structural hydrophilicity produced thereby, while maintaining the underlying unevenness structure. To introduce Si into the amorphous carbon film, a hydrocarbon-based material gas containing Si such as trimethylsilane may be used in a process of forming the amorphous carbon film. In forming an amorphous carbon film including Si and oxygen, a hydrocarbon-based material gas containing Si such as trimethylsilane may be mixed with oxygen or a gas containing oxygen (e.g., CO₂) at a ratio for avoiding an explosion, and an amorphous carbon film including Si may be previously formed and then irradiated with a plasma of oxygen or a gas containing oxygen, thereby preventing explosion caused by mixing introduction of oxygen-based gas into the hydrocarbon-based gas, enabling a large amount of oxygen to be safely included in the amorphous carbon film, and enabling a larger amount of functional groups (—OH, etc.) to be formed on the surface of the amorphous carbon film than in the case without irradiation with oxygen plasma.

Also, the amount of oxygen introduced can be more readily adjusted than in the case where a hydrocarbon-based material gas previously including oxygen and Si is used to form an amorphous carbon film including Si and oxygen. The amorphous carbon film containing Si and irradiated with a plasma of nitrogen or a gas containing nitrogen and oxygen may also exhibit strong hydrophilicity in the surface thereof. In combination with the structural hydrophilicity produced by the unevenness in the underlayer, the surface may have further reinforced hydrophilicity. Further, the amorphous carbon film containing Si may be irradiated with a plasma containing oxygen, a plasma containing nitrogen, or a plasma containing oxygen and nitrogen such that the interface portion thereof tightly adhered to the underlayer including the unevenness structure remains an amorphous carbon film containing Si providing high adhesiveness, while the surface layer portion serving as a functional interface with outside and not required to have adhesiveness with the underlayer may become an amorphous carbon film containing Si and including large amounts of oxygen and nitrogen, introduced by high energy plasma irradiation, and the functional groups mentioned above. In an embodiment, the amorphous carbon film including Si may be irradiated with oxygen plasma such that transparency (optical transparency) of the portion into which the oxygen is introduced can be increased (e.g., the total light transmittance of the structure may be increased to 80% or more) while keeping the ductility and the adhesiveness with the underlayer of the amorphous carbon film.

The structure according to an embodiment may include a carbon film having fine unevenness structure in the surface thereof. If, for example, the carbon film is formed on a transparent or translucent (light transmissive) substrate, the unevenness structure may have sparse projections or a smaller thickness under the recesses so as to readily secure light transmittance, while providing the structure with water repellence or hydrophilicity, wear resistance, and low friction. The carbon film having such light transmittance may be formed for surface treatment of a channel or capillary of an analysis apparatus for analyzing a liquid sample such as μ-TAS, or surface treatment of a resin film or glass required to have transparency.

Further, the recesses in the fine unevenness structure formed in an insulating amorphous carbon film may retain an electrically conductive carbon material (e.g., powder such as acetylene black) so as to provide the amorphous carbon film with electric conductivity, and the recesses in the unevenness structure may include a coloring matter such as anodized aluminum for coloring so as to vary the color tone. For frictional or wearing applications, the recesses in the unevenness structure may retain a lubricant such as molybdenum disulfide grease so as to significantly reduce the frictional resistance. In this case, the recesses in the unevenness structure of the amorphous carbon film having a high hardness may be filled with other films or substances so as to further strengthen the unevenness structure against external stresses. Such unevenness structure can also protect the films and substances filled in the recesses in the unevenness structure. Further, an amorphous carbon film or other known hard film having a higher hardness may be stacked on the unevenness structure in the amorphous carbon film so as to maintain and even reinforce the unevenness structure. Further, other functional films or supported matter can be provided on the unevenness structure. Further, other various films can be stacked on the unevenness structure. Examples of such films may include films composed of electrically conductive carbon such as graphite, fullerene, and CNT, films produced by known dry processes, and metal films produced by wet plating.

Further, if the unevenness structure is formed only in a portion of the thickness of the surface layer of the amorphous carbon film, the amorphous carbon film can appropriately retain the functions thereof such as tight adhesion to the substrate, UV absorbing ability, and ductility.

### EXAMPLES

### 1. Observation of Unevenness Structure in the Surface of the Carbon Film Preparation of a Sample

A necessary number of rectangular plates 2 cm wide and 2 cm long (about 0.625 mm thick) were cut out from a 6 inch Si (100) wafer, to be used as substrates. These substrates were subjected to ultrasonic cleansing using isopropyl alcohol (IPA) and then placed into a reaction container of a known DC-pulsed plasma CVD apparatus such that individual substrates can be subjected to a negative DC voltage. The conditions for applying a pulsed DC voltage in the plasma CVD apparatus were the pulse frequency of 10 kHz and the pulse width of 19 is for all of Examples, Comparative Examples, and Reference Examples.

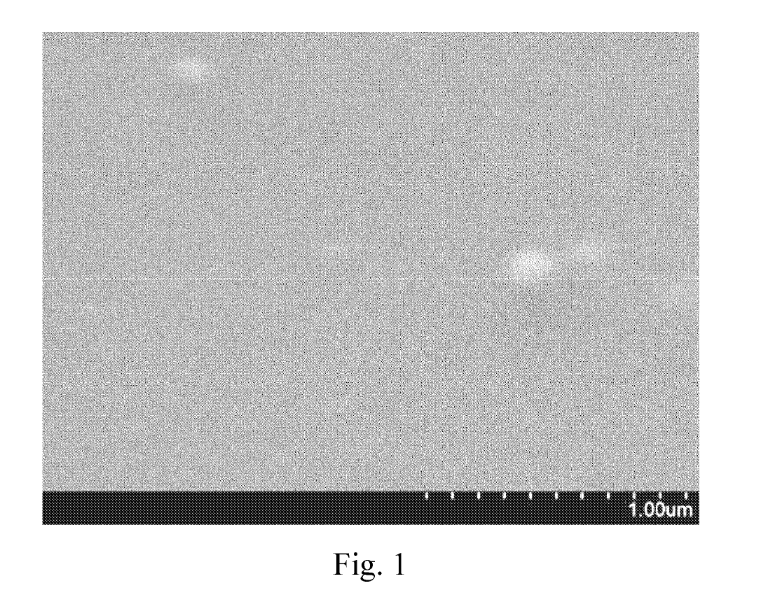

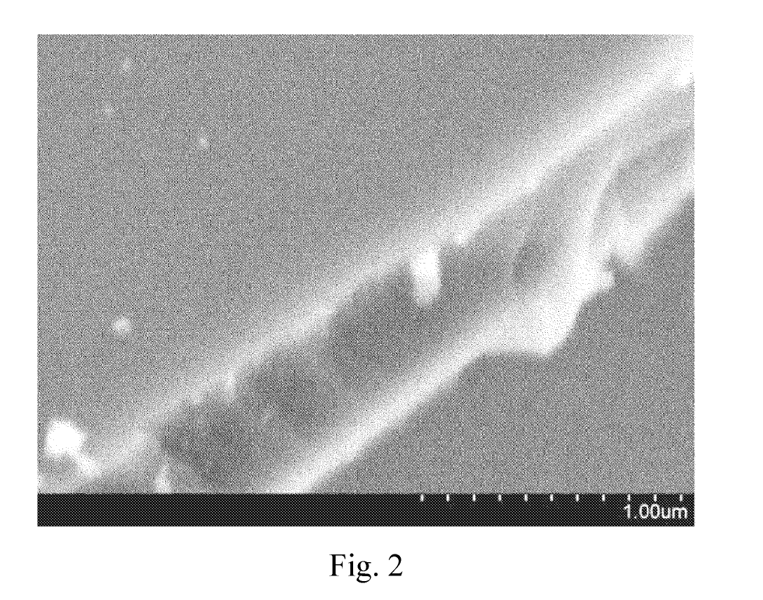

Next, the reaction container containing the Si sample piece was evacuated to 1×10⁻³ Pa, and then Ar gas was introduced into the reaction container at a flow rate of 30 SCCM to a gas pressure of 2 Pa, while applying a voltage of −3.0 kVp to generate Ar plasma for cleaning the surface of the substrate for one minute. Next, the reaction container was evacuated of Ar gas to a vacuum, and then trimethylsilane gas was introduced into the reaction container at a flow rate of 30 SCCM to a gas pressure of 1.2 Pa, while applying a voltage of −4.0 kVp to generate a plasma for forming a substrate adhesion layer composed of an amorphous carbon film containing Si for three minutes. Next, the reaction container was evacuated of trimethylsilane gas to a vacuum, and then acetylene gas was introduced into the reaction container at a flow rate of 30 SCCM to a gas pressure of 2 Pa, while applying a voltage of −4.0 kVp to generate a plasma for forming an amorphous carbon film composed of carbon and hydrogen having a thickness of about 750 nm. Next, acetylene gas was evacuated, and then the reaction container of the plasma CVD apparatus was tentatively returned to a normal pressure. The Si sample piece was taken out of the reaction container and was taken as Comparative Example 1-1. FIG. 1 is an electron microscope photograph of the surface of Comparative Example 1-1 (with a magnification of 50,000). FIG. 2 is an electron microscope photograph of a section of Comparative Example 1-1 (with a magnification of 50,000).

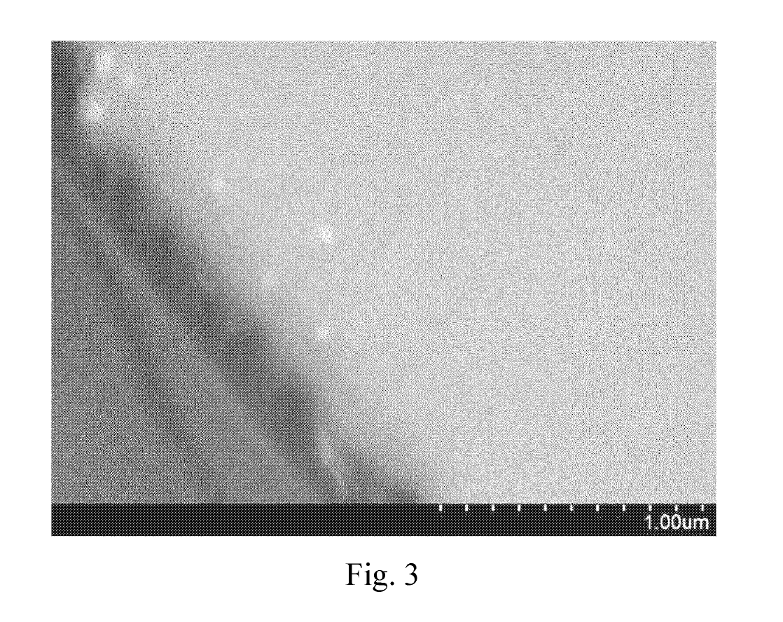

Next, a Si sample piece formed in the same manner as for Comparative Example 1-1 was placed into the reaction container of the plasma CVD apparatus, the reaction container was evacuated to 1×10⁻³ Pa again, and then trimethylsilane gas was introduced into the reaction container at a flow rate of 30 SCCM to a gas pressure of 1 Pa, while applying a voltage of −4.0 kVp to generate a plasma for forming an amorphous carbon film containing Si to a thickness of about 80 nm. Next, trimethylsilane gas was evacuated, and the reaction container was returned to a normal pressure. The Si sample piece was then taken out of the reaction container and was taken as Comparative Example 2. FIG. 3 is an electron microscope photograph of the surface of Comparative Example 2 (with a magnification of 50,000).

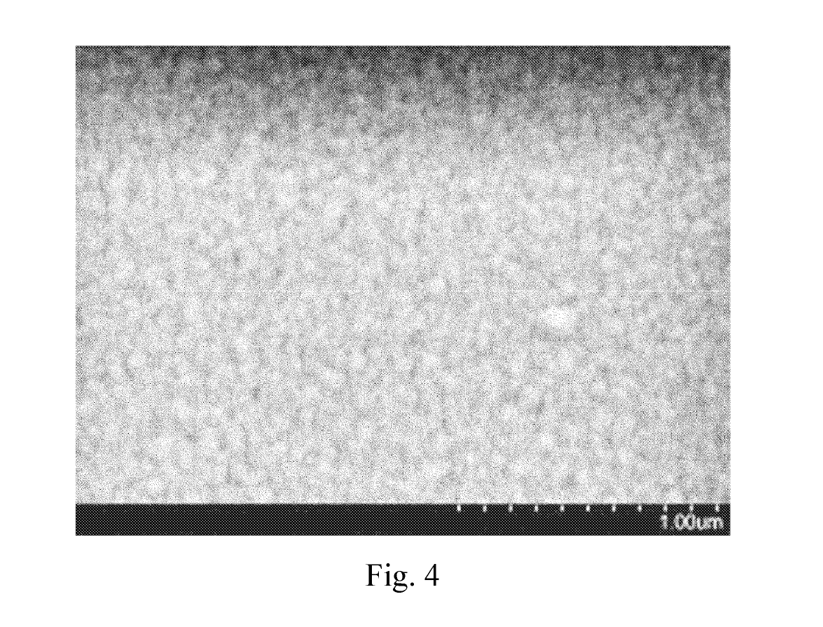

An untreated Si (100) sample piece having a thickness of 0.625 mm was placed into a sputtering apparatus (manufacturer: Unaxis Balzers AG, name: CUBE LITE ARQ131) and subjected to sputtering of a carbon (graphite) target (manufacturer: Kojundo Chemical Laboratory Co., Ltd, name: C200φ×6t, purity: 20 ppm or less of ash) under the film forming conditions of input voltage of 3 kW, sputtering gas Ar, a gas flow rate of 10 SCCM, and film forming time of 200 sec, to from on the Si sample piece a carbon film not containing hydrogen and having a thickness of about 350 nm, which was taken as Comparative Example 3-1. FIG. 4 is an electron microscope photograph of the surface of Comparative Example 3-1 (with a magnification of 50,000). Two same samples of Comparative Example 3-1 were prepared, and one of them was used for observation of the color tone. In this sample of Comparative Example 3-1 for observation of the color tone, a green film was visually observed on the Si (100) substrate, and the color tone of the Si (100) substrate underlying the green film cannot be observed.

Application of a Plasma of Ar and Oxygen

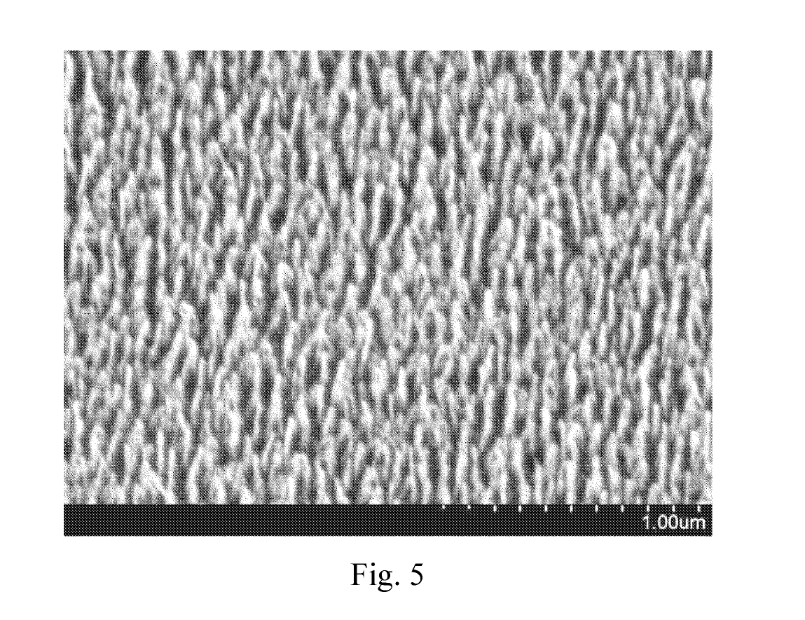

Next, the same sample as Comparative Example 1-1 was placed into the reaction container of the plasma CVD apparatus, the reaction container was evacuated to 1×10⁻³ Pa again, and then a mixture of Ar gas at a flow rate of 40 SCCM and oxygen gas at a flow rate of 70 SCCM was introduced into the reaction container to a gas pressure of 2 Pa, while applying a voltage of −3.5 kV to generate a plasma of the mixture gas of Ar and oxygen which was applied to the substrate for 35 minutes. Next, the mixture gas of Ar and oxygen was evacuated, and the reaction container was returned to a normal pressure. The Si sample piece was then taken out of the reaction container and was taken as Example 1-1. FIG. 5 is an electron microscope photograph of the surface of Example 1-1 (with a magnification of 50,000).

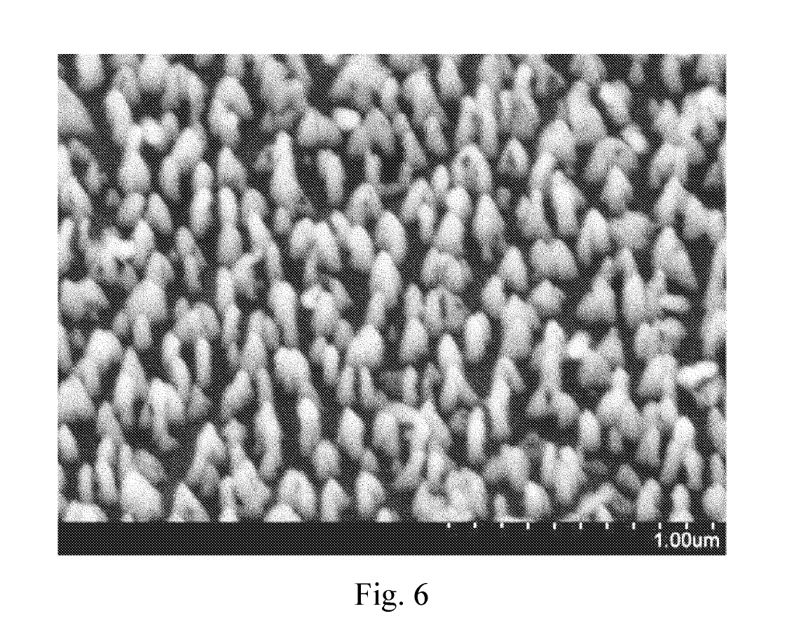

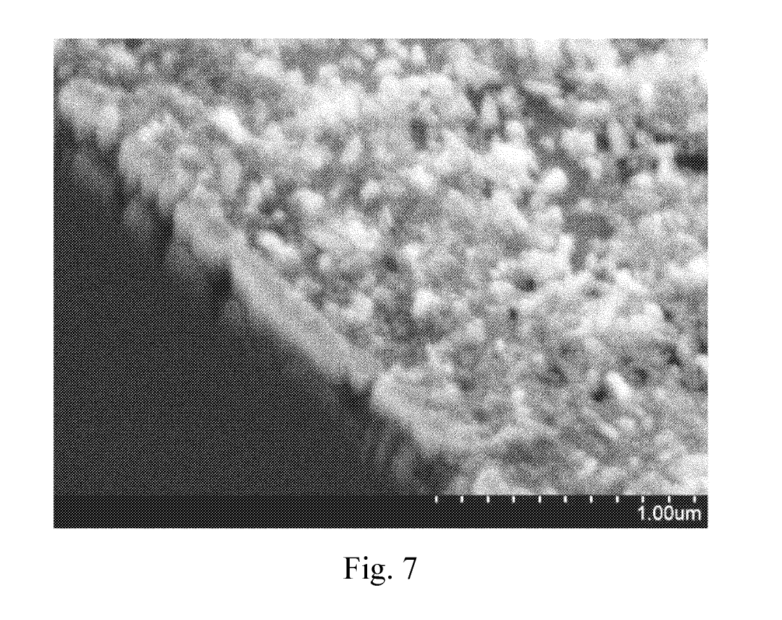

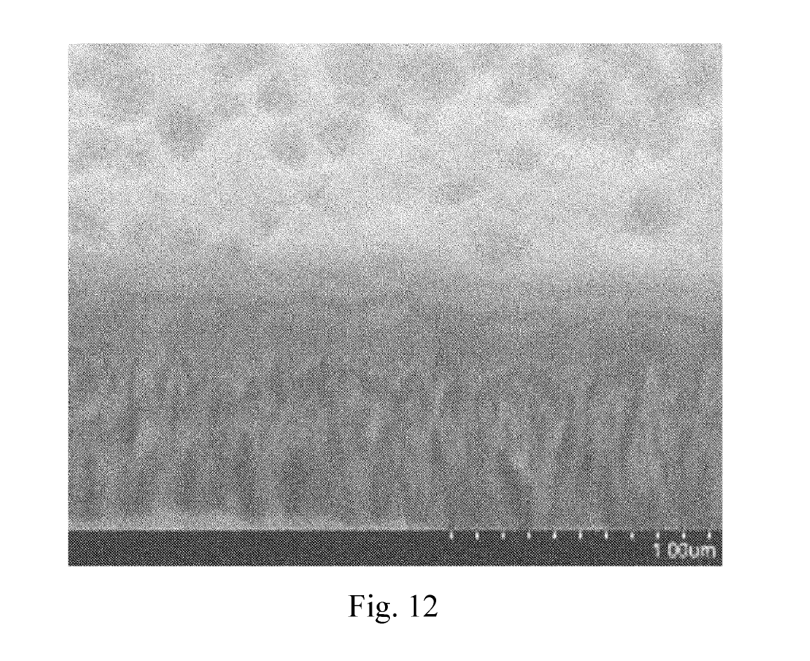

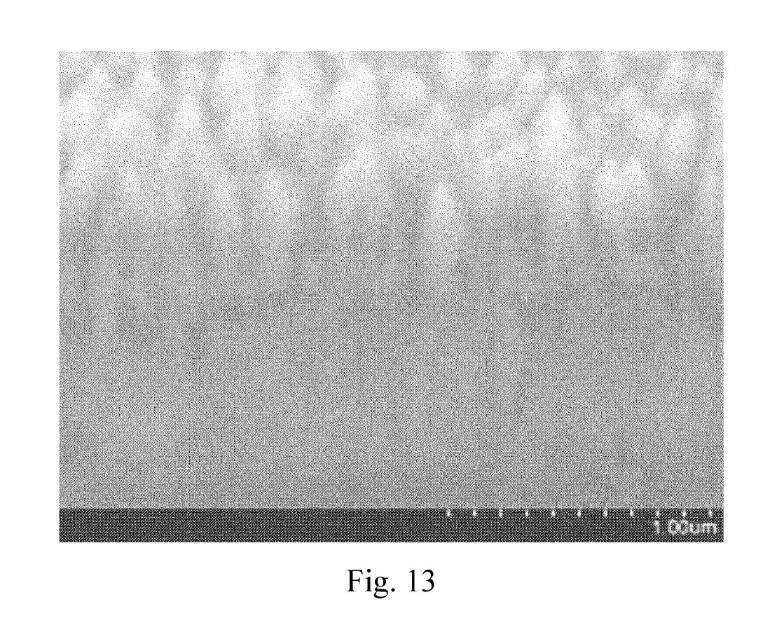

The same sample as Comparative Example 1-1 was irradiated with a plasma of the mixture gas of Ar and oxygen for 125 minutes under the same conditions as for Example 1-1 and was taken as Example 1-2, and the same sample as Comparative Example 2 was subjected to the same treatment and was taken as Example 6. FIG. 6 is an electron microscope photograph of the surface of Example 1-2 (with a magnification of 50,000). FIGS. 7 and 13 are electron microscope photographs of a section of Example 1-2 (with a magnification of 50,000). Further, FIG. 12 is an electron microscope photograph of the surface of Example 6 (with a magnification of 50,000).

Further, to confirm the reproducibility of Example 1-1, another amorphous carbon film was formed on the Si (100) substrate by the same process and under the same conditions as for Example 1-1, and this sample was taken as Example 2.

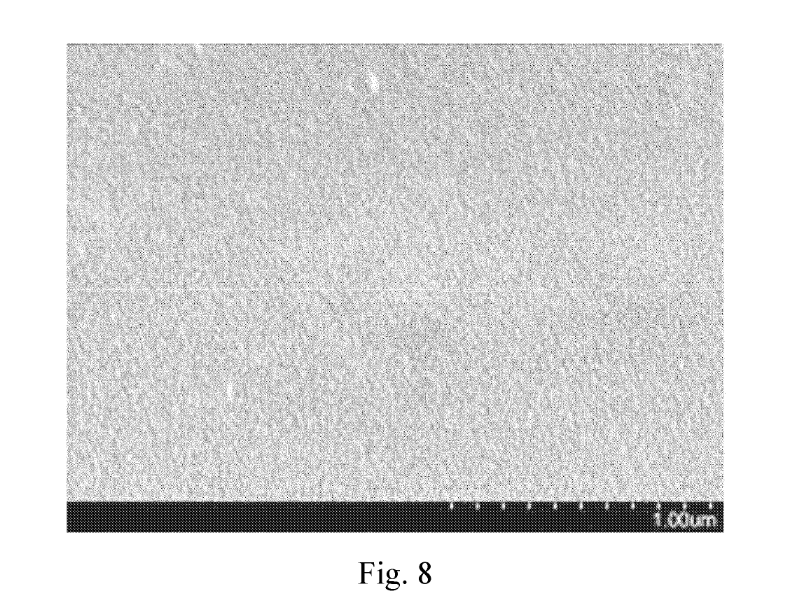

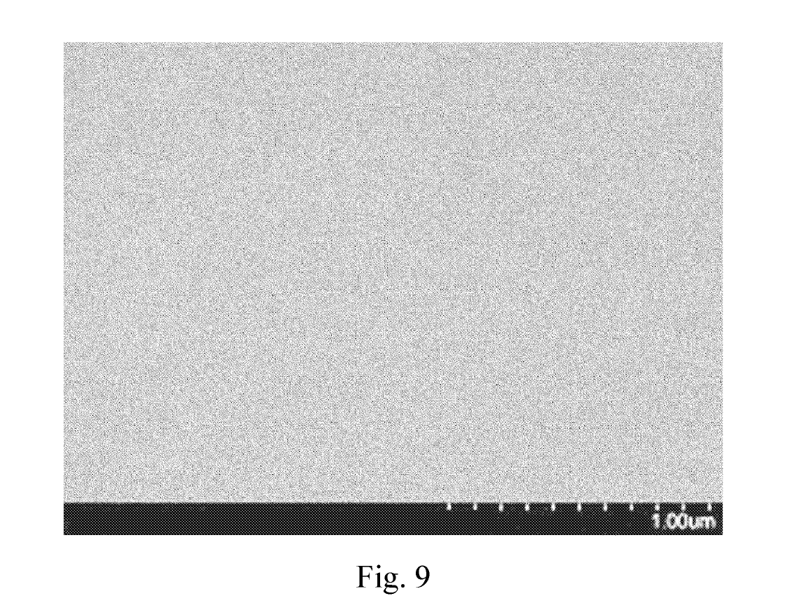

The same sample as Comparative Example 1-1 was irradiated with a plasma of the mixture gas of Ar and oxygen for 11 minutes under the same conditions as for Example 1-1 and was taken as Example 1-3, and another same sample as Comparative Example 1-1 was irradiated with the plasma of the mixture gas of Ar and oxygen only for one minute and was taken as Comparative Example 1-2. FIG. 8 is an electron microscope photograph of the surface of Example 1-3 (with a magnification of 50,000). FIG. 9 is an electron microscope photograph of the surface of Comparative Example 1-2 (with a magnification of 50,000).

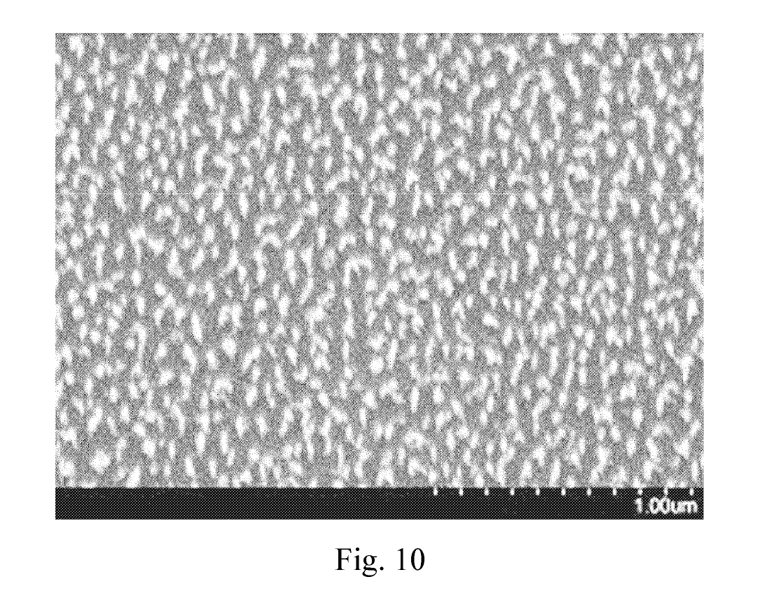

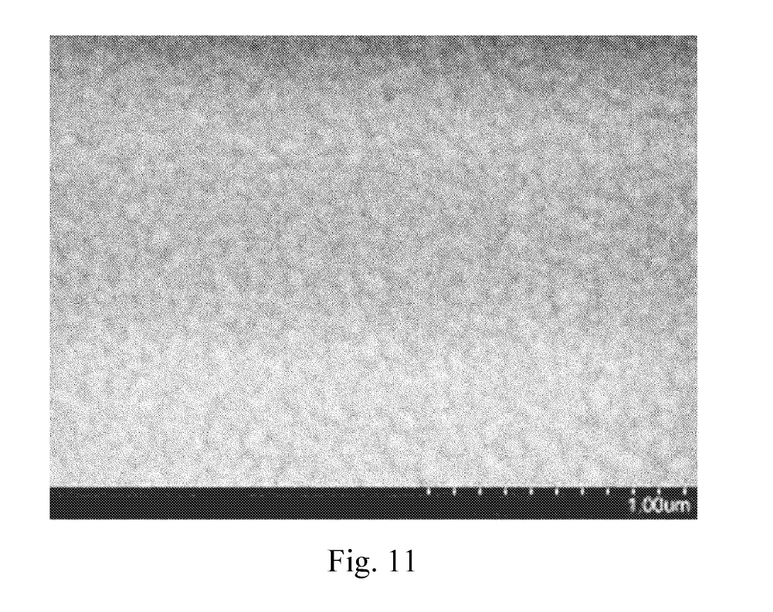

Two same samples as Comparative Example 3-1 were irradiated with a plasma of the mixture gas of Ar and oxygen for 11 minutes under the same conditions as for Example 1-1 and were taken as Example 3 (one of them was used for observation of the color tone), and another same sample as Comparative Example 3-1 was irradiated with the plasma of the mixture gas of Ar and oxygen only for one minute and was taken as Comparative Example 3-2. FIG. 10 is an electron microscope photograph of the surface of Example 3 (with a magnification of 50,000). In one of the samples of Example 3 for observation of the color tone, no green film was visually observed, and the color tone of the underlying Si (100) substrate can be observed. FIG. 11 is an electron microscope photograph of the surface of Comparative Example 3-2 (with a magnification of 50,000).

Application of a Plasma of Ar

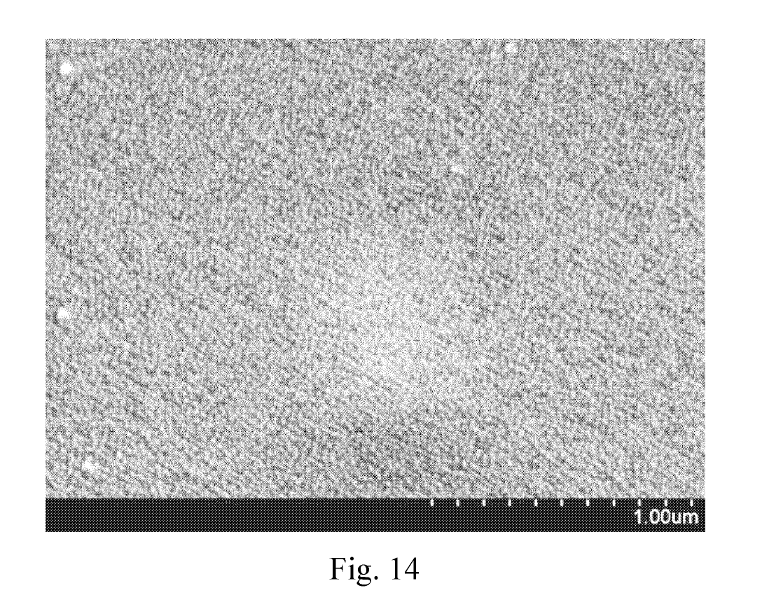

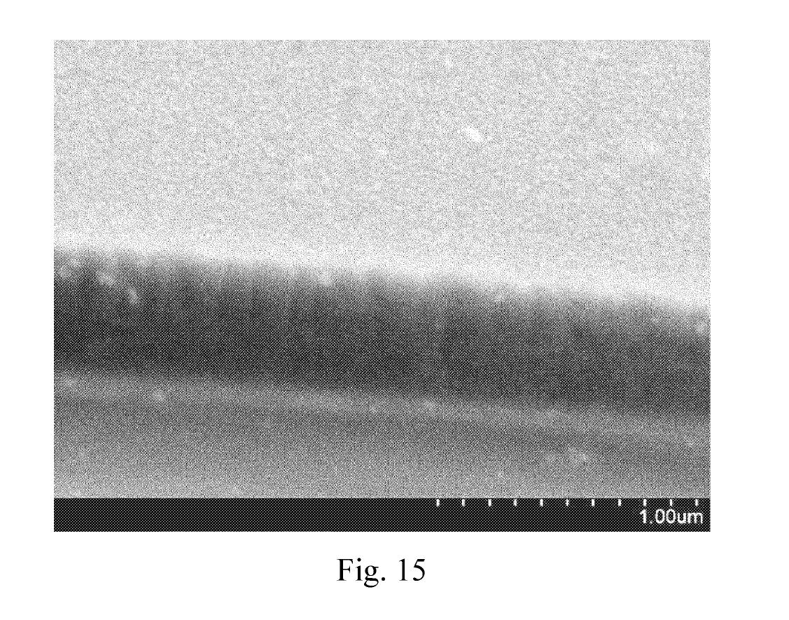

Next, the same sample as Comparative Example 1-1 was placed into the reaction container of the plasma CVD apparatus, the reaction container was evacuated to 1×10⁻³ Pa again, and then Ar gas was introduced into the reaction container at a flow rate of 40 SCCM to a gas pressure of 2 Pa, while applying a voltage of −3.5 kV to generate a plasma of Ar gas which was applied for 35 minutes. Next, Ar gas was evacuated, and the reaction container was returned to a normal pressure. The Si sample piece was then taken out of the reaction container and was taken as Example 4. FIG. 14 is an electron microscope photograph of the surface of Example 4 (with a magnification of 50,000). An uneven shape including projections having a diameter of several nanometers was observed. FIG. 15 is an electron microscope photograph of a section of Example 4 (with a magnification of 50,000).

Application of a Plasma of Oxygen

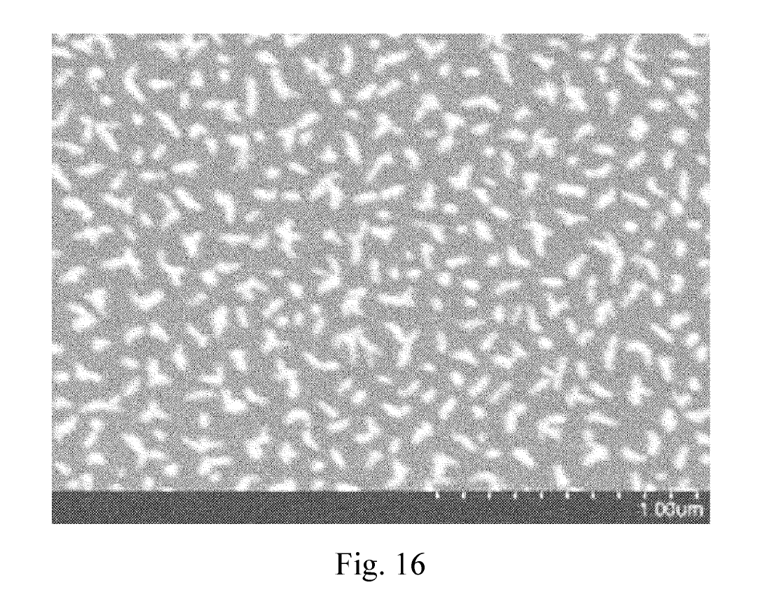

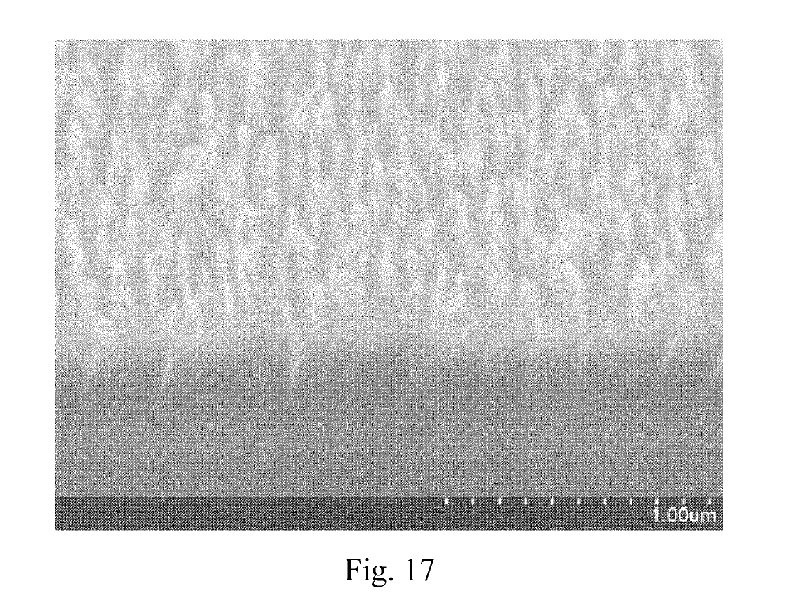

Next, the same sample as Comparative Example 1-1 was placed into the reaction container of the plasma CVD apparatus, the reaction container was evacuated to 1×10⁻³ Pa again, and then oxygen gas was introduced into the reaction container at a flow rate of 70 SCCM to a gas pressure of 2 Pa, while applying a voltage of −3.5 kV to generate a plasma of oxygen gas which was applied for 35 minutes. Next, oxygen gas was evacuated, and the reaction container was returned to a normal pressure. The Si sample piece was then taken out of the reaction container and was taken as Example 5. FIG. 16 is an electron microscope photograph of the surface of Example 5 (with a magnification of 50,000). FIG. 17 is an electron microscope photograph of a fracture section of Example 5 (with a magnification of 50,000).

Observation of Surface Condition

The surface condition of each sample was measured and observed. The measurement instrument used was “FE-SEM SU-70” from Hitachi High-Technologies Corporation. In Example 1 (FIGS. 5, 6, and 8), Example 3 (FIG. 10), Example 5 (FIG. 16), and Example 6 (FIG. 12), it was observed that fine projecting unevenness structure was formed uniformly, which was not observed in the surfaces of the corresponding Comparative Examples.

Further, as can be observed in Examples, the fine unevenness structure was also formed in the outside surface of the carbon film, the interior of the carbon film, and the side surface (end surface) of the carbon film (see FIG. 13).

In Example 3, it was observed that the carbon film not containing hydrogen and composed mainly of carbon can have fine unevenness structure formed therein by application of a plasma of a material gas composed of Ar and oxygen.

It was also observed that, under the same plasma irradiation condition, the unevenness structure is more rough as the duration of plasma irradiation with a material gas composed of Ar and oxygen is longer, and that the region (thickness) of the fine projecting unevenness structure formed in the carbon film can be controlled by adjusting the initial thickness of the carbon film to be etched (prior to the plasma irradiation with a material gas composed of Ar and oxygen) and the plasma irradiation condition.

Further, comparison between Example 1-3 (irradiated with a plasma of a mixture gas of Ar and oxygen), Example 4 (irradiated with a plasma of Ar gas only), and Example 5 (irradiated with a plasma of oxygen gas only) revealed that oxygen gas mainly contributed to forming of relatively large unevenness structure, and Ar gas contributed to forming of relatively small unevenness structure. In Example 4, it was observed that the surface had finer unevenness structure than in other Examples. This suggests the possibility that when the carbon film is irradiated with a plasma of a mixture of at least oxygen gas and Ar gas for a predetermined time at a predetermined energy level, relatively large unevenness structure is formed by application of oxygen gas, and fine unevenness structure is additionally formed by application of Ar gas in the surface layer of the relatively large unevenness structure, thereby enlarging the surface area of the unevenness structure.

In Comparative Example 2, it was observed that the surface was smooth as in Comparative Example 1. However, in Example 6 obtained by irradiating the sample of Comparative Example 2 with a plasma of a mixture gas of Ar and oxygen, it was observed that fine unevenness structure having a crater-like shape with a diameter of about 50 to 100 nm is formed, and that this unevenness structure enlarged the surface area. By contrast, in Example 1-2 obtained by applying a plasma to an amorphous carbon film composed of carbon and hydrogen under the same condition as for Example 6, it was observed from the measurement result of an AFM (atomic force microscope) that the surface roughness (root-mean-square roughness) is extremely larger than in Example 6 and the surface are is also enlarged significantly.

This indicates that formation of unevenness structure by oxygen plasma is restricted in an amorphous carbon film containing a certain amount of element such as Si that forms an oxide upon irradiation with oxygen plasma and remains in the film. It is also suggested that the surface roughness can be controlled by adding adjusted amount of Si or metal elements into a carbon film composed of carbon or carbon and hydrogen.

More specifically, due to irregular distribution of Si (which tends to chemically react with oxygen and not to gasify and disappear) in the surface layer and interior of an amorphous carbon film, etching proceeds in the portion containing more carbon (and less Si) which tends to disappear upon oxygen etching, while in the portion containing more Si, an oxide of Si produced as a byproduct of oxygen etching remains and deposits so as to inhibit oxygen etching, thereby to form the observed unevenness having a crater-like shape with a diameter of about 50 to 100 nm.

The crater-shaped unevenness structure is very useful to obtain surface area for increasing or reducing the wettability with a liquid such as water and retain, in the recesses of the unevenness structure, substances having an extremely poor wettability with water such as the air. As described above, since the pressure difference from the outside air pressure is large in the fine recesses, condensation of water tends to begin at a vapor pressure lower than the saturated vapor pressure. Accordingly, the recesses may tend to retain or be filled with water formed from vapor by capillary condensation. As a result, the recesses in the unevenness structure filled with water may have wettability with water close to 0°, and thus the structure according to an embodiment may tend to exhibit a high wettability with water. Additionally, since the surface layer has the crater-shaped unevenness, external stresses such as friction can be received only by the projections in the unevenness, and the portions of the surface layer constituting the recesses can be separated from external physical forces or protected by reducing the stresses.

As described above, it was observed that the surface layer of the amorphous carbon film in Examples formed by the above method had fine unevenness structure. More specifically, as is obvious from the sections in Examples, the projections in the fine unevenness structure in the surface layer extend to the surface layer or the interior of the films of Examples. This indicates that after an amorphous carbon film is formed, a plasma of a large amount of oxygen gas, Ar gas, or a mixture of these gases can be applied at a high energy level so as to form fine unevenness structure in the surface layer of the amorphous carbon film without degrading the tight adhesion thereof to the substrate.

In the sample of Example 3 (obtained by irradiating a carbon film not containing hydrogen with a plasma of a mixture gas of Ar and oxygen for 11 minutes) for observation of the color tone, no green film was observed which was visually observed initially (in Comparative Example 3-1), and the color tone of the underlying Si (100) substrate was observed. The thickness of the film of Example 3 is about 20 to 30 nm at the recesses in the unevenness structure. An ordinary carbon film formed as a continuous film having a thickness of 20 to 30 nm is recognized as a light-brown film. Observation of the electron microscope photograph suggests that the carbon film having the unevenness structure remains in the surface layer of the sample, and the coverage of the projections having a large thickness in the unevenness structure of the remaining film is significantly reduced, which increases the light transmittance.

Measurement of Surface Roughness

Each of Comparative Examples and Examples was measured for the surface roughness (root-mean-square roughness (Sq) and ten point average roughness (Rz)) and the surface area (S3A). The measurement was performed using an atomic force microscope (AFM). The measurement conditions (planar measurement) of the root-mean-square roughness (Sq) and the surface area (S3A) include a scan size of 5.0 μm and a scan rate of 0.3 Hz. The measurement result was as follows. The “ten point average roughness (Rz)” is prescribed in JIS B0601(1994). The actual measurement values of the surface roughness of the Si wafer substrate Si (100) commonly used herein as a substrate for Examples and Comparative Examples were as follows.

### Wafer Substrate Si (100)

root-mean-square roughness: 0.0814 (Sq, nm)

ten point average roughness: 2.57 (Rz, nm)

surface area: 25,000,000 nm² (S3A, nm²)

Comparative Example 1 (C+H, untreated)

root-mean-square roughness: 0.633 (Sq, nm)

ten point average roughness: 11.3 (Rz, nm)

surface area: 25,000,000 nm² (S3A, nm²)

### Example 1-1 (C+H, Ar+oxygen, 35 min.)

root-mean-square roughness: 15.4 (Sq, nm)

ten point average roughness: 222 (Rz, nm)

surface area: 28,100,000 nm² (S3A, nm²)

Example 2 (C+H, Ar+oxygen, 35 min.) for confirming the reproducibility of Example 1-1

root-mean-square roughness: 17.3 (Sq, nm)

ten point average roughness: 171 (Rz, nm)

surface area: 29,100,000 nm² (S3A, nm²)

### Example 1-2 (C+H, Ar+oxygen, 125 min.)

root-mean-square roughness: 29.1 (Sq, nm)

ten point average roughness: 379 (Rz, nm)

surface area: 40,500,000 nm² (S3A, nm²)

### Example 1-3 (C+H, Ar+oxygen, 11 min.)

root-mean-square roughness: 2.03 (Sq, nm)

ten point average roughness: 33.4 (Rz, nm)

surface area: 25,200,000 nm² (S3A, nm²)

### Comparative Example 1-2 (C+H, Ar+oxygen, 1 min.)

root-mean-square roughness: 0.795 (Sq, nm)

ten point average roughness: 14.6 (Rz, nm)

surface area: 25,000,000 nm² (S3A, nm²)

Comparative Example 2 (C+H+Si, untreated)

root-mean-square roughness: 0.629 (Sq, nm)

ten point average roughness: 11.0 (Rz, nm)

surface area: 25,000,000 nm² (S3A, nm²)

Comparative Example 3-1 (C, untreated)

root-mean-square roughness: 2.08 (Sq, nm)

ten point average roughness: 18 (Rz, nm)

surface area: 25,000,000 nm² (S3A, nm²)

### Comparative Example 3-2 (C, Ar+oxygen, 1 min.)

root-mean-square roughness: 2.03 (Sq, nm)

ten point average roughness: 16.9 (Rz, nm)

surface area: 25,000,000 nm² (S3A, nm²)

### Example 3 (C, Ar+oxygen, 1 min.)

root-mean-square roughness: 11.1 (Sq, nm)

ten point average roughness: 80.8 (Rz, nm)

surface area: 26,600,000 nm² (S3A, nm²)

### Example 6 (C+H+Si, Ar+oxygen, 125 min.)

ten point average roughness: 33.5 (Rz, nm)

surface area: 25,200,000 nm² (S3A, nm²)

Each of Examples shows increase in root-mean-square roughness, ten point average roughness, and surface area. Further, in Example 2 for confirming reproducibility of Example 1-1, it was observed that the unevenness structure (rough surface) according to an embodiment was formed almost in the same manner.

Thus, the fine unevenness structure according to an embodiment can be readily reproduced by appropriately adjusting the condition for applying a plasma of oxygen and/or Ar and the duration of the application. Also, the following explanation is possible for the mechanism in which the fine unevenness structure is formed by applying a plasma of oxygen and/or Ar to the surface of a carbon film (e.g., an amorphous carbon film) composed of carbon and hydrogen and formed on a substrate.

First, a plasma of oxygen and/or Ar, etc. is applied to a carbon film composed of carbon and hydrogen and formed on a substrate, such that weakly bound portions, defective portions, and thin portions in the carbon film (in particular, the surface layer thereof) are initially etched by the plasma, and these etched portions are thinned faster than other portions. If the carbon film is an amorphous carbon film having a high insulation quality such as Example 1-1 (e.g., even a carbon film having a certain degree of electric conductivity formed on a metal substrate having a high electric conductivity is also highly insulating with respect to the metal substrate), the thinned portions of the carbon film have an increased electric conductivity and, if a bias voltage is applied to the substrate, more plasma is formed (concentrated) at the thinned portions of the carbon film. Thus, a strong plasma is repeatedly formed on the thinned portions of the carbon film to perform etching, thereby forming the unevenness structure according to an embodiment.

For example, when a plasma of oxygen gas is applied onto the surface layer of the carbon film at a gas flow rate and a gas pressure both higher than a certain level, the oxygen gas tentatively made into a plasma in the vacuum apparatus binds to carbon (film) on the substrate or carbon sputtered from the carbon film and discharged from the vacuum apparatus (e.g., in the form of COₓ) without depositing on the surface layer of the carbon film again.

Accordingly, as to the condition of making a plasma of oxygen and/or Ar, etc. to be applied onto the surface layer of the carbon film, it can be expected that forming (growth) of the fine unevenness structure in the surface layer of the carbon film can be facilitated by a larger voltage applied to the substrate, a larger pressure and flow rate of the gases, and a longer duration of application of the plasma.

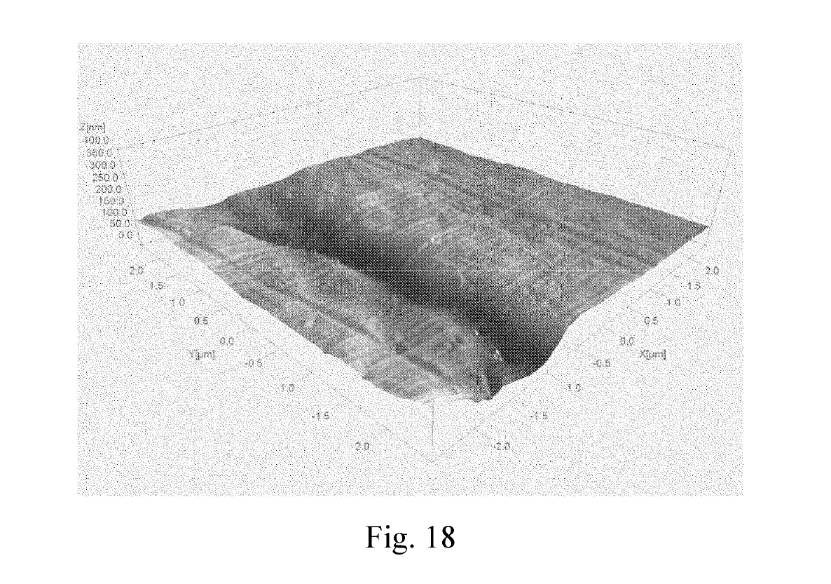

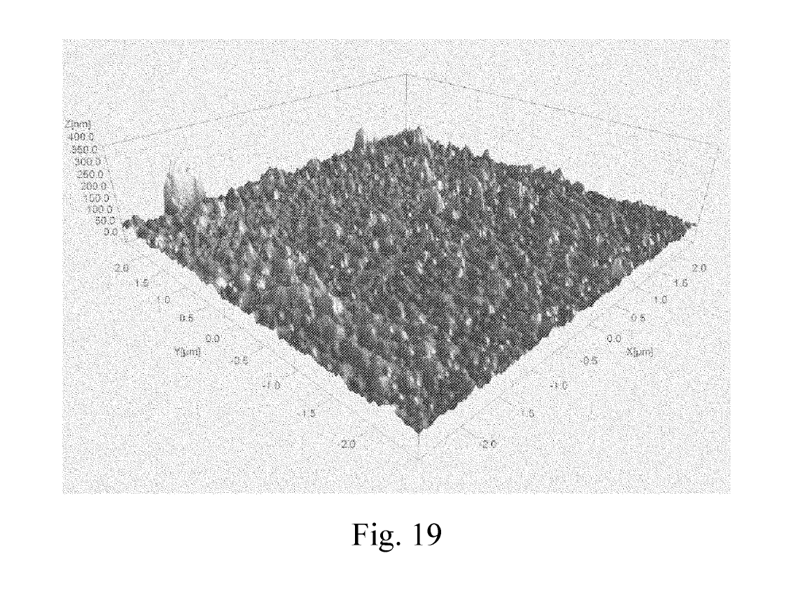

FIG. 18 shows a surface condition of a stainless steel (SUS304) film of Reference Example. The stainless steel film of Reference Example has a root-mean-square roughness of 21.8 nm, a ten point average roughness of 128 nm, and a surface area of 25,200,000 nm². FIG. 19 shows a surface condition of Example 1-1. Example 1-1 has a root-mean-square roughness of 15.4 nm, a ten point average roughness of about 222 nm, and a surface area of 28,100,000 nm². Thus, Example 1-1 has a smaller root-mean-square roughness and a larger ten point average roughness and surface area than Reference Example. Example 1-3 has a root-mean-square roughness of 2.03 nm which is one order of magnitude smaller than that of Reference Example, and a surface area of 25,200,000 nm² which is the same as that of Reference Example.

This indicates that a surface including (rough) unevenness structure having a large indentation but not including smaller (fine) unevenness structure in the rough unevenness structure does not have a largely increased surface area, whereas a surface including fine and dense unevenness structure having a small roughness can have a more increased surface area.

As described above, an amorphous carbon film is known to form a film in conformity to the shape of the substrate such as unevenness structure. An amorphous carbon film forms a shape such as unevenness structure different from the shape of the substrate by itself mainly when perforation is inevitable due to droplets and an abnormal electric discharge. It is also possible that unevenness structure having relatively large indentations with large clusters and flocks is formed due to an abnormally high plasma gas pressure during film deposition. However, such unevenness structure is different from the fine unevenness structure according to an embodiment (e.g., unevenness structure having a ten point average roughness Rz of 20 nm or larger). This verification indicates that the fine unevenness structure in the amorphous carbon film itself formed on the substrate (Si 100 substrate) not having fine unevenness structure produces a large surface area.

Element Analysis

Next, comparison of the amounts of Ar and oxygen detected in the surface was made between Comparative Example 1-1, Comparative Example 1-2, Example 1-1, Example 1-2, Example 1-3, Example 4, Example 5, Comparative Example 3-2, and Example 3. The detection was conducted under the following conditions.

Measurement Instrument
FE-SEM SU-70 from Hitachi High-Technologies Corporation

Measurement Conditions:
No vapor deposition
Acceleration voltage: 7.0 kV
Electric current mode: Med-High
Magnification: 50,000×
Designated elements: carbon, oxygen, and Ar

The carbon films of Comparative Example 3-2 and Example 3 do not contain hydrogen, and others contain hydrogen. The atomic composition in the amorphous carbon films containing hydrogen are on the “hydrogen-free basis” in which atomic composition is analyzed without detecting hydrogen in the amorphous carbon films. The composition ratio of the elements listed below such as carbon, oxygen, and Ar assumes the total detected amount of these elements in a measured sample as 100%. The detected amount of oxygen is shown below. Additionally, each of Examples and Comparative Examples is kept under a normal temperature and pressure.

Comparative Example 1-1 (an untreated amorphous carbon film composed of hydrogen and carbon)

carbon: 99.54 at %

Ar: 0.00 at %

oxygen: 0.46 at %

Comparative Example 1-2 (irradiated with Ar and oxygen gas for 1 min.)

carbon: 99.5 at %

oxygen: 0.5 at %

Ar was not measured (designated), and the composition ratio was based on the two elements.

Example 1-1 (irradiated with Ar and oxygen gas for 35 min.)

carbon: 96.62 at %

Ar: 0.10 at %

oxygen: 3.28 at %

Example 1-2 (irradiated with Ar and oxygen gas for 125 min.)

carbon: 38.04 at %

Ar: 0.96 at %

oxygen: 61.00 at %

Example 1-3 (irradiated with Ar and oxygen gas for 11 min.)

carbon: 99.26 at %

oxygen: 0.74 at %

Ar was not measured (designated), and the composition ratio was based on the two elements.

Example 4 (irradiated with Ar for 35 min.)

carbon: 98.19 at %

Ar: 0.06 at %

oxygen: 1.75 at %

Example 5 (irradiated with oxygen gas for 35 min.)

carbon: 94.02 at %

Ar: 0.00 at %

oxygen: 5.98 at %

### Comparative Example 3-2

carbon: 89.13 at %

oxygen: 10.87 at %

Ar was not measured (designated), and the composition ratio was based on the two elements.

### Example 3

carbon: 36.51 at %

oxygen: 63.49 at %

Ar was not measured (designated), and the composition ratio was based on the two elements.

These results show that, at the time of measuring the samples, Ar was detected from all of the amorphous carbon films containing hydrogen and irradiated with at least Ar, confirming that Ar is contained in these amorphous carbon films containing hydrogen. Further, it was confirmed that the samples of Examples irradiated with at least oxygen plasma contains a much larger amount of oxygen than ordinary amorphous carbon films containing hydrogen, and that a longer duration of application of oxygen plasma enlarges the ratio of oxygen to carbon contained. Additionally, more oxygen was detected from Example 4 not irradiated with oxygen than from ordinary amorphous carbon films. This is because the active portions in the amorphous carbon film including open chains produced by application of a plasma of Ar gas adsorbed oxygen (oxygen, carbon dioxide, and water vapor) in the air.

Observation of Forming of a Composite Layer

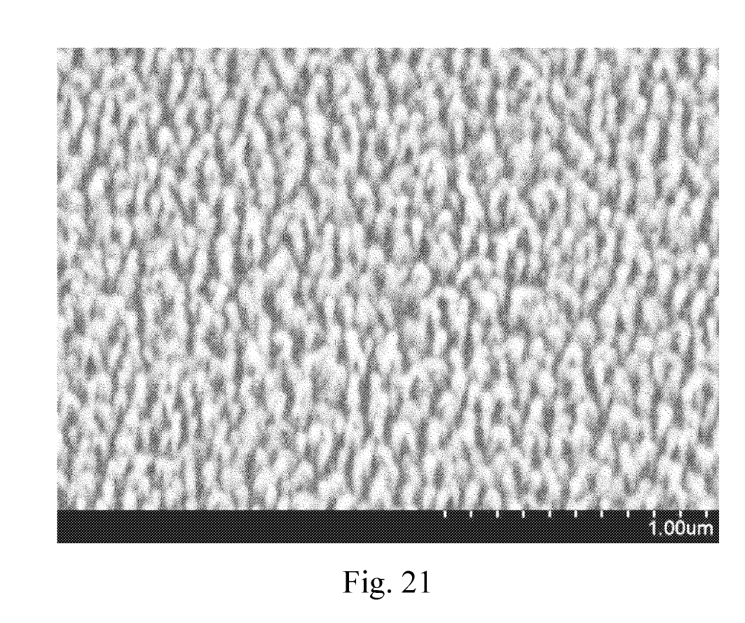

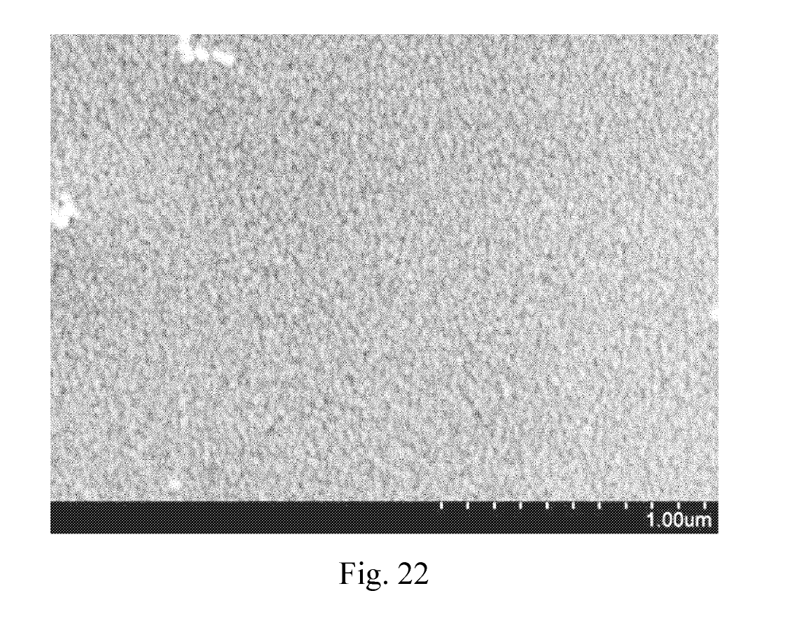

Next, Si sample pieces formed by the same process as Example 1-1 and Example 4 were placed into the reaction container of a DC-pulsed plasma CVD apparatus, the reactive gas was evacuated from the reaction container, and then trimethylsilane gas was introduced into the reaction container at a flow rate of 30 SCCM to a gas pressure of 0.66 Pa, while applying a voltage of −3 kV to generate a plasma for forming on the surface layer an amorphous carbon film containing Si to a thickness of about 10 nm, and then the trimethylsilane gas was evacuated. Further, oxygen gas was introduced into the reaction container at a flow rate of 30 SCCM to a gas pressure of 0.66 Pa, while applying a voltage of −3 kV to generate a plasma for forming on the surface layer an amorphous carbon film containing Si and oxygen. These sample pieces were taken as Example 7 (obtained by adding an amorphous carbon film containing Si and oxygen to Example 1-1) and Example 8 (obtained by forming an amorphous carbon film containing Si and oxygen on Example 4). FIG. 21 is an electron microscope photograph of the surface of Example 7 (with a magnification of 50,000). FIG. 22 is an electron microscope photograph of the surface of Example 8 (with a magnification of 50,000).

The measurement results of the surface roughness and the surface area under the above-described measurement condition are as follows.

Example 1-1 (before treatment, Ar+oxygen)

root-mean-square roughness: 15.4 (Sq, nm)

ten point average roughness: 222 (Rz, nm)

surface area: 28,100,000 nm² (S3A, nm²)

Example 7 (after treatment, Ar+oxygen)

root-mean-square roughness: 12.8 (Sq, nm)

ten point average roughness: 106 (Rz, nm)

surface area: 25,900,000 nm² (S3A, nm²)

Example 4 (before treatment, Ar only)

root-mean-square roughness: 1.93 (Sq, nm)

ten point average roughness: 36.4 (Rz, nm)

surface area: 25,200,000 nm² (S3A, nm²)

Example 8 (after treatment, Ar only)

root-mean-square roughness: 0.642 (Sq, nm)

ten point average roughness: 9.69 (Rz, nm)

surface area: 25,000,000 nm² (S3A, nm²)

In the surface of Example 7, it was observed that underlying fine unevenness structure was maintained, but the surface roughness and the surface area were reduced to form a more smooth surface as compared to Example 1-1, the sample before the treatment. In the surface of Example 8, it was observed that (the recesses of) underlying unevenness structure was filled with an amorphous carbon film containing Si and oxygen and having a thickness of about 10 nm, reducing the surface roughness and the surface area.

Further, it was observed in Example 7 that an amorphous carbon film containing Si and oxygen can be formed on the structure according to an embodiment having fine unevenness structure in a carbon film such that the underlying unevenness structure is maintained in a predetermined range. It is known that after a carbon film composed of hydrogen and carbon is irradiated with oxygen or Ar to activate the surface layer thereof such that it exhibits hydrophilicity or have increased adhesiveness to other substances, the activity provided is lost with time. However, an amorphous carbon film containing Si and oxygen can retain the hydrophilicity thereof for a long period. This verification confirmed that if the unevenness structure according to an embodiment underlies an amorphous carbon film containing Si and oxygen, the overlying amorphous carbon film having a stable hydrophilicity and containing Si and oxygen can also be provided with unevenness structure that can exhibit structural hydrophilicity.

Confirmation of Hydrophilicity

Substrates prepared were stainless steel screen mesh ((SC) #500-19-23 from Asada Mesh Co., Ltd. having a size of 10 cm×10 cm) and a Si (100) wafer (having a rectangular shape, a size of 10 cm×10 cm, and a thickness of 0.625 mm). These substrates were subjected to ultrasonic cleansing using isopropyl alcohol (IPA) and then placed into a known DC-pulsed CVD plasma film forming apparatus. The surface of the sample of the above Si (100) wafer was partially covered with a piece of the stainless steel mesh cut into a rectangular shape having a size of 30 mm×30 mm. The substrates were arranged such that application of voltage thereto is possible. (All the samples below were subjected to a plasma process under the condition that voltage is applied to each substrate.) After evacuation with vacuum to 1×10⁻³ Pa, the surface was cleaned for one minute with Ar gas at a flow rate of 30 SCCM to a gas pressure of 1.5 Pa. Then, Ar gas was evacuated, and trimethylsilane gas was introduced at a flow rate of 30 SCCM to a gas pressure of 1.5 Pa, while applying a voltage of −4 kVp to form an amorphous carbon film containing Si to a thickness of about 80 nm as a substrate adhesion layer. Next, acetylene gas was introduced at a flow rate of 30 SCCM to a gas pressure of 1.5 Pa, while applying a voltage of −3.5 kVp to form an amorphous carbon film composed of carbon and hydrogen, the total thickness including the thickness of the above adhesion layer being about 360 nm. The Si (100) wafer now taken out of the vacuum apparatus was taken as “Comparative Example 13.” The stainless steel mesh partially covering the surface of the Si (100) wafer substrate was removed and the Si (100) wafer substrate was observed. No film was formed on the portion masked with the mesh, and thus an amorphous carbon film having unevenness structure was formed to a segmented (separated) shape of the openings in the mesh.

Next, the samples having the above-described film formed thereon (the mesh was removed from the Si (100) wafer substrate) were placed into a known DC-pulsed CVD plasma film forming apparatus. After evacuation with vacuum to 1×10⁻³ Pa, Ar gas and oxygen gas were introduced at flow rates of 30 SCCM and 60 SCCM, respectively, to a gas pressure of 2 Pa, while applying a voltage of −3.5 kVp for plasma irradiation of the samples. The mesh sample irradiated with the plasma for four minutes was taken as Comparative Example 11-1, the mesh sample irradiated with the plasma for 20 minutes was taken as Example 11-1, and the mesh sample irradiated with the plasma for 40 minutes was taken as Example 12-1. Further, the Si (100) sample irradiated with the plasma for 40 minutes at portions not having the above segmented structure formed thereon was taken as Example 13-1, and the Si (100) sample irradiated with the plasma for 40 minutes at portions having the above segmented structure formed thereon was taken as Example 13-2.

These samples were taken out of the vacuum apparatus, and then left to stand in the atmosphere with a normal temperature and pressure (and a humidity of about 20%) for about 30 minutes. Then, Fluorosurf FG-5010Z130-0.2 from Fluoro Technology Corporation was applied to one side of the meshes and dried for 90 minutes, and again applied and dried for 60 minutes to provide the surface with water and oil repellence. These samples were taken as Comparative Example 11-2, Example 11-2, and Example 12-2 (the preceding samples were formed only of mesh samples). A mesh not subjected to surface treatment was taken as Comparative Example 10. The contact angle with water (pure water) was measured in Comparative Example 11-1, Example 11-1, and Example 12-1 (the mesh samples before the surface treatment for water and oil repellence). The measurement was performed about three hours after the samples were subjected to the plasma process with a mixture of Ar gas and oxygen gas and taken out of the vacuum apparatus into the atmosphere (at a room temperature of about 25° C. and a humidity of about 20%). The meshes were held during the measurement such that the measurement points of the contact angle on the mesh samples are floating in the air. The mesh #500 were used for measuring the contact angle because this mesh is a structure including large microscale unevenness structure in which thin fiber threads having a diameter of 19 μm extending longitudinally and latitudinally and intersecting each other three-dimensionally (at points of intersection), and the synergistic wettability of the structure according to an embodiment can be observed in this mesh provided further with nanoscale unevenness structure in the surface layer thereof. As for the above-described portion of the Si (100) sample having no segmented structure formed thereon (Example 13-1), and the portion of the Si (100) sample having the segmented structure formed thereon (Example 13-2), the substrates were subjected to the plasma process with a mixture of Ar gas and oxygen gas and then taken out of the vacuum apparatus into the atmosphere, and left to stand for about one week under a normal temperature and pressure, before measurement of the samples. The contact angle was measured after about one week because an amorphous carbon film cannot retain the surface activity thereof provided by irradiation with a plasma of Ar gas or oxygen gas for activation of the surface layer, and the wettability can be observed in the amorphous carbon film as a hydrophilic structure including physical unevenness after some degree of chemical surface activity provided by the plasma process is lost.

The measurement conditions were as follows.

Measurement instrument portable contact angle gauge PCA-1 from Kyowa Interface Science Co., Ltd

Measurement range: 0 to 180° (display resolution 0.1°)

Measurement method: contact angle measurement (drop method)

Measurement liquid: pure water

Amount of measurement liquid (amount of dropped pure water): 1.5 μl

Measurement environment an environment with a room temperature of 25±3° C. and a humidity of 20±3%

The measurement results are shown below. Each of these measurement results is an average of measurement values obtained at ten different points of a sample. Only the water and oil repellent sample coated with Fluorosurf, a water and oil repellence coating agent, were cleansed for one minutes in an ultrasonic cleansing apparatus filled with isopropyl alcohol (IPA) and dried naturally, before the measurement of the contact angle.

### Mesh Samples

Comparative Example 10: 101.0°

Comparative Example 11-1: 54.4°

Example 11-1: 44.2°

Example 12-1: 39.1°

### Si (100) Substrates

Comparative Example 13: 72.1°

Example 13-1: 46.4°

Example 13-2: 30.4° (the portion having the segmented structure formed thereon)

The measurement results of Comparative Example 11-1 show that the chemical activation by the plasma irradiation with Ar and oxygen largely reduced the contact angle with water. The difference in contact angle between Comparative Example 11-1 and Examples 11-1 and 12-1 are presumably caused by the difference in roughness of fine unevenness structure formed in the amorphous carbon films of the samples. Further, comparison between Example 13-1 and Example 13-2 show that the nanoscale fine unevenness structure according to an embodiment can be provided in the surface layer of an amorphous carbon film previously having microscale unevenness structure formed in the substrate thereof, so as to largely vary (improve) the wettability with water.

Next, the contact angle was measured in the Si (100) sample subjected to water and oil repellence surface treatment (Comparative Example 12-2).

Comparative Example 11-2: 108.1°

Example 11-2: 121.9°

Example 12-2: (measurement impossible)

Comparative Example 12-2: 108.1°

In Example 12-2, the contact angle with water was extremely large, and the pure water drop of the contact angle gauge was repelled by the mesh surface and was not settled.

In Example 11-1 and Example 12-1, the observed contact angle was larger than the contact angle with water (about 110°) exhibited by the smooth and water and oil repellent surface of the Si (100) sample of Comparative Example 12-2. This enlargement of the contact angle is caused by increased structural water repellence. Both Example 11-1 and Example 12-1 exhibited the contact angle exceeding the contact angle with water of general fluorine materials being 120°.

Next, the contact angle with water of Example 12-2 was measured with the amount of the measurement liquid (the amount of the dropped pure water) of the contact angle gauge set at 2.5 μl. In Example 12-2, measurement was performed at seven points with the amount of the dropped pure water set at 2.5 μl. The average of the measurement values at these seven points was 134.6°. This contact angle is significantly larger than the contact angle with water of fluorine materials. This large contact angle is presumably caused by structural water repellence.

Observation of the Formation of the Carbon Film Before Plasma Irradiation, and Roughening of the Carbon Film Under Different Plasma Irradiation Conditions

The substrate prepared was a Si (100) wafer (having a rectangular shape, a size of 10 cm×10 cm, and a thickness of 0.625 mm). These substrates were subjected to ultrasonic cleansing using isopropyl alcohol (IPA) and then placed into a known DC-pulsed CVD plasma film forming apparatus such that voltage can be applied to each of the substrates. After evacuation with vacuum to 1×10⁻³ Pa, the surface was cleaned for one minute with Ar gas at a flow rate of 30 SCCM to a gas pressure of 1.5 Pa, while applying a voltage of −3 kVp. Then, Ar gas was evacuated, and trimethylsilane gas was introduced at a flow rate of 30 SCCM to a gas pressure of 1.5 Pa, while applying a voltage of −4 kVp to form an amorphous carbon film containing Si to a thickness of about 80 nm as a substrate adhesion layer. Next, acetylene gas was introduced at a flow rate of 30 SCCM to a gas pressure of 1.5 Pa, while applying a voltage of −4 kVp to form an amorphous carbon film composed of carbon and hydrogen, the total thickness including the thickness of the above adhesion layer being about 660 nm.

Next, the Si (100) wafer substrates having the above-described film formed thereon were placed into a known DC-pulsed CVD plasma film forming apparatus. After evacuation with vacuum to 1×10⁻³ Pa, Ar gas and oxygen gas were introduced at flow rates of 20 SCCM and 35 SCCM, respectively, to a gas pressure of 1.5 Pa, while applying a voltage of −3 kVp for plasma irradiation of the samples. The Si (100) sample irradiated with the plasma for four minutes was taken as Reference Example 3, the Si (100) sample irradiated with the plasma for ten minutes was taken as Reference

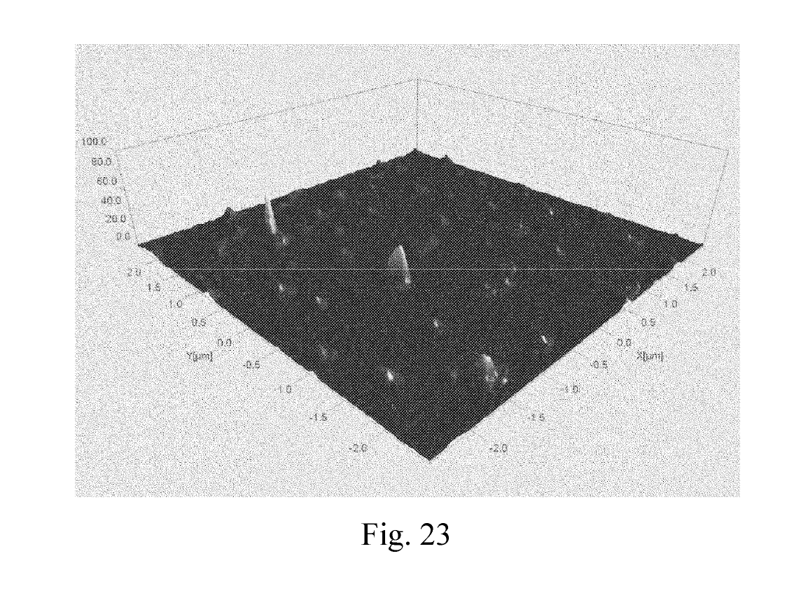

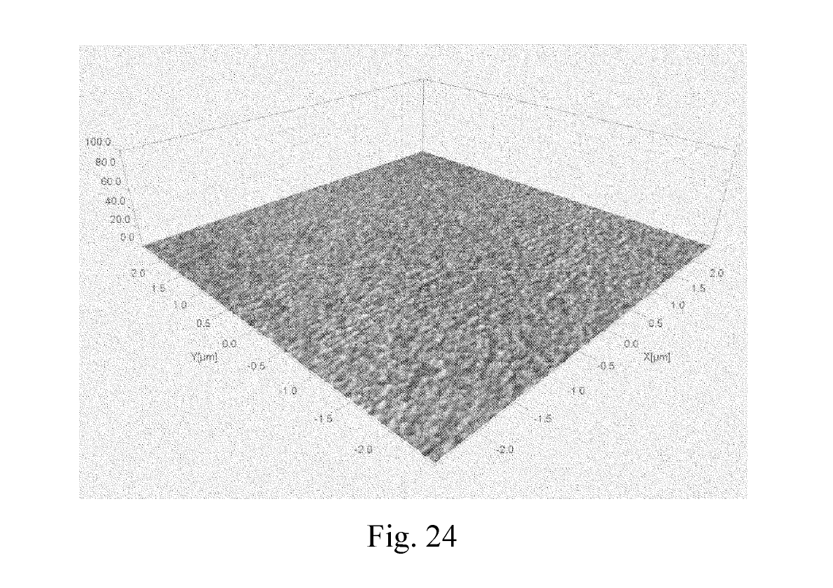

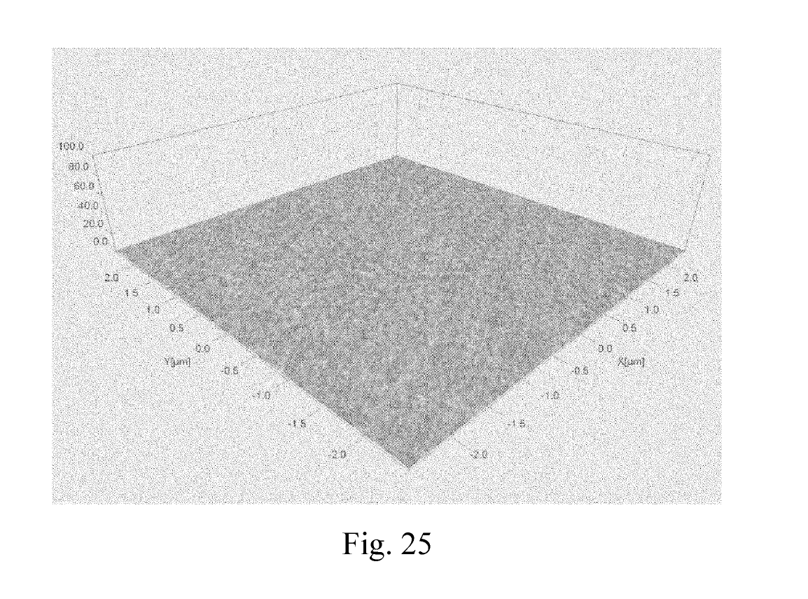

Example 4, and the Si (100) sample irradiated with the plasma for 20 minutes was taken as Reference Example 5. Each Reference Examples was observed with an atomic force microscope (AFM) for the surface roughness and the surface condition thereof. An atomic force microscope (AFM) was used for this measurement. The measurement conditions of the root-mean-square roughness (Sq) include a scan size of 5.0 μm and a scan rate of 0.3 Hz. The surface conditions of Reference Examples 3, 4, and 5 are shown in FIGS. 23, 24, and 25, respectively. The measurement result of surface roughness was as follows.

Reference Example 3 (irradiated with Ar and oxygen gas for 4 min.)

root-mean-square roughness: 1.93 nm

ten point average roughness: 31.4 nm

Reference Example 4 (irradiated with Ar and oxygen gas for 10 min.)

root-mean-square roughness: 0.414 nm

ten point average roughness: 3.56 nm

Reference Example 5 (irradiated with Ar and oxygen gas for 20 min.)

root-mean-square roughness: 0.148 nm

ten point average roughness: 2.25 nm

The conditions of plasma irradiation with a mixture of oxygen and Ar for Reference Examples, including the gas flow rates and the gas pressure of oxygen and Ar and the voltage and the duration of applying the voltage for producing a plasma, were set at smaller values than those for Examples described above. Reference Example 3 included relatively rough “sticking-out” projections in an uncontrollable manner immediately after the amorphous carbon film was formed. Upon subsequent irradiation with a plasma of a mixture of oxygen and Ar, the “sticking-out” projections observed in Reference Example 3 disappeared (Reference Example 4), and as the duration of plasma irradiation is longer (Reference Example 5), the surface of the amorphous carbon film was etched in a more smooth direction. This indicates that the surface layer of the amorphous carbon film is not necessarily roughened but may be smoothened depending on the conditions and duration of irradiation with a plasma of oxygen and/or Ar.

Further, the thickness of the amorphous carbon film was reduced by about 36 nm during the plasma irradiation (ten minutes) to prepare Reference Example 5 from Reference Example 4. This indicates that irradiation with a plasma of oxygen and/or Ar for removing a carbon film may be successful in removing (reducing the thickness of) the carbon film but is not necessarily successful in roughening of the carbon film for forming unevenness structure according to an embodiment.

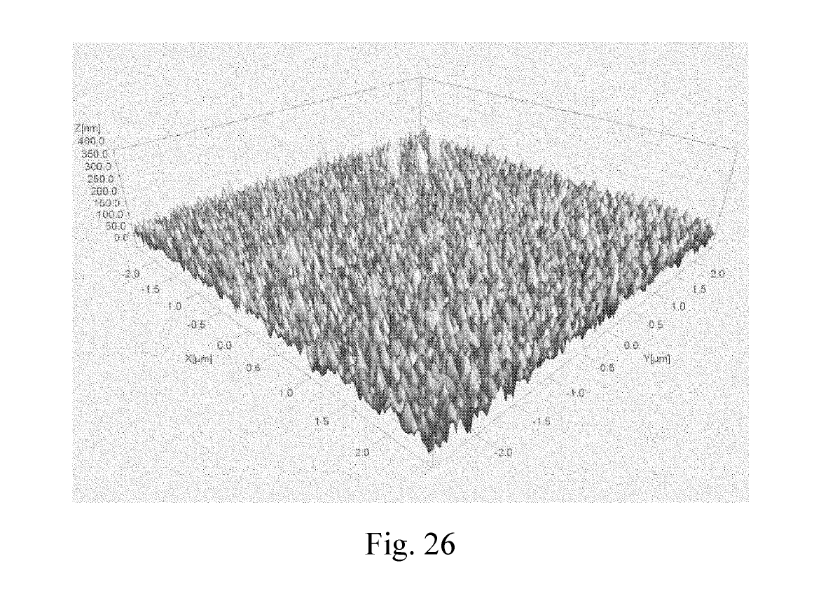

Then, a mixture of oxygen gas at a flow rate of 70 SCCM and Ar gas at a flow rate of 40 SCCM was introduced to a gas pressure of 2.0 Pa, while applying a voltage of −3.5 kVp to generate a plasma which was applied to the sample for 35 minutes. As a result, the fine unevenness structure according to an embodiment (having a root-mean-square roughness of 25.7 nm and a ten point average roughness of 236 nm) was formed in the surface layer of the amorphous carbon film (FIG. 26). Thus, depending on the condition of the amorphous carbon film (before plasma irradiation) in which to form fine unevenness structure and the condition and duration of applying a plasma of oxygen and/or Ar, the amorphous carbon film may not be roughened (the fine unevenness structure may not be formed). Therefore, those skilled in the art could have understood that these conditions can be appropriately adjusted to form the unevenness structure according to an embodiment.

### 2. Additional Observation of Unevenness Structure in the Surface of the Carbon Film Containing Si

Substrates prepared were necessary number of rectangular plates having a size of 2 cm by 2 cm (and a thickness of about 0.625 mm) cut out from a 6-inch Si (100) wafer, and necessary number of stainless steel (SUS304) plates polished to a surface roughness Ra of 0.03 μm and plated with hard chrome, having a rectangular shape with a size of 2 cm by 2 cm and a thickness of 1 mm.

First, the Si (100) samples were subjected to ultrasonic cleansing using isopropyl alcohol (IPA) and then placed into a reaction container of a known DC-pulsed plasma CVD apparatus such that individual substrates can be subjected to a negative DC voltage.

Next, the reaction container containing the Si sample piece was evacuated to 1×10⁻³ Pa, and then Ar gas was introduced into the reaction container at a flow rate of 30 SCCM to a gas pressure of 2 Pa, while applying a voltage of −3.0 kVp to generate Ar plasma for cleaning the surface of the substrate for one minute. Next, the reaction container was evacuated of Ar gas to a vacuum, and then trimethylsilane gas was introduced into the reaction container at a flow rate of 30 SCCM to a gas pressure of 1.2 Pa, while applying a voltage of −4.0 kVp to generate a plasma for forming a substrate adhesion layer composed of an amorphous carbon film containing Si for three minutes. The stainless steel (SUS304) plates plated with hard chrome form the samples of Examples under the same conditions as the Si sample pieces described later, except that no substrate adhesion layer is formed of the amorphous carbon film containing Si. The elementary composition analysis with FE-SEM was performed using the samples having the stainless steel (SUS304) plate plated with hard chrome to form an alternative substrate adhesion layer. This is for the purpose of accurately detecting Si in the sample films without detecting Si in the Si (100) wafer serving as a substrate.

Next, the reaction container was evacuated of trimethylsilane gas to a vacuum, and then acetylene gas was introduced into the reaction container at a flow rate of 30 SCCM to a gas pressure of 2 Pa, while applying a voltage of −4.0 kVp to generate a plasma for forming an amorphous carbon film composed of carbon and hydrogen having a thickness of about 750 nm. Next, acetylene gas was evacuated, and then the reaction container of the plasma CVD apparatus was tentatively returned to a normal pressure. The Si sample piece was taken out of the reaction container and was taken as Comparative Example 101.

Next, a Si sample piece formed in the same manner as for Comparative Example 101 was placed into the reaction container of the plasma CVD apparatus, the reaction container was evacuated to 1×10⁻³ Pa again, and then trimethylsilane gas was introduced into the reaction container at a flow rate of 30 SCCM to a gas pressure of 1 Pa, while applying a voltage of −4.0 kVp to generate a plasma for forming on the surface layer of the sample an amorphous carbon film containing Si to a thickness of about 10 nm. This sample was taken as Example 101. Additionally, the sample formed under the same condition and having the amorphous carbon film formed to a thickness of 30 nm was taken as Example 102, and the sample formed under the same condition and having the amorphous carbon film formed to a thickness of 80 nm was taken as Example 103.

Next, a Si sample piece formed in the same manner as for Comparative Example 101 was placed into the reaction container of the plasma CVD apparatus, the reaction container was evacuated to 1×10⁻³ Pa, and then a mixture of trimethylsilane gas at a flow rate of 5 SCCM and acetylene gas at a flow rate of 25 SCCM was introduced into the reaction container to a gas pressure of 1 Pa, while applying a voltage of −4.0 kVp and reducing the concentration of Si in the mixture gas to generate a plasma for forming an amorphous carbon film containing Si to a thickness of 80 nm. This sample was taken as Example 104. Further, a Si sample piece formed in the same manner as for Comparative Example 101 was placed into the reaction container of the plasma CVD apparatus, the reaction container was evacuated to 1×10⁻³ Pa, and then a mixture of trimethylsilane gas at a flow rate of 5 SCCM and acetylene gas at a flow rate of 45 SCCM was introduced into the reaction container to a gas pressure of 1 Pa, while applying a voltage of −4.0 kVp and reducing the concentration of Si in the mixture gas to generate a plasma for forming an amorphous carbon film containing Si to a thickness of 80 nm. This sample was taken as Example 105.

Finally, an untreated Si (100) sample was placed into the reaction container of the plasma CVD apparatus, the reaction container was evacuated to 1×10⁻³ Pa, and then trimethylsilane gas was introduced into the reaction container at a flow rate of 30 SCCM to a gas pressure of 1 Pa, while applying a voltage of −4.0 kVp to generate a plasma for forming on the surface layer of the Si (100) sample an amorphous carbon film containing Si to a thickness of about 750 nm. This sample was taken as Example 106.

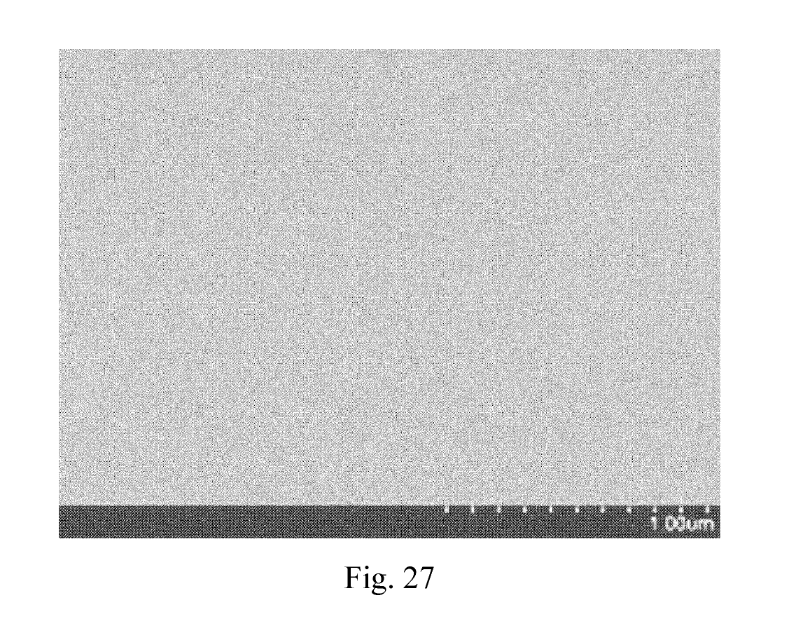

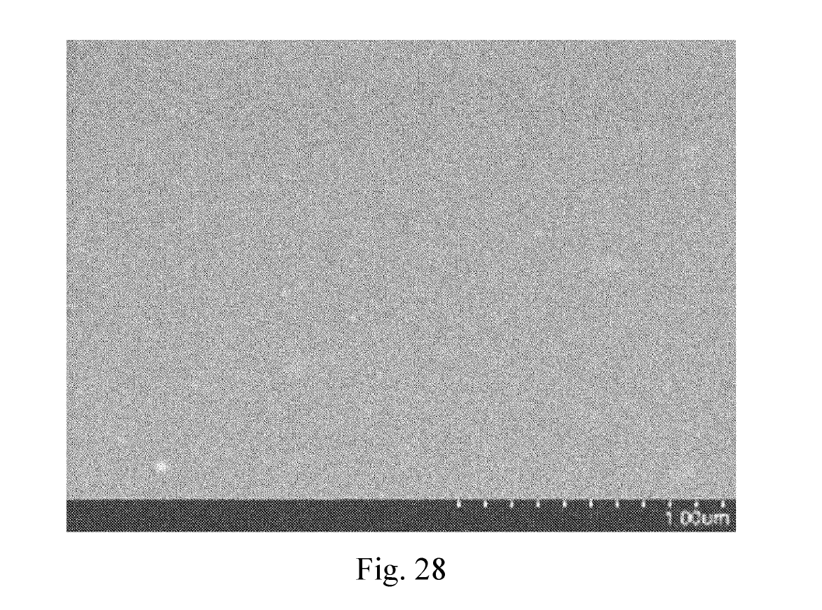

Each of Comparative Examples and Examples was observed by electron microscope photography for the surface condition thereof. The measurement was performed with a magnification of 50,000. FIG. 27 is a photograph of the surface of Comparative Example 101, and FIG. 28 is a photograph of the surface of Example 101 (before the dry etching described later). The measurement result of surface roughness was as follows. Observation by electron microscope photography and measurement of the surface roughness by an atomic force microscope (AFM) were performed by the same measurement instruments and methods as those having been described herein unless otherwise specified, which also applies to the units of the measurement values.

### Comparative Example 101

root-mean-square roughness: 0.95

ten point average roughness: 9.06

surface area: 25,000,000

Example 101 (prior to dry etching)

root-mean-square roughness: 0.637

ten point average roughness: 14.9

surface area: 25,000,000

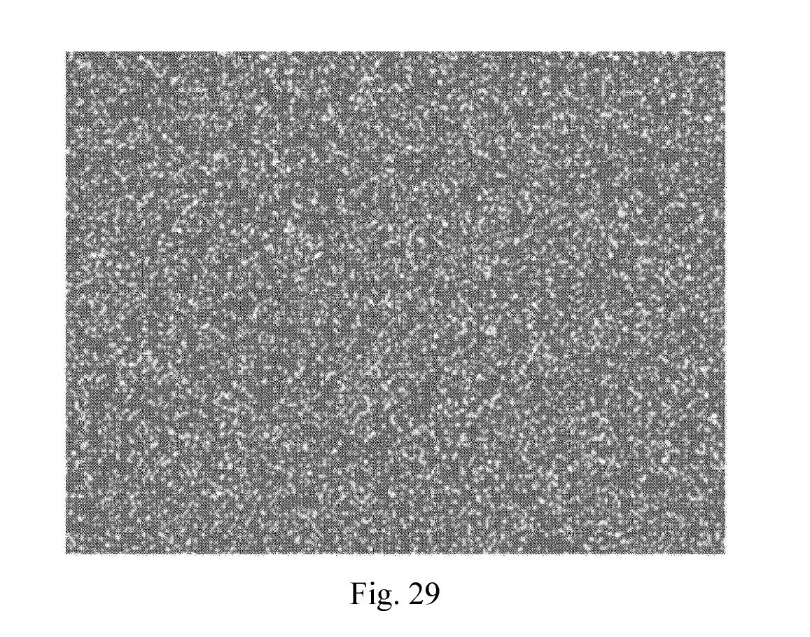

Examples 102 to 106 (prior to dry etching) were likewise observed for the surface condition thereof. The surfaces were smooth with no large unevenness found therein, as the surface of Example 101. FIG. 29 is a photograph showing measured distribution of Si in the surface layer of Example 101. The measurement was conducted with FE-SEM under the following conditions.

Measurement Instrument
FE-SEM SU-70 from Hitachi High-Technologies Corporation

Measurement Condition:
No vapor deposition
Acceleration voltage: 5.0 kV
Electric current mode: Med-High

In FIG. 29, bright portions include much Si and dark portions include less Si, indicating that the concentration of Si in the surface is irregular. Such irregular distribution of Si is presumably caused by the amorphous structure of the amorphous carbon film containing Si, which has no regular bonds between elements unlike crystalline structure. Additionally, as will be described later, such irregular distribution of Si (or metal elements having less tendency to be etched by oxygen like Si) is one of the factors for constructing “crater-like recess structure” different from “needle-like projection structure having sharp tip ends,” found in oxygen etching of a film composed of carbon only or carbon and hydrogen.

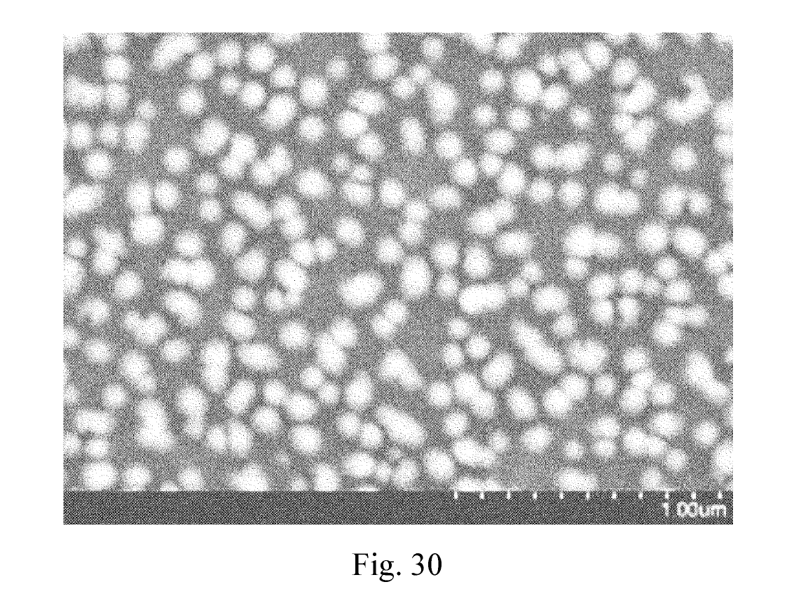

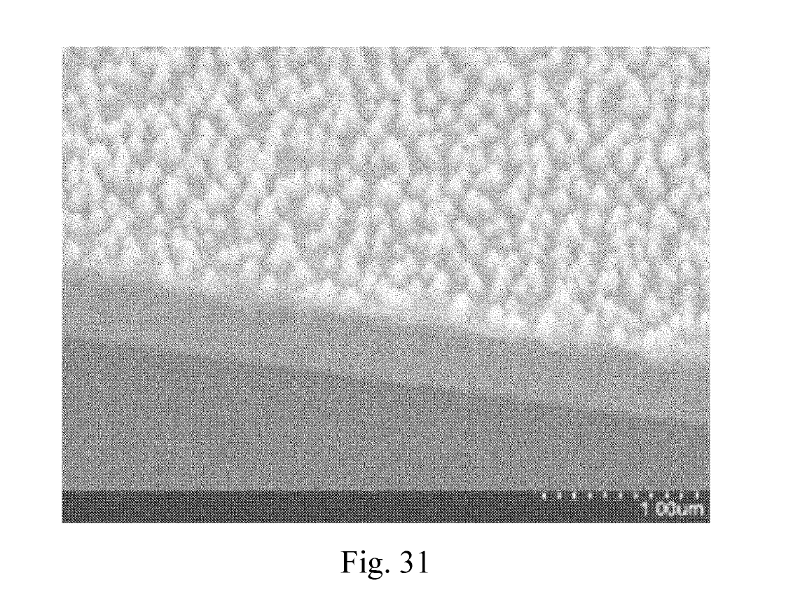

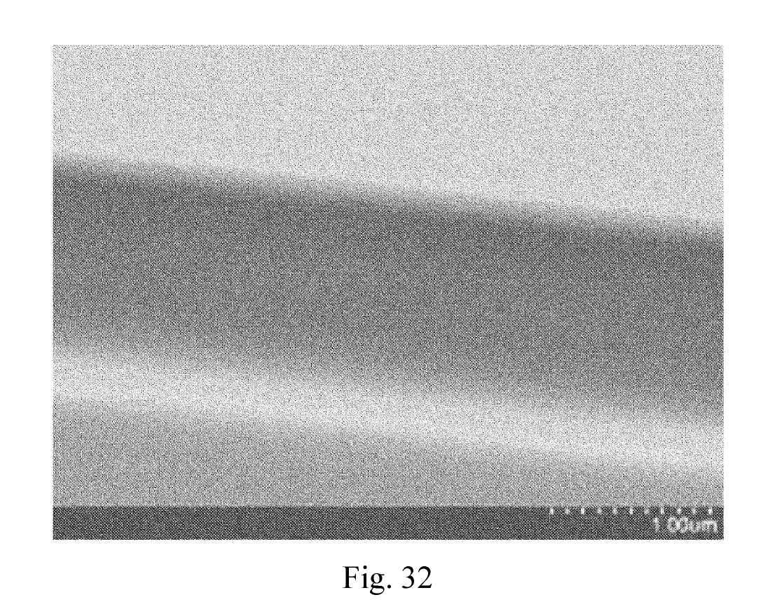

Next, the samples of Comparative Example 101, Examples 101 to 105, and Comparative Example 106 were placed into the reaction container of the plasma CVD apparatus, the reaction container was evacuated to 1×10⁻³ Pa again, and then a mixture of Ar gas at a flow rate of 40 SCCM and oxygen gas at a flow rate of 70 SCCM was introduced into the reaction container to a gas pressure of 2 Pa, while applying a voltage of −3.5 kV to generate a plasma of the mixture gas of Ar and oxygen which was applied to the substrate for 125 minutes. Next, the mixture gas of Ar and oxygen was evacuated, and the reaction container was returned to a normal pressure. The Si sample pieces of the Comparative Examples and Examples were then taken out of the reaction container. FIGS. 30 and 31 are electron microscope photographs (with a magnification of 30,000) of the surface and a section of Comparative Example 101 (after the etching). The photographs show the tip ends of the needle-like projections. FIG. 32 is an electron microscope photograph (with a magnification of 30,000) of Comparative Example 101 (prior to the etching). Comparison in thickness between the films of FIGS. 31 and 32 reveals that the thickness of the film of Comparative Example, which was about 750 nm before the dry etching and was about 550 nm after the dry etching, was reduced by as much as about 200 nm by application of a plasma of Ar and oxygen. By contrast, the same observation (measurement) of a section of Example 106 by electron microscope photography revealed that the thickness of the film of Example 106 (formed with a material gas containing Si to a thickness of about 750 nm and entirely composed of the amorphous carbon film containing Si) was reduced (lost) by only about 30 nm by the dry etching (the thickness of the film after the dry etching was about 720 nm).

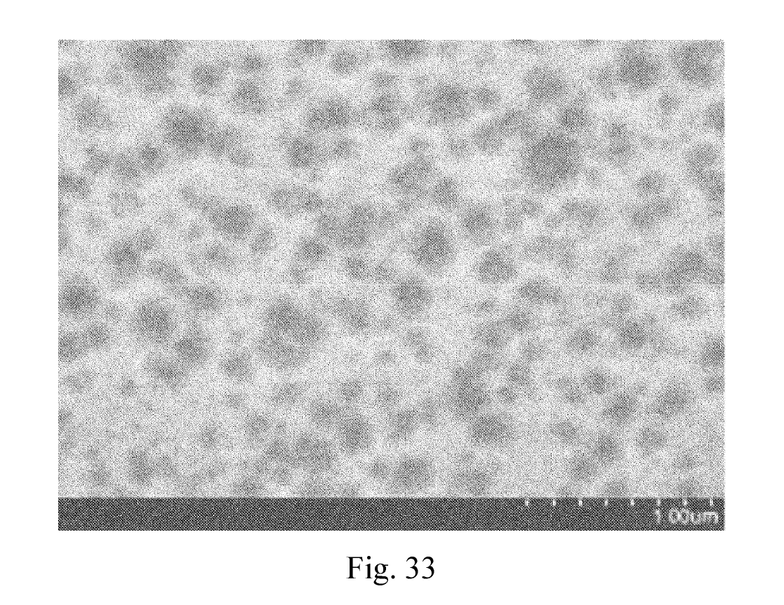

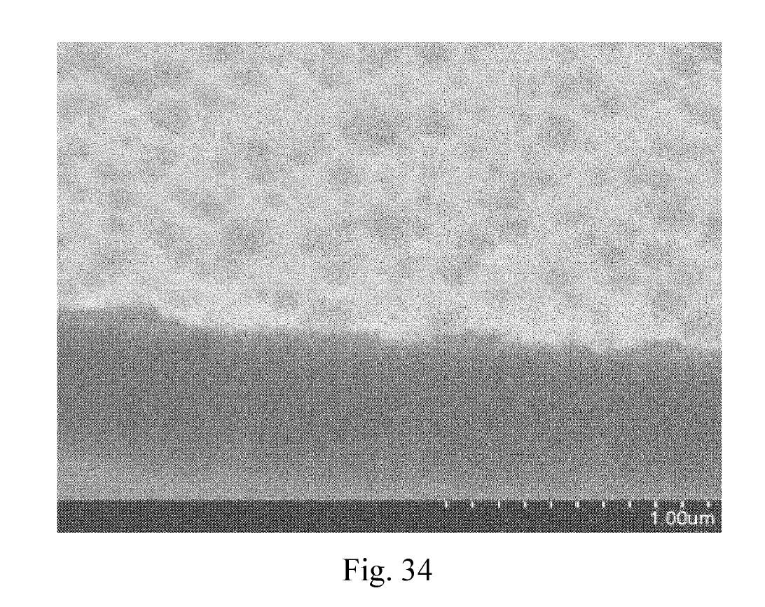

FIGS. 33 and 34 are electron microscope photographs of the surface and a fracture section of Example 101 (after the etching). These photographs show that the surface layer of Example 101 after the etching has a large number of crater-like recesses formed therein. These crater-like recesses had a diameter (opening width) of about 50 nm to 100 nm, and the maximum diameter thereof was about 150 nm. From the measurement values of the surface roughness obtained by an atomic force microscope (AFM), the depth of the crater-like recesses (the depth of the holes) can be estimated to be about 30 to 50 nm. Thus, it was found that the crater-like recesses formed had an aspect ratio (depth/opening width) of about 0.3 to 1.0. The crater-like recesses having the same diameter as in Example 101 were found in all of Examples 102 and 103 having the amorphous carbon film containing Si, Examples 104 and 105 having less amount of Si, and Example 106 not including an underlying amorphous carbon layer not containing Si and including a thick amorphous carbon film containing Si. The measurement result of surface roughness was as follows.

Example 101 (after the etching)

root-mean-square roughness: 6.08

ten point average roughness: 36.8

surface area: 25,700,000

The surface layer of Example 101, having a large number of crater-like recesses formed therein, is entirely continuous. The surface layer of Comparative Example 101 constituted by an amorphous carbon film not containing Si has a plurality of needle-like projections formed therein, and external stresses tend to concentrate at the tip ends of these projections (concentration of stresses tends to occur). By contrast, in Example 101, external stresses are received at the upper surface of relatively thin columnar projections forming the crater-like recesses and thus are less prone to concentrate. This structure provides excellent wear resistance.

Since such structure of the surface layer of Example 101 is formed by applying a plasma of oxygen to Si in the amorphous carbon film constituting the surface layer, this surface layer include functional groups exhibiting hydrophilicity such as Si—OH. Further, this surface layer has a strong structural hydrophilicity produced by a large surface area enlarged by a large number of crater-like recesses and thus is less prone to short-term degradation of hydrophilicity which is found in the case where a plasma of oxygen or Ar is applied to carbon only, being capable of retaining hydrophilicity for a long period.

Further, if a fluorine-containing coupling agent exhibiting water and oil repellence and capable of being fixed firmly by condensation reaction with Si—OH is received in the crater-like recesses in the surface layer of Example 101 (to form a thin layer having a thickness of about 10 to 20 nm), the thickness portion of the coupling agent layer is less prone to receive lateral external stresses as compared to the case where the fluorine-containing coupling agent is received between the projections scattered in a needle-like manner (that is, in an open space) in Comparative Example 101 (after the etching). Thus, the fluorine-containing coupling agent layer can be protected against external stresses. Further, since structural water and oil repellence can be produced by the large surface area enlarged by the unevenness structure, such a surface can retain water and oil repellence for a long period.

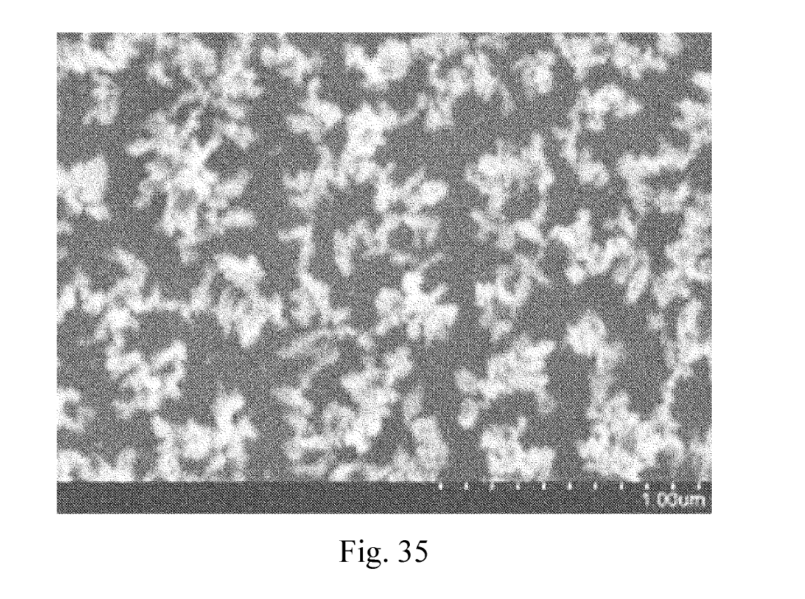

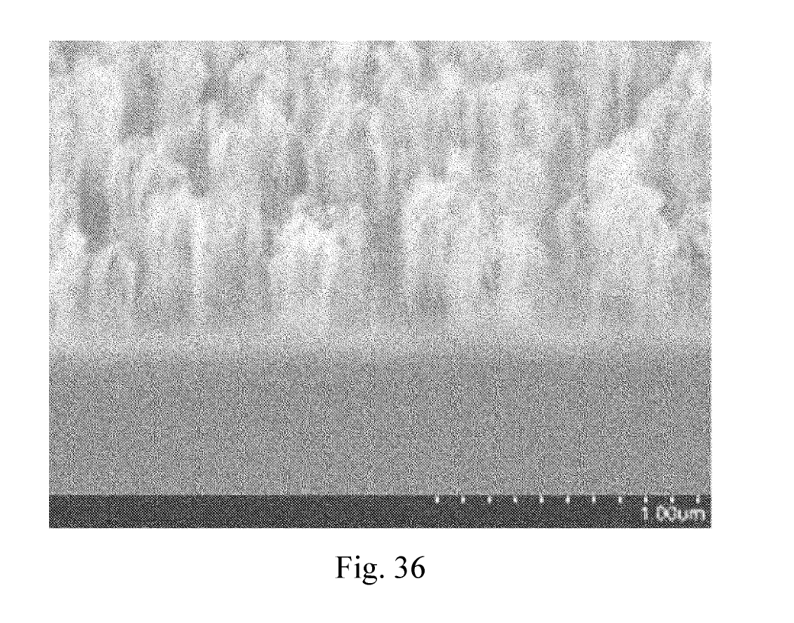

Next, Example 101 (after the dry etching) was subjected to another dry etching (the second dry etching) for 120 minutes under the same conditions as those for producing Example 101. FIGS. 35 and 36 are electron microscope photographs (with a magnification of 50,000) of the surface and a section of Example 101 (after the second dry etching), respectively. These photographs show that the surface having the crater-like recesses has disappeared. Further, the photographs show a large number of “columnar” projections different from the “needle-like projections having sharp tip ends” formed in Comparative Example 101 (after the dry etching) not containing Si and composed of carbon and hydrogen. The large number of columnar projections do not have sharp tip ends but have wall surfaces substantially perpendicular to the surface of the substrate, and stand close to each other with uniform heights of about 300 to 400 nm. The electron microscope photographs also show that the recesses formed between the projections constitute deep holes having an extremely large aspect ratio (depth/opening width). Such structure is produced because in the etching process, the Si oxide layer in the crater-like recesses is first removed and then the underlying carbon layer not containing Si and having a high etching rate is etched, such that the etching process proceeds rapidly at this portion.

Thus, if a carbon layer containing a substance such as Si or metals less prone to be etched by oxygen is previously formed on a layer not containing such a substance but composed of a substance such as carbon more prone to be etched by oxygen, the shape of the projections in the unevenness is less collapsible (the ends of the projections are restricted from being sharp and structurally fragile) during the dry etching with oxygen, thereby making it possible to form the unevenness structure including the structurally robust projections and the deep recesses having an extremely large aspect ratio (depth/opening width). The measurement result of surface roughness was as follows.

Example 101 (after etching twice)

root-mean-square roughness: 38.8

ten point average roughness: 338

surface area: 30,900,000

The elementary composition analysis was performed with FE-SEM on the “hydrogen-free basis” and under the following condition.

Measurement Instrument
FE-SEM SU-70 from Hitachi High-Technologies Corporation

Measurement Condition:
No vapor deposition
Acceleration voltage: 7.0 kV
Electric current mode: Med-High
Magnification: 1,000×
Substrate for samples: stainless steel (SUS304) plated with hard chrome
Designated elements: C (carbon), O (oxygen), Si (silicon), and Ar (argon)

The analysis result was as follows.

Example 101 (before the etching)

carbon: 97.84 at %

oxygen: 0.94 at %

silicon: 1.22 at %

Example 101 (after etching twice)

carbon: 34.13 at %

oxygen: 16.99 at %

silicon: 48.88 at %

As to the composition ratio on the “hydrogen-free basis” ignoring hydrogen, the percentage of carbon atoms was reduced significantly from 97.84 at % to 34.13 at %, while the values indicating the presence of Si oxide were increased significantly, that is, the percentage of Si was 48.88 at % and the percentage of oxygen was 16.99 at %. Since Si oxide has less tendency to be etched by oxygen, it can be presumed that the surface layer of the unevenness portion formed includes concentrated Si oxide in particular. The Si oxide contain much functional groups such as hydroxyl groups that provide better wettability with water and chemically bind to substances such as coupling agents capable of being fixed on a substrate by condensation reaction or hydrogen bonding for firm fixation on the substrate.

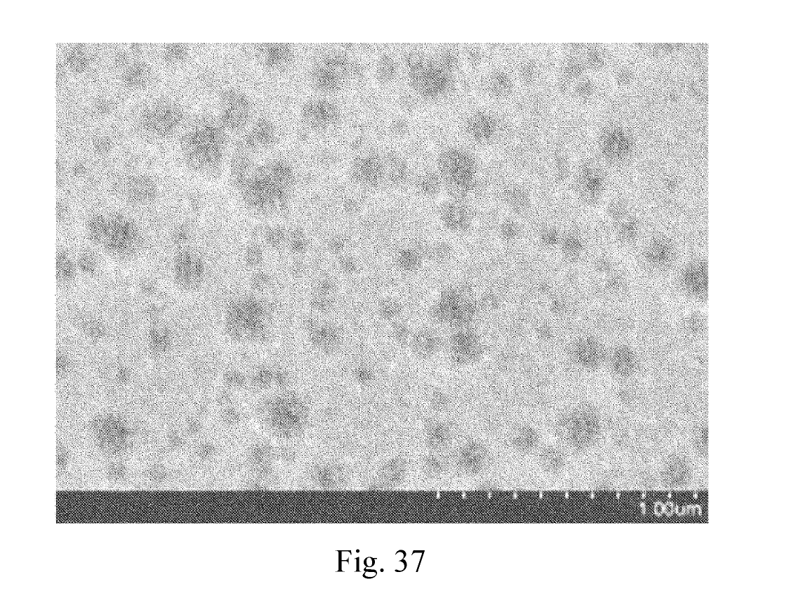

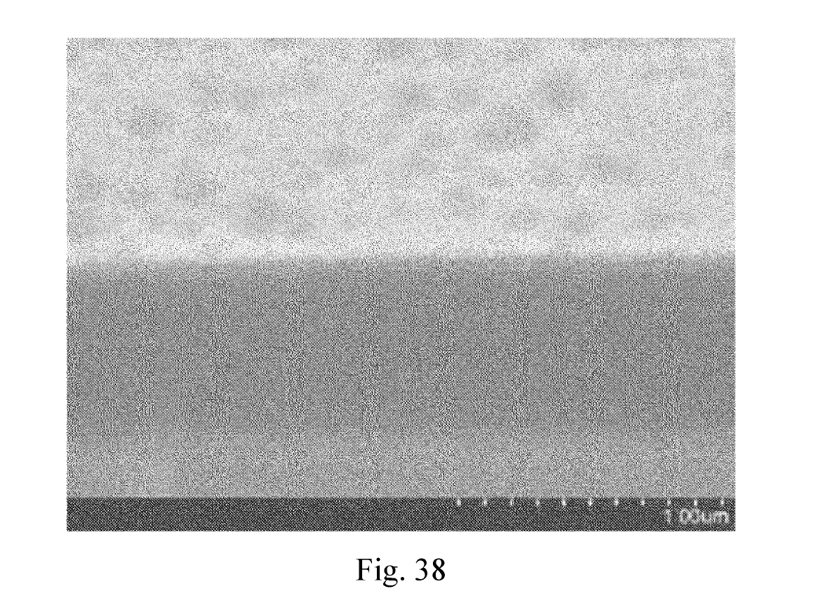

FIGS. 37 and 38 are electron microscope photographs of the surface and a section of Example 105. The measurement result of surface roughness was as follows.

### Example 105

root-mean-square roughness: 6.48

ten point average roughness: 41.6

surface area: 25,600,000

The analysis result of elementary composition was as follows.
Example 105 (prior to the dry etching)

carbon: 95.86 at %

oxygen: 1.58 at %

silicon: 2.56 at %

Example 105 (after the dry etching)

carbon: 83.85 at %

oxygen: 13.22 at %

silicon: 2.93 at %

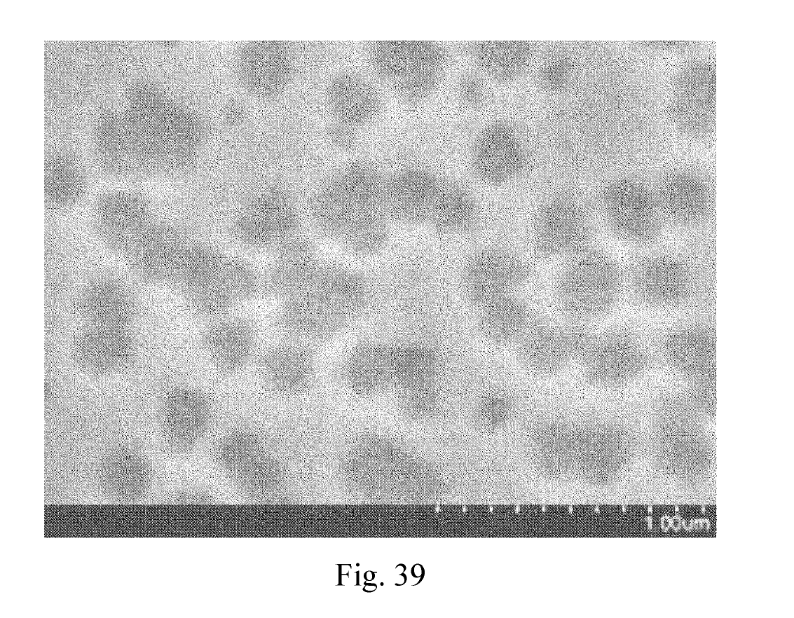

FIG. 39 is an electron microscope photograph of the surface of Example 106.

The measurement result of surface roughness was as follows.

### Example 106

root-mean-square roughness: 8.35

ten point average roughness: 55.1

surface area: 25,900,000

The analysis result of elementary composition was as follows.
Example 106 (before the etching)

carbon: 58.43 at %

oxygen: 0.78 at %

silicon: 40.79 at %

Example 106 (after the etching)

carbon: 44.12 at %

oxygen: 18.35 at %

silicon: 37.53 at %

The composition analysis of Example 101 (before the etching) revealed that if a carbon film before the etching contains Si at a ratio of “97.84 at % of carbon, 0.94 at % of oxygen, and 1.22 at % of Si” on the hydrogen-free basis, the fine unevenness structure according to an embodiment can be formed to include a large number of (crater-like) recesses recessed downward rather than a large number of (needle-like or columnar) projections projecting upward that would be formed in a carbon film not containing Si.

The following surface roughnesses of Comparative Example 106 (equal to Example 106 before the etching) and Example 106 indicate enlargement of the unevenness in the surface and the surface area.

### Comparative Example 106

root-mean-square roughness: 0.187

ten point average roughness: 3.5

surface area: 25,000,000

### Example 106

root-mean-square roughness: 8.35

ten point average roughness: 55.1

surface area: 25,900,000

Next, one week after Comparative Example 106 and Example 106 (after the etching) were prepared, these samples were manually coated with Fluorosurf FG-5010Z130-0.2 from Fluoro Technology Corporation, a water and oil repellent coating agent containing fluorine and capable of chemically binding to hydroxyl groups in the surface layer of a substrate by condensation reaction or hydrogen bonding, and left to stand for one hour in an environment having a room temperature of 25° C. and a humidity of 45%. Then, these samples were coated again with the coating agent, dried for 24 hours, cleansed for one minute in an ultrasonic cleansing apparatus filled with isopropyl alcohol (IPA), and then dried naturally, before the measurement of the contact angle with water (pure water). The measurement conditions were as follows.

Measurement instrument portable contact angle gauge PCA-1 from Kyowa Interface Science Co., Ltd

Measurement range: 0 to 180° (display resolution 0.1°)

Measurement method: contact angle measurement (drop method)

Measurement liquid: pure water

Amount of measurement liquid: 0.5 μl

The measurement points were the four corners and the middle of the rectangular work, and the average value was calculated based on these five points. The measurement result of the contact angle is shown below.

Comparative Example 106: 96.82° (96.8°, 98.9°, 95.6°, 96.7°, 96.1°)

Example 106: measurement of the contact angle was impossible because the water drops were repelled from the surface of the substrate and were not settled at all of the five points. Therefore, the contact angles were estimated to be larger than 140°.

The amount of liquid for measurement of the contact angle with water is 0.5 μl. This amount is slightly small. The contact angle (water repellence) of Example 106 larger than that of Comparative Example is presumably produced by the unevenness structure in the surface of Example 106 and the large surface area thereof. Further, the fine unevenness structure in Example 106 includes crater-like recesses, and the air retained in the recesses are blocked by the surrounding inner walls of the recesses and presumably are not free to move outside. Thus, the crater-like unevenness structure which is open upward only is more capable of retaining the air in the recesses and can exhibit a higher structural water repellence than the needle-like projection structure including open spaces around the projections that are not defined by walls and communicate with the outside (allow the air to move outside).

It is publicly known that the surface layer of an amorphous carbon film containing Si can be hydrophilized by irradiating the amorphous carbon film with a plasma including oxygen, and that the hydrophilic effect can be amplified by enlargement of the surface area (structural hydrophilicity). Therefore, the surface layer of the structure according to an embodiment such as Example 106 is presumed to have a strong hydrophilicity.

The additional observation of the unevenness structure in the surface of the carbon film containing Si has been described above. This observation revealed the following points. If Si (or a metal such as Ti, Zr, Al, etc. that is less prone to be etched by oxygen and is oxidized simultaneously with the etching to form hydrophilic functional groups, etc.) is previously contained in a film containing carbon prone to be etched by oxygen and particularly in an amorphous carbon film that tends to have irregular distribution of Si, and etching is performed with an inert gas such as oxygen or oxygen and Ar, carbon is partially removed to form, e.g., a structure including unevenness structure having a ten point average roughness Rz of 20 nm or larger or other structures including desired unevenness structure required in various aspects described above. This unevenness structure ensures a large surface area or retains a desired substance in the recesses of the unevenness structure. Further, this unevenness structure has a reduced pressure in the recesses thereof and retains water in the recesses.

Further, to form the unevenness structure according to an embodiment by dry etching with oxygen, it is necessary that carbon to be removed by the etching should be present in the film before the etching and that if the film to be etched is an amorphous carbon film, a certain amount of carbon, hydrogen, etc. should be present as “a substance that can be removed by etching and form the recesses of the unevenness structure.” By contrast, if the film before the etching previously contains Si, metals, Si oxide, or metal oxides, the surface layer of the film can include, for a long period and in a stable manner, hydroxyl groups that increase the wettability with water and fix a coupling agent including M that forms —O-M bonds (M is any one element selected from the group consisting of Si, Ti, Al, and Zr), and other functional groups that form chemical bonds or hydrogen bonds with external substances, as described above. However, the presence of carbon and hydrogen may inhibit the film from previously containing (in the surface layer or the interior thereof) a desired necessary amount or more of Si, metals, Si oxide, or metal oxides. It may also inhibit the etching itself if the surface layer of the film contains Si, metals, or oxides thereof at a high concentration before the etching.

However, the above observation revealed that an amorphous carbon film containing Si subjected to plasma etching with oxygen gas includes at least a reduced proportion of carbon atoms and an increased total proportion of Si and oxygen (presumably constituting Si oxide). That is, if Si, metals, Si oxide, or metal oxides are previously contained in the interior of an amorphous carbon film containing carbon and hydrogen, not in the surface layer thereof, and then etching is performed with an etching gas including at least oxygen, it can be presumed that Si, Si oxide, metals, or metal oxides that are less prone to be removed by oxygen etching remain concentratedly in the surface layer of the film. Such an oxygen etching process presumably allows Si, Si oxide, metals, or metal oxides dispersed in the film to efficiently concentrate and remain so as to coat the surface layer of the structure including the unevenness structure according to an embodiment.

That is, to form a structure including a carbon film containing a substance, not limited to Si or Si oxide, less prone to be removed by dry etching with oxygen plasma such that the substance is concentrated to a high concentration in the vicinity of the surface layer of fine unevenness structure in the carbon film, the structure should be formed such that the carbon film contains, in a dispersed manner, the substance to be concentrated to a high concentration, by forming the carbon film with a mixture of a material gas for forming the carbon film, e.g., a hydrocarbon-based material gas such as acetylene and a gas containing the substance less prone to be removed by dry etching with oxygen plasma (e.g., an organic metal gas containing various metals (for titanium for example, titanium chloride (TiCl₄), titanium iodide (TiI₄), titanium isopropoxide Ti(i-OC₃H₇)₄, etc.)) or forming the carbon film while sputtering a metal such as titanium from a solid metal target thereof into the carbon film, and then the dry etching should be performed with oxygen, such that the substance such as a metal can be concentrated to a high concentration in a form of the metal oxide, etc. in the surface layer of the unevenness structure formed. Further, if a layer containing the above metal or metal oxide is formed on the fine unevenness structure formed in the carbon film not containing the metal, the fine unevenness structure can presumably be prevented from being flattened.

The above results indicate that it is possible to form a hydrophilic structure that includes in the surface thereof unevenness structure exhibiting structural hydrophilicity and also includes in the surface layer thereof a large amount of functional groups that can exhibit hydrophilicity. Further, the functional groups can fix the fluorine-containing coupling agent, etc. firmly by chemical bonding. A layer of the coupling agent can be formed so as not to fill the interior of the recesses in the unevenness structure, thereby to simultaneously produce structural water repellence. Since the layer of the coupling agent is protected in the recesses of the unevenness structure against external stresses, the water repellence can be retained stably for a long period.

Next, the same sample as Comparative Example 101 was placed into the reaction container of the plasma CVD apparatus, the reaction container was evacuated to 1×10⁻³ Pa, and then a mixture of Ar gas at a flow rate of 40 SCCM and oxygen gas at a flow rate of 70 SCCM was introduced into the reaction container to a gas pressure of 2 Pa, while applying a voltage of −3.5 kV to generate a plasma of the mixture gas of Ar and oxygen which was applied to the substrate for 35 minutes. This sample was taken as Example 201. Next, the same sample as Comparative Example 101 was placed into the reaction container of the plasma CVD apparatus, the reaction container was evacuated to 1×10⁻³ Pa, and then a mixture of Ar gas at a flow rate of 40 SCCM and hydrogen gas at a flow rate of 70 SCCM was introduced into the reaction container to a gas pressure of 2 Pa, while applying a voltage of −3.5 kV to generate a plasma of the mixture gas of Ar and hydrogen which was applied to the substrate for 35 minutes. This sample was taken as Example 301. Next, the mixed etching gases were evacuated, and the reaction containers were returned to a normal pressure. The Si sample pieces of Examples were then taken out of the reaction container. The measurement result of surface roughness was as follows.

### Comparative Example 101

root-mean-square roughness: 0.95

ten point average roughness: 9.06

surface area: 25,000,000

Example 201 (irradiated with Ar and nitrogen gas for 35 min.)

root-mean-square roughness: 1.87

ten point average roughness: 15.1

surface area: 25,100,000

Example 301 (irradiated with Ar and hydrogen gas for 35 min.)

root-mean-square roughness: 1.65

ten point average roughness: 13

surface area: 25,100,000

Thus, the unevenness structure formed is gentle as compared to that formed with oxygen, but nitrogen and hydrogen can be used as etching gases to form fine unevenness structure (increase the surface area). It can be presumed that nitrogen used for plasma irradiation reacts with carbon to form CN and hydrogen reacts with carbon to form CH, and therefore, rough unevenness structure is formed in the surface as with oxygen.

### 3. Observation of Hydrophilicity in Accordance with Increase of Surface Area

The sample for evaluation was prepared by a plasma CVD method as follows.

### Preparation of a Sample of Example 401

Six sheets of tabular substrates formed of stainless steel (SUS304) having a size of 100 mm by 100 mm and a thickness of 3 mm were prepared. One of these substrates was subjected to Ni plating with a sulfamic acid nickel bath. The sulfamic acid nickel bath was prepared in accordance with the known composition by mixing 450 g/L of sulfamic acid (Ni(NH₂SO₂)₂), the main component, with 30 g/L of boric acid (H₃BO₃), and 5 g/L of nickel chloride (NiCl₂.6H₂O) (all from NIHON KAGAKU SAN GYO CO., LTD.). To roughen the surface, the sulfamic acid nickel bath did not include a leveling agent (“NSE-E” from NIHON KAGAKU SANGYO CO., LTD.) and an anti-pit agent that are ordinarily added to smoothen the surface. The Ni plating was performed at 2 A/dm² for 90 minutes.

The substrate thus plated was subjected to ultrasonic cleansing using isopropyl alcohol (IPA) and placed into a reaction container of a plasma CVD apparatus. Next, the reaction container was evacuated to 1×10⁻³ Pa, and then Ar gas was introduced into the reaction container at a flow rate of 30 SCCM to a gas pressure of 2 Pa, while applying a voltage of −3.5 kVp to generate Ar plasma for cleaning the surface of the substrate for ten minutes. Next, the reaction container was evacuated of Ar gas to a vacuum, and then trimethylsilane gas was introduced into the reaction container at a flow rate of 30 SCCM to a gas pressure of 1.5 Pa, while applying a voltage of −4.0 kVp to form a film for four minutes. Through this process, an Si-containing amorphous carbon film (a first amorphous carbon film) was formed on the surface of the substrate. Next, the reaction container was evacuated of trimethylsilane gas and then evacuated to a vacuum again. Next, acetylene gas was introduced into the vacuum reaction container at a flow rate of 30 SCCM to a gas pressure of 1.5 Pa, while applying a voltage of −5.0 kVp to form an amorphous carbon film (a second amorphous carbon film) for 40 minutes. Next, the reaction container was evacuated of acetylene gas, and then Ar gas and oxygen gas were introduced into the reaction container at flow rates of 30 SCCM and 50 SCCM, respectively, to a mixed-gas pressure of 2 Pa, while applying a voltage of −3 kVp to perform etching on the substrate for 60 minutes. Next, the reaction container was evacuated of Ar gas and oxygen gas, and then trimethylsilane gas was introduced into the reaction container at a flow rate of 30 SCCM to a gas pressure of 0.6 Pa, while applying a voltage of −4 kVp to form an amorphous carbon film (a third amorphous carbon film) containing Si for 40 seconds. Next, the reaction container was evacuated of trimethylsilane gas, and then oxygen gas was introduced into the reaction container at a flow rate of 30 SCCM to a gas pressure of 0.8 Pa, while applying a voltage of −3.5 kVp to irradiate the substrate with oxygen plasma for four minutes. Next, the reaction container was evacuated of oxygen gas, and then the samples irradiated with oxygen plasma were taken out of the reaction container. The samples were left to stand at a room temperature and a normal pressure for one hour, and then the surface of the formed film was manually coated with a fluorine containing coupling agent, Fluorosurf FG-5010Z130-0.2 from Fluoro Technology Corporation. The samples coated with the fluorine-containing coupling agent were dried at a room temperature and a normal pressure for 120 minutes. Next, the dried samples were coated with the same fluorine-containing coupling agent as above, and then the samples were dried at a room temperature and a normal pressure for 120 minutes. The dried samples were subjected to ultrasonic cleansing in an ultrasonic cleansing bath containing IPA for one minute. The samples subjected to ultrasonic cleansing were taken as Example 401.

### Preparation of a Sample of Example 402

One of the six substrates prepared previously was subjected to Ni plating at an electric current density of about 2 A/dm² for 90 minutes using a nickel chloride plating bath (an immersion nickel bath) that can further roughen the surface of the substrate, the nickel chloride plating bath having a pH of about 2 and composed mainly of nickel chloride (300 g/L) with about 10% boric acid (30 g/L) and no leveling agent added thereto. As with Example 401, the substrate subjected to the plating was then subjected to formation of the first amorphous carbon film, formation of the second amorphous carbon film, formation of the third amorphous carbon film, etching, coating with a fluorine-containing coupling agent, and ultrasonic cleansing. The sample thus obtained was taken as Example 402.

### Preparation of Example 403

The remaining four substrates were sandblasted at one surface thereof using a polishing medium in a sandblasting apparatus (“PNEUMA-BLASTER SGF-3(B)” from Fuji Manufacturing Co., Ltd). First, one of the four remaining substrates was sandblasted using a polishing medium #100, and the sandblasted substrate was then subjected to satellite Ni plating using a sulfamic acid Ni bath including dispersed fine particles with a diameter of about 1 μm. As with Example 401, the substrate subjected to the plating was then subjected to formation of the first amorphous carbon film, formation of the second amorphous carbon film, formation of the third amorphous carbon film, etching, coating with a fluorine-containing coupling agent, and ultrasonic cleansing. The sample thus obtained was taken as Example 403.

### Preparation of Example 404

One of the remaining substrates was sandblasted at one surface thereof using a polishing medium #100. As with Example 401, the sandblasted substrate was then subjected to formation of the first amorphous carbon film, formation of the second amorphous carbon film, formation of the third amorphous carbon film, etching, coating with a fluorine-containing coupling agent, and ultrasonic cleansing. The sample thus obtained was taken as Example 404.

### Preparation of Example 405

One of the remaining substrates was sandblasted at one surface thereof using a polishing medium #300. As with Example 401, the sandblasted substrate was then subjected to formation of the first amorphous carbon film, formation of the second amorphous carbon film, formation of the third amorphous carbon film, etching, coating with a fluorine-containing coupling agent, and ultrasonic cleansing. The sample thus obtained was taken as Example 405.

### Preparation of Example 406

One of the remaining substrates was sandblasted at one surface thereof using a polishing medium #400. As with Example 401, the sandblasted substrate was then subjected to formation of the first amorphous carbon film, formation of the second amorphous carbon film, formation of the third amorphous carbon film, etching, coating with a fluorine-containing coupling agent, and ultrasonic cleansing. The sample thus obtained was taken as Example 406.

Each of Examples 401 and 402 was measured for the surface roughness (calculated average roughness (Ra), maximum height (Ry), and ten point average roughness (Rz)) and the surface area (S3A). Measurement of Examples 401 and 402 was performed twice, before and after formation of the amorphous carbon film. The measurement was performed using a 3D profile microscope (“VK-9510” from KEYENCE CORPORATION) under the following conditions.

Measurement mode: color 3D measurement
Lens magnification: 50× or 150×

### Pitch: 0.05 μm

The measurement result for Example 401 (the substrate subjected to sulfamic acid Ni plating with no leveling agent) was as follows (m). The laser microscope was set at a magnification of 150×.

### (1) Before Film Formation

Ra: 0.26, Ry: 4.56, Rz:4.34, surface area/area (projection area): 2.12

### (2) After Film Formation

Ra: 0.27, Ry: 5.64, Rz:4.85, surface area/area: 2.31

The measurement result for Example 402 (the substrate subjected to Ni chloride plating with no leveling agent) was as follows (m). The laser microscope was set at a magnification of 150×.

### (1) Before Film Formation

Ra: 0.68, Ry:10.51, Rz:10.26,

surface area/area: 6.17

### (2) After Film Formation

Ra: 0.74, Ry:11.97, Rz:11.75,

surface area/area: 6.63

(surface area/area, measured at the same magnification of 150× for comparison with Example 401: 8.03)

Thus, it was observed that the rough surface before film formation is maintained. Likewise, each of Examples was measured for surface roughness and area after film formation.

Example 403 (sandblasted with #100+satellite Ni plating)
After film formation

Ra: 1.60, Ry:20.31, Rz:19.11,

surface area/area: 2.76

Example 405 (polishing medium #300)
After film formation

Ra: 0.99, Ry:13.47, Rz:13.37,

surface area/area: 3.64

Example 406 (polishing medium #400)
After film formation

Ra: 1.46, Ry:16.52, Rz:16.45,

surface area/area: 3.71

Next, each of Examples 401 to 406 was measured for contact angle with water (pure water) at the surface thereof. The measurement was performed using a portable contact angle gauge (“PCA-1” from Kyowa Interface Science Co., Ltd) under the following conditions.

Measurement range: 0 to 180° (display resolution 0.1°)

Measurement method: contact angle measurement (drop method)

Measurement liquid: pure water

Amount of measurement liquid: 1 μl

Temperature: 25±5° C.

Humidity: 45±10%

Normal pressure

Each of the samples was measured for contact angles at ten different points on the surface thereof, and the average value of the contact angles was calculated. The average values for Examples were as follows.

### Example 401: 122.2°

Example 402: Water drops were not settled and measurement was impossible at the ten points.
Amount of measurement liquid: 1.5 μl

### Example 401: 122.1°

Example 402: Water drops were settled at only three points measuring 139.3°, 139.6°, 140.0°. At other points, water drops were not settled and measurement was impossible.

### Example 403: 132.94°

### Example 404: 130°

### Example 405: 133.40°

### Example 406: 134.52°

For Example 402, water drops were not settled and measurement of contact angles was impossible. Under the above measurement conditions, a contact angle of about 140° or larger prevents water from being settled and thus cannot be measured. Therefore, each of the contact angles of Example 402 can be estimated to be at least larger than 140°.

The contact angle with water of Example 401, in which the ratio of surface area/area is about 2.31, is about the same as (or slightly larger than) the contact angle with water (about 120°) in the case where the same amorphous carbon film and a water and oil repellent layer composed of a fluorine-containing silane coupling agent were formed on a very smooth SUS substrate (having a surface roughness Ra of about 0.03 μm). However, for Examples 402 to 406 in which the ratio of surface area/area is 2.76 or larger, the contact angle with water is 130° or larger, and for Example 402 in which the ratio of surface area/area is at least larger than 6, the contact angle is large enough (exceeding about 140°) to prevent water drops from being settled.

Confirmation of Superhydrophilicity

A sample was prepared in the same manner as Examples 401 and 402 except that the fluorine-containing silane coupling agent was not applied, and contact angles with water of this sample were measured. The measurement conditions were the same as those for the confirmation of water and oil repellence described above, and the amount of water drop was 1.5 μl. Due to spreading of water, contact angles could not be measured with the contact angle gauge and thus were confirmed to be smaller than 5°.

Thus, it was confirmed that all of Examples 401 to 406 had a high water repellence. In particular, Examples 402 and 403 exhibited contact angles (structural water repellence) larger than the contact angles exhibited by ordinary fluorine-containing silane coupling agent.

What is claimed is:

1. A structure comprising:
a substrate; and
a carbon film formed on the substrate and containing carbon, or carbon and hydrogen,
wherein at least part of a surface of the carbon film has unevenness structure formed by irradiation with ions and/or radicals of oxygen and/or Ar and having a ten point average roughness Rz of 20 nm or larger.

2. The structure of claim 1 wherein the unevenness structure has a ten point average roughness Rz of 40 nm or larger.

3. The structure of claim 1 wherein the unevenness structure has a ten point average roughness Rz of 150 nm or larger.

4. The structure of claim 1 wherein the unevenness structure is formed by irradiation with plasma of oxygen and/or Ar.

5. The structure of claim 1 wherein the unevenness structure includes a plurality of projections arranged at intervals of less than 50 nm, and recesses formed between adjacent projections have an aspect ratio (depth/opening width) of 0.3 or larger.

6. The structure of claim 1 wherein the unevenness structure has a surface area of 25,200,000 nm² or larger and a root-mean-square roughness of 2.03 nm or larger in a rectangular measurement region having a size of 5 μm by 5 μm.

7. The structure of claim 1 wherein at least part of the projections of the unevenness structure are wider toward the substrate.

8. The structure of claim 1 wherein the carbon film comprises an amorphous carbon film composed mainly of carbon, or carbon and hydrogen.

9. The structure of claim 1 wherein at least part of the carbon film is reduced by hydrogen.

10. The structure of claim 1 wherein the unevenness structure is formed in the surface of the carbon film so as to include an outermost part of the carbon film in a thickness direction.

11. The structure of claim 1 wherein at least part of the surface of the carbon film has a contact angle with water of less than 50°.

12. The structure of claim 1 wherein the carbon film further contains Si and/or a metal element.

13. The structure of claim 1 wherein in the carbon film, the content of oxygen and/or Ar in the surface having the unevenness structure is larger than the content of oxygen and/or Ar in the other surface.

14. The structure of claim 1 wherein in the carbon film, a layer underlying the unevenness structure is exposed at at least part of the recesses of the unevenness structure.

15. The structure of claim 1, wherein
the substrate is transparent or translucent, and
a total light transmittance of the structure is 80% or higher.

16. The structure of claim 15 wherein the substrate comprises a transparent resin mold, a transparent film, or transparent glass.

17. The structure of claim 1 wherein the substrate comprises a porous material such as a mesh, fabric, and a porous sheet.

18. The structure of claim 1 wherein the unevenness structure included in the surface of the carbon film has a different shape than a portion of the substrate underlying the unevenness structure.

19. The structure of claim 1 wherein recesses of the unevenness structure in the surface of the carbon film contain a predetermined matter.

20. The structure of claim 19 wherein the predetermined matter is a hard film formed by a dry process.

21. The structure of claim 19 wherein the predetermined matter is formed by a dry process and contains at least one element selected from the group consisting of Si, Ti, Al, and Zr.

22. The structure of claim 20 wherein the predetermined matter is an amorphous carbon film containing at least one element selected from the group consisting of Si, oxygen, nitrogen, and Ar.

23. The structure of claim 22 wherein the amorphous carbon film is formed by applying plasma of at least one selected from the group consisting of oxygen, nitrogen, and Ar to an amorphous carbon film containing at least Si.

24. The structure of claim 22 wherein the amorphous carbon film contains a substance having water repellence or water and oil repellence.

25. The structure of claim 24 wherein the substance having water repellence or water and oil repellence is fluorine.

26. The structure of claim 22, wherein
the substrate is transparent or translucent, and
the amorphous carbon film contains Si and oxygen, and
a total light transmittance of the structure is 80% or higher.

27. The structure of claim 19 wherein the predetermined matter is a semiconductor film.

28. The structure of claim 27 wherein the semiconductor film includes titanium dioxide, zinc oxide, or amorphous Si.

29. The structure of claim 19 wherein the predetermined matter is water or water vapor.

30. The structure of claim 19 wherein the predetermined matter is a fluorine resin, a silicone resin, a grease, or a lubricant.

31. The structure of claim 19 wherein the predetermined matter is fine particles of Pt, Au, Ag, or Ro.

32. The structure of claim 1, wherein
the carbon film further contains Si, and
the unevenness structure is formed of a plurality of crater-like recesses.

33. The structure of claim 32 wherein the crater-like recesses have a diameter of 50 to 150 nm.

34. The structure of claim 32 wherein the crater-like recesses have a depth of 40 to 50 nm.

35. The structure of claim 32 wherein the crater-like recesses have an aspect ratio (depth/opening width) of 0.3 to 1.0.

36. The structure of claim 32 wherein in at least a portion of the surface of the carbon film having the unevenness structure, the ratio of surface area to projection area (surface area/projection area) is 2.7 or larger.

37. The structure of claim 32 wherein in at least a portion of the surface of the carbon film having the unevenness structure, the ratio of surface area to projection area (surface area/projection area) is 6.0 or larger.

38. The structure of claim 1 wherein a coupling agent film is formed on the carbon film.

39. A method of forming a carbon film, comprising:
forming a carbon film containing carbon, or carbon and hydrogen on a substrate; and
irradiating at least part of a surface of the carbon film with ions and/or radicals of oxygen and/or Ar until unevenness structure having a ten point average roughness Rz of 20 nm or larger is formed.
